(19) United States
(12) Patent Application Publication
(10) Pub. No.: US 2025/0126777 A1
(43) Pub. Date: Apr. 17, 2025

(54) ELECTRONIC DEVICE, METHOD FOR MANUFACTURING THE ELECTRONIC DEVICE, SEMICONDUCTOR DEVICE, METHOD FOR MANUFACTURING THE SEMICONDUCTOR DEVICE, AND STORAGE DEVICE

(71) Applicant: Semiconductor Energy Laboratory Co., Ltd., Atsugi-shi, Kanagawa-ken (JP)

(72) Inventors: Shunpei YAMAZAKI, Setagaya (JP); Tatsuya ONUKI, Atsugi (JP); Kiyoshi KATO, Atsugi (JP); Hitoshi KUNITAKE, Machida (JP); Ryota HODO, Atsugi (JP)

(21) Appl. No.: 18/730,461

(22) PCT Filed: Jan. 17, 2023
(86) PCT No.: PCT/IB2023/050376

§ 371 Date: Jul. 19, 2024

(30) Foreign Application Priority Data
Jan. 28, 2022 (JP) 2022-012166
Jan. 28, 2022 (JP) 2022-012224
Jan. 28, 2022 (JP) 2022-012262

(51) Int. Cl. H10B 12/00

(52) U.S. Cl. CPC H10B 12/482; H10B 12/02

(57) ABSTRACT

An electronic device including a first conductor, a second conductor, a first insulator, a second insulator, and a connection electrode is provided. The first insulator is provided over the first conductor and has a first opening overlapping with the first conductor. The second conductor is provided over the first insulator and has a second opening overlapping with the first conductor. The second insulator is provided over the second conductor and has a third opening overlapping with the first conductor. The second opening has a portion having a width smaller than a width of the third opening. The connection electrode is positioned inside the first opening, the second opening, and the third opening and is in contact with the top surface of the first conductor. The connection electrode includes a region in contact with part of the top surface and part of the side surface of the second conductor.

### TECHNICAL FIELD

One embodiment of the present invention relates to an electronic device, a transistor, a semiconductor device, a storage device, and an electronic appliance. Another embodiment of the present invention relates to methods for manufacturing an electronic device and a semiconductor device. Another embodiment of the present invention relates to a semiconductor wafer and a module.

Note that in this specification and the like, a semiconductor device generally means a device that can function by utilizing semiconductor characteristics. A semiconductor element such as a transistor, a semiconductor circuit, an arithmetic device, and a storage device are each an embodiment of a semiconductor device. It can be sometimes said that a display device (a liquid crystal display device, a light-emitting display device, and the like), a projection device, a lighting device, an electro-optical device, a power storage device, a storage device, a semiconductor circuit, an image capturing device, an electronic appliance, and the like include a semiconductor device.

Note that one embodiment of the present invention is not limited to the above technical field. One embodiment of the invention disclosed in this specification and the like relates to an object, a method, or a manufacturing method. One embodiment of the present invention relates to a process, a machine, manufacture, or a composition of matter.

### BACKGROUND ART

In recent years, semiconductor devices have been developed; in particular, a CPU, a memory, and the like have been actively developed. A CPU is a semiconductor device including a semiconductor integrated circuit formed into a chip by processing a semiconductor wafer, and is provided with an electrode that is a connection terminal. A semiconductor integrated circuit can also be referred to as an aggregation of semiconductor elements.

A semiconductor device of a CPU, a memory, or the like is mounted on a circuit board, for example, a printed wiring board, to be used as one of components of a variety of electronic appliances.

A technique by which a transistor is formed using a semiconductor thin film formed over a substrate having an insulating surface has been attracting attention. The transistor is used in a wide range of electronic devices such as an integrated circuit (IC) and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of a transistor using an oxide semiconductor. Furthermore, for example, Patent Document 2 discloses a storage device that can retain stored contents for a long time by utilizing a feature of a low leakage current of the transistor including an oxide semiconductor.

In recent years, demand for an integrated circuit with higher density has risen with reductions in size and weight of electronic appliances. In addition, an improvement of productivity of a semiconductor device including an integrated circuit is desired. For example, Patent Document 3 and Non-Patent Document 1 disclose a technique to achieve an integrated circuit with higher density by making a plurality of memory cells overlap with each other by stacking a first transistor including an oxide semiconductor film and a second transistor including an oxide semiconductor film.

### REFERENCE

### Patent Document

[Patent Document 1] Japanese Published Patent Application No. 2012-257187
[Patent Document 2] Japanese Published Patent Application No. 2011-151383
[Patent Document 3] PCT International Publication No. 2021/053473

### Non-Patent Document

[Non-Patent Document 1]M. Oota, et al., “3D-Stacked CAAC-In—Ga—Zn Oxide FETs with Gate Length of 72 nm”, IEDM Tech. Dig., 2019, pp. 50-53

### SUMMARY OF THE INVENTION

### Problems to be Solved by the Invention

An object of one embodiment of the present invention is to provide an electronic device or a semiconductor device that can be miniaturized or highly integrated. Another object is to provide an electronic device or a semiconductor device that operates at high speed. Another object is to provide a semiconductor device having favorable electrical characteristics. Another object is to provide a semiconductor device with a small variation in electrical characteristics of transistors. Another object is to provide a semiconductor device having favorable reliability. Another object is to provide a semiconductor device with a high on-state current. Another object is to provide a semiconductor device with low power consumption. Another object is to provide a novel semiconductor device. Another object is to provide a method for manufacturing a semiconductor device with a small number of steps. Another object is to provide a storage device including a novel semiconductor device.

Note that the description of these objects does not preclude the existence of other objects. In one embodiment of the present invention, there is no need to achieve all of these objects. Note that other objects will be apparent from the description of the specification, the drawings, the claims, and the like, and other objects can be derived from the description of the specification, the drawings, the claims, and the like.

### Means for Solving the Problems

One embodiment of the present invention is an electronic device including a first conductor, a second conductor, a first insulator, a second insulator, and a connection electrode. The first insulator is provided over the first conductor and has a first opening overlapping with the first conductor. The second conductor is provided over the first insulator and has a second opening overlapping with the first conductor. The second insulator is provided over the second conductor and has a third opening overlapping with the first conductor. The second opening includes a portion having a width smaller than a width of the third opening. The connection electrode is positioned inside the first opening, the second opening, and the third opening and is in contact with a top surface of the first conductor. The connection electrode includes a region in contact with a part of a top surface and a part of a side surface of the second conductor.

In the above electronic device, the second opening preferably includes a portion having a width smaller than a width of the first opening. In this structure, the connection electrode preferably includes a region in contact with a part of a bottom surface of the second conductor.

In any of the above electronic devices, the connection electrode preferably includes a third conductor and a fourth conductor. The third conductor is positioned on an inner side of the first opening, an inner side of the second opening, and an inner side of the third opening. The fourth conductor is preferably positioned between the third conductor and the first insulator, between the third conductor and the second conductor, and between the third conductor and the second insulator and include a region in contact with the part of the top surface and the part of the side surface of the second conductor.

In the above electronic device, the third conductor preferably includes tantalum, tungsten, titanium, molybdenum, aluminum, or copper. The fourth conductor preferably includes tantalum nitride, tungsten nitride, or titanium nitride.

In the above electronic device, the first insulator preferably includes a portion of the first opening whose inner wall is a concave surface. Furthermore, the third conductor preferably includes a portion whose side surface is a convex surface.

In the above electronic device, the width of the first opening is preferably smaller than the width of the second opening. Furthermore, in the third conductor, a portion positioned in the third opening preferably has a width smaller than a width of portion positioned in the first opening.

Another embodiment of the present invention is a method for manufacturing an electronic device including the following steps. In other words, a first conductor is formed; a first insulator is formed over the first conductor; a second conductor having a second opening overlapping with the first conductor is formed over the first insulator; a second insulator is formed over the second conductor; anisotropic first etching treatment is performed so that the first insulator and the second insulator have a first opening that overlaps with the first conductor and the second opening and a third opening that overlaps with the first conductor and the second opening, respectively; parts of the first insulator and the second insulator are etched by isotropic second etching treatment so that widths of the first opening and the third opening are widened; and a connection electrode that is in contact with a top surface of the first conductor and a top surface and a side surface of the second conductor is formed inside the first opening, the second opening, and the third opening.

In the above method for manufacturing an electronic device, dry etching is preferably used for each of the first etching treatment and the second etching treatment. In this case, the first etching treatment and the second etching treatment are preferably performed successively without exposure to the air with use of the same apparatus.

Alternatively, in the above method for manufacturing an electronic device, dry etching is preferably used for the first etching treatment, and wet etching is preferably used for the second etching treatment.

Another embodiment of the present invention is a semiconductor device including a transistor and a capacitor. The transistor includes an oxide, a first conductor and a second conductor that are over the oxide, a first insulator that is over the first conductor and the second conductor, a second insulator over the first insulator, a third insulator over the oxide, and a third conductor over the third insulator. The second insulator has a first opening and a second opening. The first insulator has a third opening overlapping with the first opening. The first opening and the third opening each has a region overlapping with the oxide. The third insulator and the third conductor are positioned in the first opening. The third conductor includes a region overlapping with the oxide with the third insulator therebetween. The third insulator includes a region in contact with a top surface of the oxide and a sidewall of the opening. The capacitor includes the second conductor, the first insulator over the second conductor, a fourth insulator over the first insulator, and a fourth conductor over the fourth insulator. The fourth insulator and the fourth conductor are positioned in the second opening. In a cross-sectional view of the transistor in a channel length direction, a distance between the first conductor and the second conductor is smaller than a width of the first opening.

In the above semiconductor device, it is preferable that the second opening have a region overlapping with the second conductor, that the fourth conductor include a region overlapping with the second conductor with the first insulator and the fourth insulator therebetween, and that the fourth insulator include a region in contact with a top surface of the first insulator and a sidewall of the second opening.

In the above semiconductor device, it is preferable that the third insulator include a fifth insulator and a sixth insulator over the fifth insulator, that the fourth insulator include a seventh insulator and an eighth insulator over the seventh insulator, that the fifth insulator include the same insulating material as the seventh insulator, that the sixth insulator include the same insulating material as the eighth insulator, and that the third conductor include the same conductive material as the fourth conductor.

In the above semiconductor device, side surfaces of the first conductor and the second conductor that face each other are preferably substantially perpendicular to a top surface of the oxide.

In the above semiconductor device, it is preferable that the first conductor include a fifth conductor and a sixth conductor over the fifth conductor, that the second conductor include a seventh conductor and an eighth conductor over the seventh conductor, that the fifth conductor include the same conductive material as the seventh conductor, and that the sixth conductor include the same conductive material as the eighth conductor.

In the above semiconductor device, the oxide preferably includes indium, zinc, and one or more selected from gallium, aluminum, and tin.

Another embodiment of the present invention is a method for manufacturing a semiconductor device including a transistor that includes an oxide, a first conductor to a third conductor, and a first insulator to a third insulator and a capacitor that includes the second conductor, the first insulator, a fourth insulator, and a fourth conductor. The method includes the following steps: a step of forming the first insulator to cover the oxide and a conductive layer over the oxide; a step of forming the second insulator over the first insulator; a step of forming a first opening and a second opening in the second insulator so that a top surface of the first insulator is exposed; a step of forming a mask layer to cover the second insulator and the second opening so that the mask layer has a fourth opening that has a region overlapping with the first opening and has a width smaller than a width of the first opening in a cross-sectional view in a channel length direction of the transistor; a step of etching the first insulator and the conductive layer with use of the mask layer to form a third opening in the first insulator and form the first conductor and the second conductor from the conductive layer; a step of depositing an insulating film to cover the second insulator, the first opening, and the second opening; a step of depositing a conductive film over the insulating film; and a step of removing portions of the insulating film and the conductive film that are exposed from the first opening and the second opening to form the third insulator and the third conductor in the first opening and form the fourth insulator and the fourth conductor in the second opening.

Another embodiment of the present invention is a storage device including a plurality of layers including a memory cell, where the memory cell includes a transistor and a capacitor, where the plurality of layers are stacked, where the transistor includes a first conductor functioning as one of a source electrode and a drain electrode, a second conductor functioning as the other of the source electrode and the drain electrode, and a third conductor functioning as a gate electrode, where the capacitor includes the second conductor functioning as one of a pair of electrodes and a fourth conductor functioning as the other of the pair of electrodes, where each of the plurality of layers includes a first wiring electrically connected to the third conductor and a second wiring electrically connected to the fourth conductor, where each of the plurality of layers has an opening in a region where the openings of the plurality of layers overlap with each other, where a fifth conductor is positioned in each of the openings of the plurality of layers, and where the fifth conductor is electrically connected to the first conductor in each of the plurality of layers.

In the above storage device, it is preferable that the fifth conductor include a sixth conductor and a seventh conductor over the sixth conductor, that the sixth conductor include titanium and nitrogen, and that the seventh conductor include tungsten.

In the above storage device, it is preferable that a driver circuit be included, and that the plurality of layers be provided over the driver circuit to overlap therewith.

### Effect of the Invention

According to one embodiment of the present invention, an electronic device or a semiconductor device that can be miniaturized or highly integrated can be provided. Alternatively, an electronic device or a semiconductor device that operates at high speed can be provided. Alternatively, a semiconductor device with favorable reliability can be provided. Alternatively, a semiconductor device with a small variation in electrical characteristics of transistors can be provided. Alternatively, a semiconductor device having favorable electrical characteristics can be provided. Alternatively, a semiconductor device with a high on-state current can be provided. Alternatively, a semiconductor device with low power consumption can be provided. Alternatively, a novel semiconductor device can be provided. Alternatively, a method for manufacturing a semiconductor device with small number of steps can be provided. Alternatively, a storage device including a novel semiconductor device can be provided.

Note that the description of these effects does not preclude the existence of other effects. Note that one embodiment of the present invention does not need to have all of these effects. Other effects will be apparent from the description of the specification, the drawings, the claims, and the like, and other effects can be derived from the description of the specification, the drawings, the claims, and the like.

### BRIEF DESCRIPTION OF THE DRAWINGS

FIG. 1A and FIG. 1B are diagrams illustrating a structure example of a device.

FIG. 2 is a diagram illustrating a structure example of a device.

FIG. 3A and FIG. 3B are diagrams illustrating structure examples of a device.

FIG. 4A to FIG. 4D are diagrams illustrating an example of a method for manufacturing a device.

FIG. 5A and FIG. 5B are diagrams illustrating an example of a method for manufacturing a device.

FIG. 6A and FIG. 6B are diagrams illustrating an example of a method for manufacturing a device.

FIG. 7A and FIG. 7B are diagrams illustrating an example of a method for manufacturing a device.

FIG. 8A and FIG. 8B are diagrams illustrating structure examples of a device.

FIG. 9A is a top view of a semiconductor device of one embodiment of the present invention.

FIG. 9B to FIG. 9D are cross-sectional views of the semiconductor device of one embodiment of the present invention.

FIG. 10 is a circuit diagram illustrating a configuration of a storage device of one embodiment of the present invention.

FIG. 11A to FIG. 11C are cross-sectional views of a semiconductor device of one embodiment of the present invention.

FIG. 12A and FIG. 12B are cross-sectional views of a semiconductor device of one embodiment of the present invention.

FIG. 13A and FIG. 13B are cross-sectional views of a semiconductor device of one embodiment of the present invention.

FIG. 14 is a cross-sectional view of a semiconductor device of one embodiment of the present invention.

FIG. 15A is a top view illustrating a method for manufacturing a semiconductor device of one embodiment of the present invention. FIGS. 15B to 15D are cross-sectional views illustrating the method for manufacturing a semiconductor device of one embodiment of the present invention.

FIG. 16A is a top view illustrating a method for manufacturing a semiconductor device of one embodiment of the present invention. FIGS. 16B to 16D are cross-sectional views illustrating the method for manufacturing a semiconductor device of one embodiment of the present invention.

FIG. 17A is a top view illustrating a method for manufacturing a semiconductor device of one embodiment of the present invention. FIGS. 17B to 17D are cross-sectional views illustrating the method for manufacturing a semiconductor device of one embodiment of the present invention.

FIG. 18A is a top view illustrating a method for manufacturing a semiconductor device of one embodiment of the present invention. FIGS. 18B to 18D are cross-sectional views illustrating the method for manufacturing a semiconductor device of one embodiment of the present invention.

FIG. 19A is a top view illustrating a method for manufacturing a semiconductor device of one embodiment of the present invention. FIGS. 19B to 19D are cross-sectional views illustrating the method for manufacturing a semiconductor device of one embodiment of the present invention.

FIG. 20A is a top view illustrating a method for manufacturing a semiconductor device of one embodiment of the present invention. FIGS. 20B to 20D are cross-sectional views illustrating the method for manufacturing a semiconductor device of one embodiment of the present invention.

FIG. 21A is a top view illustrating a method for manufacturing a semiconductor device of one embodiment of the present invention. FIGS. 21B to 21D are cross-sectional views illustrating the method for manufacturing a semiconductor device of one embodiment of the present invention.

FIG. 22A is a top view illustrating a method for manufacturing a semiconductor device of one embodiment of the present invention. FIGS. 22B to 22D are cross-sectional views illustrating the method for manufacturing a semiconductor device of one embodiment of the present invention.

FIG. 23A is a top view illustrating a method for manufacturing a semiconductor device of one embodiment of the present invention. FIGS. 23B to 23D are cross-sectional views illustrating the method for manufacturing a semiconductor device of one embodiment of the present invention.

FIG. 24A is a top view illustrating a method for manufacturing a semiconductor device of one embodiment of the present invention. FIGS. 24B to 24D are cross-sectional views illustrating the method for manufacturing a semiconductor device of one embodiment of the present invention.

FIG. 25A is a top view illustrating a method for manufacturing a semiconductor device of one embodiment of the present invention. FIGS. 25B to 25D are cross-sectional views illustrating the method for manufacturing a semiconductor device of one embodiment of the present invention.

FIG. 26A is a top view illustrating a method for manufacturing a semiconductor device of one embodiment of the present invention. FIGS. 26B to 26D are cross-sectional views illustrating the method for manufacturing a semiconductor device of one embodiment of the present invention.

FIG. 27A is a top view illustrating a method for manufacturing a semiconductor device of one embodiment of the present invention. FIGS. 27B to 27D are cross-sectional views illustrating the method for manufacturing a semiconductor device of one embodiment of the present invention.

FIG. 28 is a top view illustrating a microwave treatment apparatus of one embodiment of the present invention.

FIG. 29 is a schematic cross-sectional view illustrating a microwave treatment apparatus of one embodiment of the present invention.

FIG. 30 is a schematic cross-sectional view illustrating a microwave treatment apparatus of one embodiment of the present invention.

FIG. 31 is a schematic view illustrating a microwave treatment apparatus of one embodiment of the present invention.

FIG. 32A is a top view of a semiconductor device of one embodiment of the present invention.

FIG. 32B to FIG. 32D are cross-sectional views of the semiconductor device of one embodiment of the present invention.

FIG. 33A and FIG. 33B are cross-sectional views of semiconductor devices of one embodiment of the present invention.

FIG. 34A and FIG. 34B are a block diagram and a schematic view illustrating a structure example of a storage device of one embodiment of the present invention.

FIG. 35A and FIG. 35B are schematic views illustrating a structure of a storage device of one embodiment of the present invention.

FIG. 36A and FIG. 36B are layout diagrams each illustrating a structure of a storage device of one embodiment of the present invention.

FIG. 37 is a cross-sectional view of a structure of a storage device of one embodiment of the present invention.

FIG. 38 is a cross-sectional view of a structure of a storage device of one embodiment of the present invention.

FIG. 39A and FIG. 39B are schematic views of a semiconductor device of one embodiment of the present invention.

FIG. 40A and FIG. 40B are diagrams illustrating examples of electronic components.

FIG. 41A to FIG. 41E are schematic views of storage devices of one embodiment of the present invention.

FIG. 42A to FIG. 42H are diagrams illustrating electronic appliances of one embodiment of the present invention.

FIG. 43 is a diagram illustrating examples of devices for space.

FIG. 44 is a cross-sectional view of a semiconductor device of one embodiment of the present invention.

### MODE FOR CARRYING OUT THE INVENTION

Embodiments will be described below with reference to the drawings. Note that the embodiments can be implemented with many different modes, and it is readily understood by those skilled in the art that modes and details thereof can be changed in various ways without departing from the spirit and scope thereof. Thus, the present invention should not be construed as being limited to the description of the embodiments below.

In the drawings, the size, the layer thickness, or the region is exaggerated for clarity in some cases. Therefore, they are not limited to the illustrated scale. Note that the drawings schematically show ideal examples, and embodiments of the present invention are not limited to shapes or values shown in the drawings. For example, in the actual manufacturing process, a layer, a resist mask, or the like might be unintentionally reduced in size by treatment such as etching, which might not be reflected in the drawings for easy understanding. Furthermore, in the drawings, the same reference numerals are used in common for the same portions or portions having similar functions in different drawings, and repeated description thereof is omitted in some cases. The same hatching pattern is used for portions having similar functions, and the portions are not denoted by specific reference numerals in some cases.

Furthermore, especially in a top view (also referred to as a “plan view”), a perspective view, or the like, the description of some components might be omitted for easy understanding of the invention. The description of some hidden lines and the like might also be omitted.

The ordinal numbers such as “first” and “second” in this specification and the like are used for convenience and do not denote the order of steps or the stacking order of layers. Therefore, for example, the term “first” can be replaced with the term “second”, “third”, or the like as appropriate. In addition, the ordinal numbers in this specification and the like do not sometimes correspond to the ordinal numbers that are used to specify one embodiment of the present invention.

Moreover, in this specification and the like, terms for describing arrangement, such as “over” and “under”, are used for convenience for describing the positional relationship between components with reference to drawings. The positional relationship between components changes as appropriate in accordance with the direction in which the components are described. Thus, without limitation to terms described in this specification, the description can be changed appropriately depending on the situation.

In this specification and the like, the expression “X and Y are connected” means the case where X and Y are electrically connected, for example. Here, the expression “X and Y are electrically connected” means connection that enables electrical signal transmission between X and Y in the case where an object (that refers to an element such as a switch, a transistor element, or a diode, a circuit including the element and a wiring, or the like) exists between X and Y. Note that the case where X and Y are electrically connected includes the case where X and Y are directly connected. Here, the expression “X and Y are directly connected” means connection that enables electrical signal transmission between X and Y through a wiring (or an electrode) or the like, not through the above object. In other words, direct connection refers to connection that can be regarded as the same circuit diagram when represented by an equivalent circuit.

In this specification and the like, a transistor is an element having at least three terminals including a gate, a drain, and a source. In addition, the transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

Furthermore, functions of a source and a drain are sometimes interchanged with each other when transistors having different polarities are used or when the direction of a current is changed in a circuit operation, for example. Therefore, the terms “source” and “drain” can sometimes be interchanged with each other in this specification and the like.

Note that a channel length refers to, for example, a distance between a source (a source region or a source electrode) and a drain (a drain region or a drain electrode) in a region where a semiconductor (or a portion where a current flows in a semiconductor when a transistor is in an on state) and a gate electrode overlap with each other or in a channel formation region in a top view of the transistor. Note that in one transistor, channel lengths in all regions do not necessarily have the same value. In other words, the channel length of one transistor is not fixed to one value in some cases. Thus, in this specification, the channel length is any one of the values, the maximum value, the minimum value, or the average value in a channel formation region.

A channel width refers to, for example, the length of a channel formation region in a direction perpendicular to a channel length direction in a region where a semiconductor (or a portion where a current flows in a semiconductor when a transistor is in an on state) and a gate electrode overlap with each other or in a channel formation region in a top view of the transistor. Note that in one transistor, channel widths in all regions do not necessarily have the same value. In other words, the channel width of one transistor is not fixed to one value in some cases. Thus, in this specification, the channel width is any one of the values, the maximum value, the minimum value, or the average value in a channel formation region.

Note that in this specification and the like, depending on the transistor structure, a channel width in a region where a channel is actually formed (hereinafter also referred to as an “effective channel width”) is different from a channel width shown in a top view of a transistor (hereinafter also referred to as an “apparent channel width”) in some cases. For example, when a gate electrode covers a side surface of a semiconductor, the effective channel width is larger than the apparent channel width, and its influence cannot be ignored in some cases. For example, in a miniaturized transistor whose gate electrode covers a side surface of a semiconductor, the proportion of a channel formation region formed in the side surface of the semiconductor is high in some cases. In that case, the effective channel width is larger than the apparent channel width.

In such a case, the effective channel width is sometimes difficult to estimate by actual measurement. For example, estimation of an effective channel width from a design value requires assumption that the shape of a semiconductor is known. Accordingly, in the case where the shape of a semiconductor is not known accurately, it is difficult to measure the effective channel width accurately.

In this specification, the simple term “channel width” refers to an apparent channel width in some cases. Alternatively, in this specification, the simple term “channel width” refers to an effective channel width in some cases. Note that the value of a channel length, a channel width, an effective channel width, an apparent channel width, or the like can be determined, for example, by analyzing a cross-sectional TEM image.

Note that impurities in a semiconductor refer to, for example, elements other than the main components of the semiconductor. For example, an element with a concentration lower than 0.1 atomic % can be regarded as an impurity. When an impurity is contained, for example, the density of defect states in a semiconductor increases and the crystallinity decreases in some cases. In the case where the semiconductor is an oxide semiconductor, examples of an impurity which changes the characteristics of the semiconductor include Group 1 elements, Group 2 elements, Group 13 elements, Group 14 elements, Group 15 elements, and transition metals other than the main components of the oxide semiconductor; hydrogen, lithium, sodium, silicon, boron, phosphorus, carbon, and nitrogen are given as examples. Note that water also serves as an impurity in some cases. In addition, oxygen vacancies (also referred to as Vo) are formed in an oxide semiconductor in some cases by entry of impurities, for example.

Note that in this specification and the like, silicon oxynitride has a composition in which the oxygen content is higher than the nitrogen content. Moreover, silicon nitride oxide has a composition in which the nitrogen content is higher than the oxygen content. Similarly, aluminum oxynitride refers to a substance that contains more oxygen than nitrogen in its composition. Moreover, aluminum nitride oxide refers to a substance that contains more nitrogen than oxygen in its composition. Similarly, hafnium oxynitride refers to a substance that contains more oxygen than nitrogen in its composition. Moreover, hafnium nitride oxide is a substance that contains more nitrogen than oxygen in its composition.

In this specification and the like, the term “film”, the term “layer”, and the term ending with “-or” can be interchanged with each other. For example, in some cases, the term “conductive layer” and the term “insulating layer” can be interchanged, respectively, with the term “conductive film” and the term “insulating film” or with the term “conductor” and the term “insulator”.

In this specification and the like, “parallel” indicates a state where two straight lines are placed at an angle greater than or equal to −10° and less than or equal to 10°. Accordingly, the case where the angle is greater than or equal to −5° and less than or equal to 5° is also included. Furthermore, “substantially parallel” indicates a state where two straight lines are placed at an angle greater than or equal to −30° and less than or equal to 30°. Moreover, “perpendicular” indicates a state where two straight lines are placed at an angle greater than or equal to 80° and less than or equal to 100°. Accordingly, the case where the angle is greater than or equal to 85° and less than or equal to 95° is also included. Furthermore, “substantially perpendicular” indicates a state where two straight lines are placed at an angle greater than or equal to 60° and less than or equal to 120°.

In this specification and the like, a metal oxide is an oxide of a metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor can also be referred to as a transistor including a metal oxide or an oxide semiconductor.

In this specification and the like, “normally off” means that a drain current per micrometer of channel width flowing through a transistor when no potential is applied to a gate or the gate is supplied with a ground potential is lower than or equal to 1×10⁻²⁰ A at room temperature, lower than or equal to 1×10⁻¹⁸ A at 85° C., or lower than or equal to 1×10⁻¹⁶ A at 125° C.

In this specification and the like, “voltage” and “potential” can be replaced with each other as appropriate. “Voltage” refers to a potential difference from a reference potential, and when the reference potential is a ground potential, for example, “voltage” can be replaced with “potential”. Note that the ground potential does not necessarily mean 0 V. Moreover, potentials are relative values, and a potential supplied to a wiring, a potential applied to a circuit or the like, and a potential output from a circuit or the like, for example, change with a change in the reference potential.

In this specification and the like, when a plurality of components are denoted with the same reference numeral, and in particular need to be distinguished from each other, an identification sign such as “_1”, “[n]”, or “[m,n]” is sometimes added to the reference numeral.

Note that in this specification and the like, the expression “level or substantially level” is used to describe a structure in which levels from a reference surface (e.g., a flat surface such as a substrate surface) are the same in a cross-sectional view. For example, in a manufacturing process of a semiconductor device, planarization treatment (typically, CMP treatment) is performed, whereby the surface(s) of a single layer or a plurality of layers are exposed in some cases. In this case, the surfaces on which the CMP treatment is performed are at the same level from a reference surface. Note that the plurality of layers are at different levels in some cases, depending on a treatment apparatus, a treatment method, or a material of the treated surfaces at the time when the CMP treatment is performed. This case is also described with the expression “level or substantially level” in this specification and the like. For example, the expression “level or substantially level” is also used to describe the case where layers having two levels with respect to the reference surface (here, given as a first layer and a second layer) are provided to have a difference less than or equal to 20 nm between the top-surface level of the first layer and the top-surface level of the second layer.

Note that in this specification and the like, the expression “end portions are aligned or substantially aligned” means that outlines of stacked layers at least partly overlap with each other in a top view. For example, the case of processing an upper layer and a lower layer with use of the same mask pattern or mask patterns that are partly the same is included. Note that in some cases, the outlines do not exactly overlap with each other and the outline of the upper layer is positioned inward from the outline of the lower layer or the outline of the upper layer is positioned outward from the outline of the lower layer; such a case is also represented by the expression “end portions are aligned or substantially aligned”.

### Embodiment 1

In this embodiment, a structure example of a connection portion including a connection electrode of one embodiment of the present invention and an example of a method for manufacturing a device including the connection portion will be described. One embodiment of the present invention relates to an electronic device having a multilayer wiring structure connected to each other by the connection portion. In this specification and the like, an electronic device refers to a device that utilizes an electrical function.

### [Structure Example]

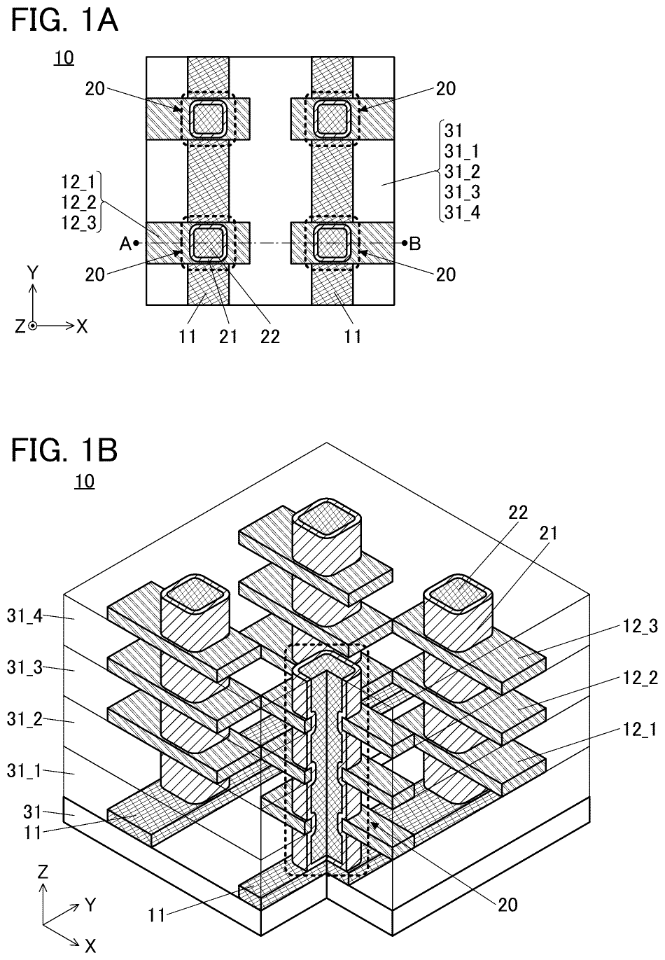

FIG. 1A is a schematic top view of a device 10 including a connection portion 20 of one embodiment of the present invention, and FIG. 1B is a schematic perspective view. The device 10 has a multilayer wiring structure in which a plurality of wiring layers are stacked. Although a structure in which four wiring layers are stacked is described here as an example, a structure including two or three wiring layers may be employed, or five or more wiring layers may be stacked. In FIG. 1A and FIG. 1B, directions X, Y, and Z are indicated by arrows.

In the device 10, a plurality of wirings 11 are provided over an insulator 31, a plurality of wirings wiring 12_1 are provided thereover with an insulator 31_1 therebetween, a plurality of wirings 12_2 are provided thereover with an insulator 31_2 therebetween, a plurality of wirings 12_3 are provided thereover with an insulator 31_3 therebetween, and an insulator 31_4 is provided thereover. Each of the insulator 31_1, the insulator 31_2, the insulator 31_3, and the insulator 31_4 functions as an interlayer insulating film.

The wiring 11 extends in the Y direction. The wiring 12_1, the wiring 12_2, and the wiring 12_3 extend in the X direction. Note that the above is an example, and the extending directions of the wiring 11, the wiring 12_1, the wiring 12_2, and the wiring 12_3 are not limited thereto. The wiring 11, the wiring 12_1, the wiring 12_2, and the wiring 12_3 can each be referred to as an electrode or a conductor.

The wiring 11, the wiring 12_1, the wiring 12_2, and the wiring 12_3 are electrically connected to each other in the connection portion 20. The connection portion 20 includes a conductor 21 and a conductor 22 each functioning as a connection electrode. The conductor 21 and the conductor 22 can be collectively referred to as a connection electrode. Although FIG. 1A and the like illustrate the case where the outlines of the top surfaces of the conductor 21 and the conductor 22 have a quadrangular shape with rounded corners, one embodiment of the present invention is not limited thereto, and various shapes such as a rectangular shape, a circular shape, and an elliptical shape can be adopted.

In FIG. 1B, the conductor 21, the conductor 22, and parts of the periphery thereof are not illustrated. The conductor 21 is provided along the inner walls of openings in the insulator 31_1, the insulator 31_2, the insulator 31_3, the insulator 31_4, the wiring 12_1, the wiring 12_2, and the wiring 12_3 to cover the inner walls. The bottom portion of the conductor 21 is provided to be in contact with part of the top surface of the wiring 11. The conductor 22 is provided to be embedded in a depressed portion of the conductor 21.

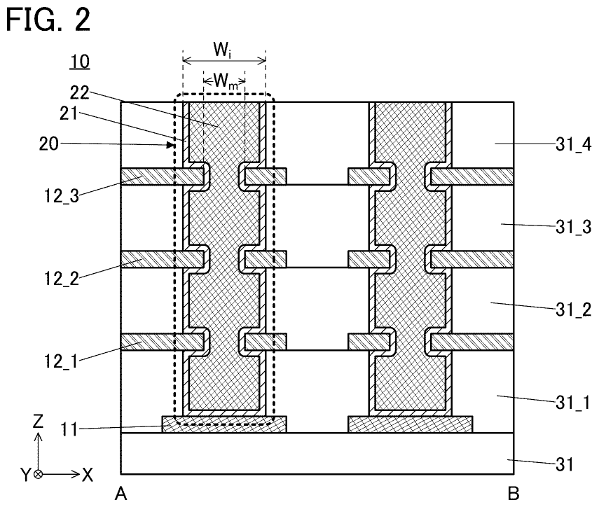

FIG. 2 is a schematic cross-sectional view taken along dashed-dotted line A-B in FIG. 1A. In FIG. 2, two connection portions 20 are placed side by side to be clearly shown.

The wiring 12_3 is provided with an opening in a region overlapping with the wiring 11. The wiring 12_3 has a portion of the opening with a width Wₘ. In addition, the insulator 31_4 placed directly over the wiring 12_3 is provided with an opening in a region overlapping with the wiring 11. The insulator 31_4 has a portion of the opening with a width Wᵢ. Here, when the width Wᵢ of the opening in the insulator 31_4 is larger than the width Wₘ of the opening in the wiring 12_3, a region not covered with the insulator 31_4 can be formed in part of the top surface of the wiring 12_3. Furthermore, the conductor 21 is provided along the inner walls of the openings in the insulator 31_4 and the wiring 12_3, whereby not only the side surface but also the top surface of the wiring 12_3 can be in contact with the conductor 21; accordingly the contact resistance of the wiring 12_3 and the conductor 21 can be reduced favorably. Moreover, the conductor 21 is preferably in contact with the bottom surface of the wiring 12_3 as well as the top surface and the side surface thereof.

Similarly, the wiring 12_2 has a portion of the opening with a smaller width than the insulator 31_3, so that the top surface of the wiring 12_2 has part that is not covered with the insulator 31_3 but in contact with the conductor 21. The wiring 12_1 has a portion of the opening with a smaller width than the insulator 31_2, so that the top surface of the wiring 12_1 has part that is not covered with the insulator 31_2 but in contact with the conductor 21.

In terms of the shape of the conductor 22, the conductor 22 has such a shape that a portion with a large diameter and a portion with a small diameter are alternately stacked in the thickness direction. The number of portions with a small diameter corresponds to the number of wirings stacked. The portion with a small diameter can also be referred to as a thin portion, a depressed portion, or a narrowed portion.

Since the conductor 21 is provided between the conductor 22 and the insulators 31_1 to 31_4, the wirings 12_1 to 12_3, and the wiring 11, the external shape of the conductor 21 is such that the conductor 22 is increased by the thickness of the conductor 21. In other words, it can be said that the external shape of the conductor 21 is substantially the same as the shape formed by the inner walls of the openings in the insulators 31_1 to 31_4 and the wirings 12_1 to 12_3. When the conductor 21 is formed by a method enabling deposition of a film with higher step coverage than the wirings 12_1 to be 12_3, the conductor 21 can be formed to cover the openings in the insulators 31_1 to 31_4 and the wirings 12_1 to 12_3. Although the conductor 21 is illustrated to have a uniform thickness in FIG. 2 and the like, a thin portion or a portion where the conductor 21 is not deposited may be provided at portions where deposition is obstructed by the wirings 12_1 to 12_3.

As described above, it is preferable that the connection electrode connecting a plurality of wirings as the wirings 12_1 to 12_3 that are stacked be in contact with not only the side surfaces but also the top surfaces of the wirings 12_1 to 12_3 in which case the contact resistance between the connection electrode and the wirings is reduced. In addition, the connection electrode is in contact with the bottom surfaces of the wirings 12_1 to 12_3 as well as the side surfaces and the top surfaces thereof in which case the contact resistance can be reduced more effectively. Moreover, a plurality of connection electrodes each having a narrow portion are provided to penetrate the stacked structure, in which case the mechanical strength of a device using such connection electrodes can be enhanced, the yield of manufacturing process can be increased, and the reliability of the device can be improved.

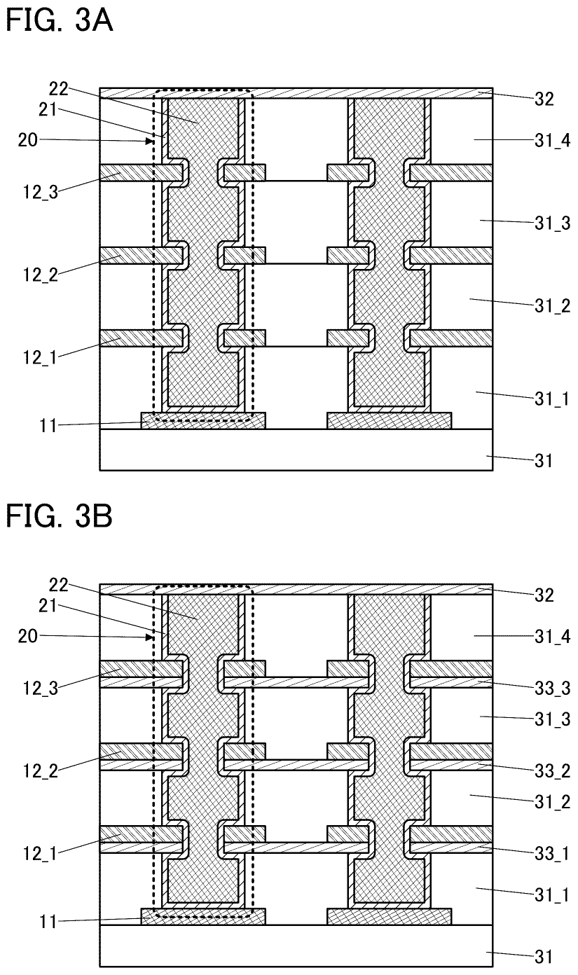

In FIG. 3A, an insulator 32 is provided over the insulator 31_4. The insulator 32 functions as a protective layer and has a function of preventing diffusion of impurities from the outside into the device. For example, in the case of a device including an oxide semiconductor, a film in which water and hydrogen are less likely to diffuse (also referred to as having a barrier property) is used as the insulator 32 because water or hydrogen affects electrical characteristics of the device including an oxide semiconductor or the like.

The insulator 32 is provided to cover the top surfaces of the conductor 21 and the conductor 22 and has a function of not only insulating the top surfaces but also protecting the top surfaces from corrosion.

In FIG. 3B, insulators 33_1, 33_2, and 33_3 are included in addition to the insulator 32. The insulator 33_1 is provided between the insulator 31_1 and the insulator 31_2, and the wiring 12_1 is provided over the insulator 33_1. Similarly, the insulator 33_2 is provided between the insulator 31_2 and the insulator 31_3, and the insulator 33_3 is provided between the insulator 31_3 and the insulator 31_4.

The insulators 33_1 to 33_3 function as protective layers, like the insulator 32. Thus, in the case of manufacturing a device having a multilayer structure, the structure below the protective layer can be protected from entry of impurities and damage generated in the manufacturing process of the structure above the protective layer.

The connection electrode of one embodiment of the present invention and connection portion including the connection electrode can be used for electronic devices such as devices using a variety of electronic circuits (including semiconductor devices). Examples of the electronic devices include storage devices such as a flash memory, a DRAM (Dynamic RAM), an SRAM (Static RAM), an MRAM (Magnetoresistive Random Access Memory), a PRAM (Phase change RAM), a ReRAM (Resistive RAM), an FeRAM (Ferroelectric RAM), a DOSRAM (Dynamic Oxide Semiconductor RAM) (registered trademark), and a NOSRAM (Nonvolatile Oxide Semiconductor RAM) (registered trademark). Other examples include a microprocessor such as a CPU (Central Processing Unit), a GPU (Graphics Processing Unit), a TPU (Tensor Processing Unit), an NPU (Neural Processing Unit), and a DSP (Digital Signal Processor) and a PLD (Programmable Logic Device) such as an FPGA (Field Programmable Gate Array) and an FPAA (Field Programmable Analog Array). Other examples can include a sensor device having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays. Other examples can include a display device such as an OLED (Organic Light Emitting Diode) display and an LED (Light Emitting Diode) display and an image capturing device such as an image sensor. Other examples can include a driver circuit for driving a device using any of a variety of electronic circuits described above and a peripheral circuit such as a signal generation circuit, a control circuit, a timing circuit, a power supply circuit, an interface circuit, and a converter circuit.

### [Manufacturing Method Example]

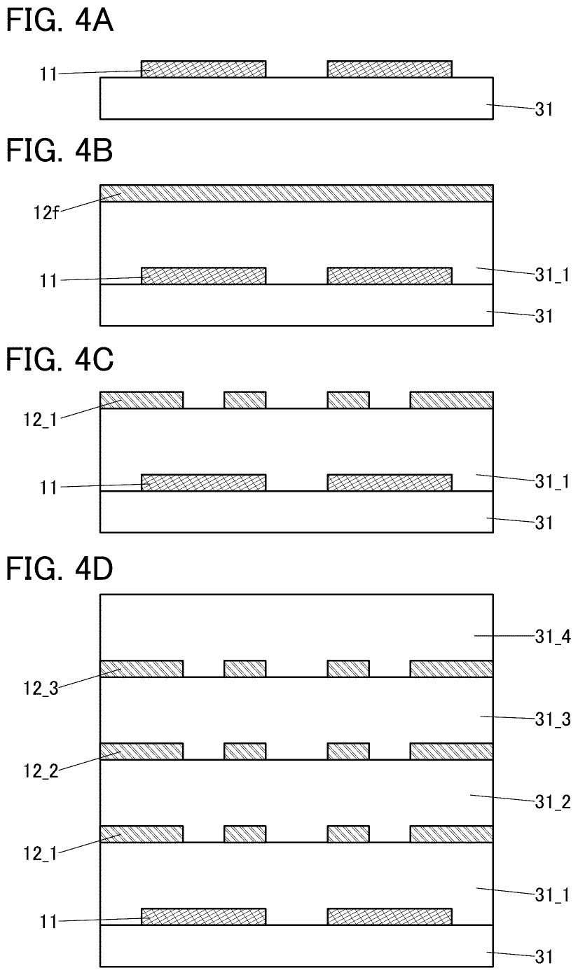

An example of a method for manufacturing a device including a connection electrode of one embodiment of the present invention will be described below with reference to drawings. Here, description is made using the display device 10 illustrated in FIG. 1A, FIG. 1B, and FIG. 2 as an example. FIG. 4A to FIG. 6B are each a schematic cross-sectional view of a step in a manufacturing method described below.

Note that thin films included in the device (insulating films, semiconductor films, conductive films, and the like) can be formed by a sputtering method, a chemical vapor deposition (CVD) method, a vacuum evaporation method, a pulsed laser deposition (PLD) method, an atomic layer deposition (ALD) method, or the like. Examples of the CVD method include a plasma-enhanced chemical vapor deposition (PECVD: Plasma Enhanced CVD) method and a thermal CVD method. An example of the thermal CVD method is a metal organic chemical vapor deposition (MOCVD: Metal Organic CVD) method. Examples of the ALD method include a thermal ALD method and a plasma-enhanced atomic layer deposition (PEALD: Plasma Enhanced ALD) method.

Alternatively, the thin films included in the device (insulating films, semiconductor films, conductive films, and the like) can be formed by a method such as spin coating, dipping, spray coating, ink-jetting, dispensing, screen printing, offset printing, a doctor knife method, a slit coater, a roll coater, a curtain coater, and a knife coater.

The thin films included in the device can be processed by a photolithography method or the like. Besides, a nanoimprinting method, a sandblasting method, a lift-off method, or the like may be used to process the thin films. Alternatively, island-shaped thin films may be directly formed by a deposition method using a shielding mask such as a metal mask.

There are two typical examples of a photolithography method. In one of the methods, a resist mask is formed over a thin film that is to be processed, the thin film is processed by etching or the like, and then the resist mask is removed. In the other method, a photosensitive thin film is formed and then processed into a desired shape by light exposure and development.

As light used for light exposure in a photolithography method, for example, an i-line (with a wavelength of 365 nm), a g-line (with a wavelength of 436 nm), an h-line (with a wavelength of 405 nm), or light in which these lines are mixed can be used. Alternatively, ultraviolet light, KrF laser light (wavelength: 248 nm), ArF laser light (wavelength: 193 nm), or the like can be used. Light exposure may be performed by liquid immersion exposure technique. For light used for the light exposure, extreme ultraviolet (EUV) light with a wavelength greater than or equal to 10 nm and less than or equal to 100 nm or X-rays may be used. Furthermore, instead of the light used for the light exposure, an electron beam can also be used. Extreme ultraviolet light, X-rays, or an electron beam is preferably used, in which case extremely minute processing can be performed. Note that a photomask is not needed when light exposure is performed by scanning with a beam such as an electron beam.

For etching of the thin films, a dry etching method, a wet etching method, a sandblast method, or the like can be used.

First, the insulator 31 is formed over a substrate (not illustrated), and the wiring 11 is formed over the insulator 31 (FIG. 4A).

As the substrate, a substrate having at least heat resistance high enough to withstand heat treatment performed later can be used. In the case where an insulating substrate is used as the substrate, a glass substrate, a quartz substrate, a sapphire substrate, a ceramics substrate, an organic resin substrate, or the like can be used. Alternatively, a single crystal semiconductor substrate or a polycrystalline semiconductor substrate using silicon, silicon carbide, or the like as a material, a compound semiconductor substrate of silicon germanium or the like, or a semiconductor substrate such as an SOI substrate can be used.

The insulator 31 functions as an interlayer insulating layer or a base insulating layer. As the insulator 31, for example, an inorganic insulating film with relatively low permittivity, such as silicon oxide, silicon oxynitride, silicon oxide to which fluorine is added, silicon oxide to which carbon is added, silicon oxide to which carbon and nitrogen are added, or porous silicon oxide can be used.

As the wiring 11, a variety of conductive materials can be used in accordance with required electrical characteristics. For example, it is possible to use a single layer or stacked layers of any of conductive films such as a metal film, an alloy film, a conductive oxide film, and a conductive nitride film. Examples of the metal material that can be used for the wiring 11 include aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum. Alternatively, a nitride of the above metal can also be used.

The wiring 11 can be formed in such a manner that a conductive film to be the wiring 11 is formed over the insulator 31 and then processed by a photolithography method.

Next, the insulator 31_1 is formed to cover the insulator 31 and the wiring 11. A material similar to that for the insulator 31 can be used for the insulator 31_1.

After the insulator 31_1 is formed, planarization treatment is preferably performed. For the planarization treatment, a CMP (chemical mechanical polishing) method can be typically used.

Next, a conductive film 12f is formed over the insulator 31_1 (FIG. 4B), and the conductive film 12f is processed by a photolithography method, whereby the wiring 12_1 is formed (FIG. 4C). For the conductive film 12f, a conductive material that can be used for the wiring 11 can be used.

Next, the insulator 31_2, the wiring 12_2, the insulator 31_3, the wiring 12_3, and the insulator 31_4 are formed by methods similar to those for the insulator 31_1 and the wiring 12_1 (FIG. 4D).

Note that in the case where five or more wirings are stacked, the insulator and the wiring are alternately stacked by a method similar to the above.

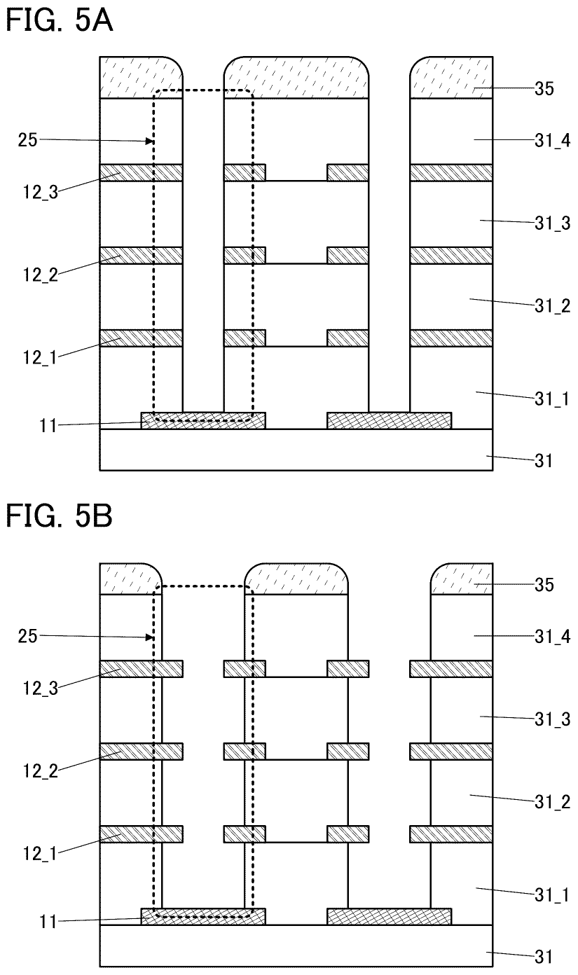

Next, a resist mask 35 is formed over the insulator 31_4, and parts of the insulators 31_1 to 31_4 are etched by anisotropic etching, so that an opening 25 reaching the wiring 11 is formed (FIG. 5A). Here, the opening width of the opening 25 (i.e., the opening width of the resist mask 35) can be substantially the same as the opening widths of the wirings 12_1 to wiring 12_3.

Then, parts (side surfaces) of the insulators 31_1 to 31_4 are etched by an isotropic etching method, so that the opening widths of the insulators 31_1 to 31_4 inside the opening 25 are widened (FIG. 5B). At this time, with use of conditions where the wiring 12_1 to the wiring 12_3 are not etched or are less likely to be etched, the opening widths of the insulators 31_1 to 31_4 can be widened while the opening widths of the wiring 12_1 to the wiring 12_3 are maintained.

Anisotropic etching and isotropic etching are preferably performed successively without exposure to the air with the same etching apparatus under different conditions. For example, in the case where a dry etching method is used for both anisotropic etching and isotropic etching, switching from anisotropic etching to isotropic etching can be performed by changing one or more of the conditions such as power supply, bias power, a flow rate of an etching gas, an etching gas species, and a pressure.

Alternatively, anisotropic etching and isotropic etching may be performed by different etching methods. For example, a dry etching method can be used for the anisotropic etching and a wet etching method can be used for the isotropic etching.

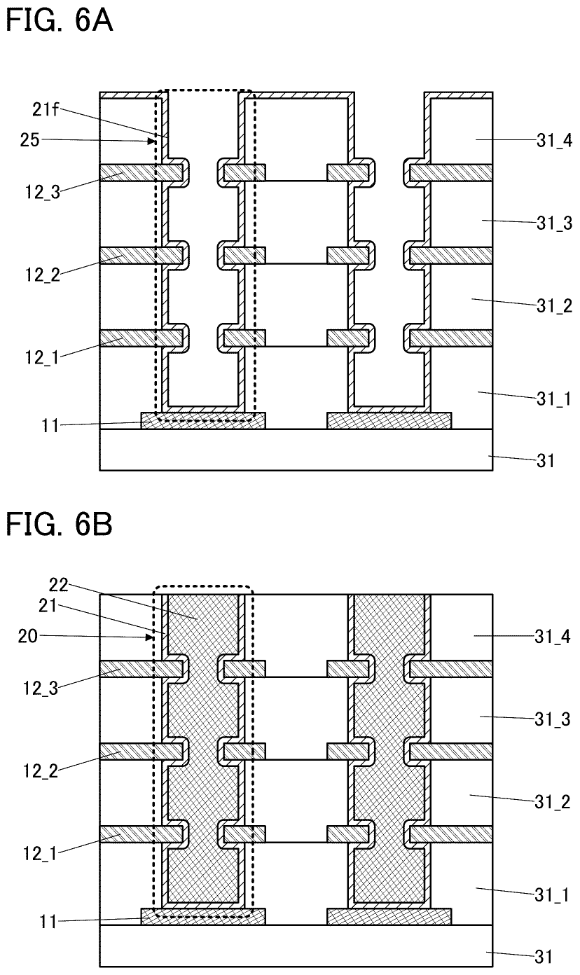

Next, a conductive film 21f is formed to cover the inner wall of the opening 25 and the top surface of the insulator 31_4 (FIG. 6A). The conductive film 21f is preferably formed by a deposition method providing a film with high step coverage. As a specific example, a deposition method such as a thermal ALD method or a PEALD method is preferably used. The thermal ALD method is preferable because of its capability of forming a film with extremely high step coverage. The PEALD method is preferable because of its capability of forming a film at low temperatures, in addition to its capability of forming a film with high step coverage.

Next, a conductive film is deposited to fill the inside of the opening 25, and planarization treatment is performed until the top surface of the insulator 31_4 is exposed, whereby the connection portion 20 including the conductor 21 and the conductor 22 can be formed (FIG. 6B).

For the conductor 21 and the conductor 22, the above-described conductive material that can be used for the wiring 11 can be used.

In particular, a metal nitride such as tantalum nitride, tungsten nitride, or titanium nitride is preferably used for the conductor 21. Such a film containing a metal nitride has a barrier property against water, hydrogen, and the like and thus is suitable for a semiconductor device using an oxide semiconductor, where electrical characteristics change due to water and hydrogen. Alternatively, a stacked film of the film containing the above metal nitride and a film containing tantalum, tungsten, titanium, molybdenum, aluminum, copper, a molybdenum-tungsten alloy, or the like may be used.

The conductive film to be the conductor 22 is preferably deposited by a deposition method with high embeddability in a depressed portion. Specifically, a CVD method such as a thermal CVD method or an MOCVD method is preferably used.

For the conductor 22, it is particularly preferable to use a conductive material containing one or more of tantalum, tungsten, titanium, molybdenum, aluminum, and copper.

Through the above steps, the connection portion 20 and a device including the connection portion 20 can be manufactured.

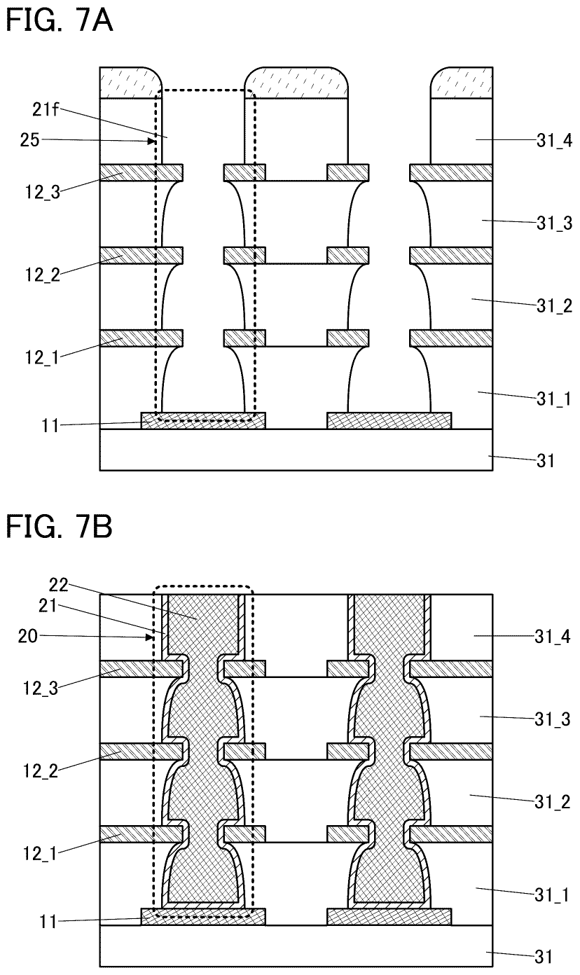

Note that in the step of forming the opening 25, the shape illustrated in FIG. 5B is an ideal shape formed by isotropic etching; however, depending on the etching conditions, the side surfaces of the insulators 31_1 to insulator 31_4 are sometimes three-dimensional curved surfaces such as a concave surface or a convex surface. For example, FIG. 7A and FIG. 7B each illustrate an example in which the insulator 31_1 to the insulator 31_3 are each processed into a shape such that the opening diameter is increased toward the lower portion. As illustrated in FIG. 7B, in the case where the side surfaces of the insulator 31_1 to the insulator 31_3 have concave surfaces, the conductor 22 has portions with a convex surface. Although not illustrated, in the case where the side surfaces of the insulator 31_1 to the insulator 31_3 have convex surfaces, the conductor 22 has portions with a concave side surface.

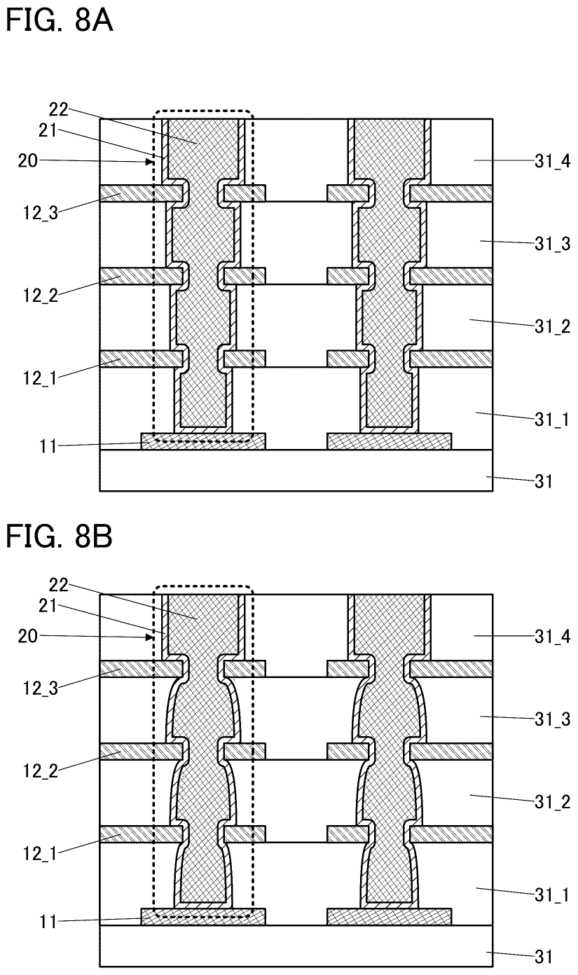

In the case where the opening 25 has a deep depth, the width of the opening may be narrowed from the upper portion toward the lower portion. FIG. 8A and FIG. 8B each illustrate an example of a cross-sectional shape in such a case. FIG. 8A corresponds to a variation of the structure illustrated in FIG. 2, and FIG. 8B corresponds to a variation of the structure illustrated in FIG. 7B. For example, in each of FIG. 8A and FIG. 8B, the width of the opening in the insulator 31_1 is smaller than that in the insulator 31_2, and the conductor 22 at a portion inside the opening in the insulator 31_1 has a smaller width (the thickness or diameter) than that at a portion inside the opening in the insulator 31_2.

The above is the description of the manufacturing method example.

At least part of this embodiment can be implemented in combination with the other embodiments described in this specification as appropriate.

### Embodiment 2

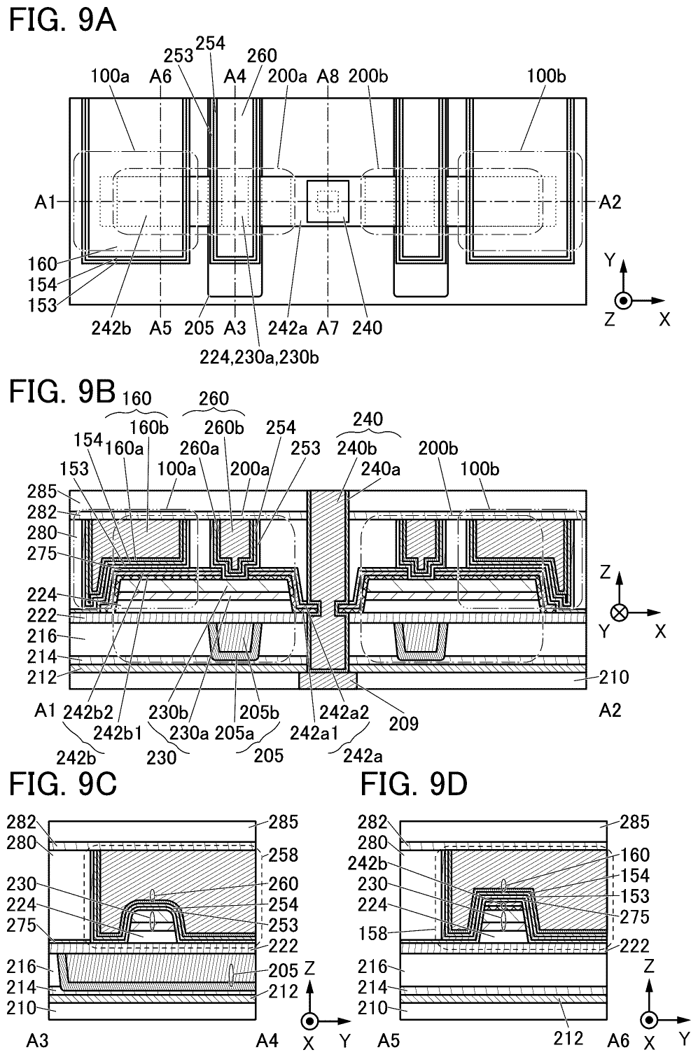

A semiconductor device including a connection electrode and a connection portion of one embodiment of the present invention will be described below. In this embodiment, an example of a semiconductor device of one embodiment of the present invention and a manufacturing method thereof are described with reference to FIG. 9A to FIG. 33B and FIG. 44. The semiconductor device of one embodiment of the present invention includes a transistor and a capacitor.

### <Structure Example of Semiconductor Device>

A structure of a semiconductor device including a transistor and a capacitor is described with reference to FIG. 9. FIG. 9A to FIG. 9D are a top view and cross-sectional views of a semiconductor device including a transistor 200a, a transistor 200b, a capacitor 100a, and a capacitor 100b. FIG. 9A is the top view of the semiconductor device. FIG. 9B to FIG. 9D are cross-sectional views of the semiconductor device. Here, FIG. 9B is a cross-sectional view of a portion indicated by a dashed-dotted line A1-A2 in FIG. 9A and also is a cross-sectional view of the transistor 200a and the transistor 200b in the channel length direction. FIG. 9C is a cross-sectional view of a portion indicated by dashed-dotted line A3-A4 in FIG. 9A, and is a cross-sectional view of the transistor 200a in the channel width direction. FIG. 9D is a cross-sectional view of a portion indicated by the dashed-dotted line A5-A6 in FIG. 9A. Note that for clarity of the drawing, some components are not illustrated in the top view of FIG. 9A.

The X direction illustrated in FIG. 9A is parallel to the channel length direction of the transistor 200a and the channel length direction of the transistor 200b, the Y direction is perpendicular to the X direction, and the Z direction is perpendicular to the X direction and the Y direction. Note that the X direction, the Y direction, and the Z direction illustrated in FIG. 9A are also illustrated in FIG. 9B to FIG. 9D.

The semiconductor device of one embodiment of the present invention includes an insulator 214 over a substrate (not illustrated); the transistor 200a, the transistor 200b, the capacitor 100a, and the capacitor 100b over the insulator 214; an insulator 280 over an insulator 275 provided in the transistor 200a and the transistor 200b; an insulator 282 over the capacitor 100a, the capacitor 100b, and the insulator 280; an insulator 285 over the insulator 282; and a conductor 240 (a conductor 240a and a conductor 240b). Each of the insulator 214, the insulator 280, the insulator 282, and the insulator 285 functions as an interlayer film. As illustrated in FIG. 9B, at least parts of the transistor 200a, the transistor 200b, the capacitor 100a, and the capacitor 100b are provided to be embedded in the insulator 280.

Here, each of the transistor 200a and the transistor 200b includes an oxide 230 functioning as a semiconductor layer, a conductor 260 functioning as a first gate (also referred to as top gate) electrode, a conductor 205 functioning as a second gate (also referred to as back gate) electrode, a conductor 242a functioning as one of a source electrode and a drain electrode, and a conductor 242b functioning as the other of the source electrode and the drain electrode. An insulator 253 and an insulator 254 functioning as a first gate insulator are also included. An insulator 222 and an insulator 224 functioning as a second gate insulator are also included. Note that the gate insulator is also referred to as a gate insulating layer or a gate insulating film in some cases.

Note that the transistor 200a and the transistor 200b have the same structure; thus, in the following description common to the transistor 200a and the transistor 200b, the alphabets are omitted from the reference numerals and the term “transistor 200” is used in some cases.

The first gate electrode and the first gate insulating film are placed inside an opening 258 formed in the insulator 280 and the insulator 275. That is, the conductor 260, the insulator 254, and the insulator 253 are placed inside the opening 258.

Each of the capacitor 100a and the capacitor 100b includes the conductor 242b functioning as a lower electrode; the insulator 275, an insulator 153, and an insulator 154 functioning as a dielectric; and a conductor 160 functioning as an upper electrode. In other words, each of the capacitor 100a and the capacitor 100b forms a MIM (Metal-Insulator-Metal) capacitor.

Note that the capacitor 100a and the capacitor 100b have the same structure; thus, in the following description common to the capacitor 100a and the capacitor 100b, the alphabets added to the reference numerals are omitted and the term “capacitor 100” is used in some cases.

The upper electrode and part of the dielectric of the capacitor 100 are positioned in an opening 158 formed in the insulator 280. That is, the conductor 160, the insulator 154, and the insulator 153 are positioned inside the opening 158.

The semiconductor device of one embodiment of the present invention also includes a conductor 240 (the conductor 240a and the conductor 240b) electrically connected to the transistor 200 and functioning as a plug. The conductor 240 includes a region in contact with the conductor 242a.

The semiconductor device of one embodiment of the present invention includes an insulator 210 and a conductor 209 between the substrate (not illustrated) and the insulator 214. The conductor 209 is provided to be embedded in the insulator 210. The conductor 209 includes a region in contact with the conductor 240.

The semiconductor device of one embodiment of the present invention may include an insulator 212 over the insulator 210 and the conductor 209 and below the insulator 214.

The semiconductor device including the transistor 200 and the capacitor 100 described in this embodiment can be used as a memory cell of the storage device. In this case, the conductor 240 is electrically connected to a sense amplifier in some cases. Here, as illustrated in FIG. 9A, at least part of the capacitor 100 is provided to overlap with the oxide 230 included in the transistor 200. Thus, since the capacitor 100 can be provided without increasing the area occupied by the capacitor 100 in the plan view, the semiconductor device of this embodiment can be miniaturized or highly integrated.

The semiconductor device described in this embodiment has a line-symmetric structure with respect to dashed-dotted line A7-A8 illustrated in FIG. 9A. A conductor 242a serves as one of a source electrode and a drain electrode of the transistor 200a and one of a source electrode and a drain electrode of the transistor 200b. Accordingly, when the connection of the two transistors, the two capacitors, and the plug have the above-described structure, a semiconductor device that can be miniaturized or highly integrated can be provided.

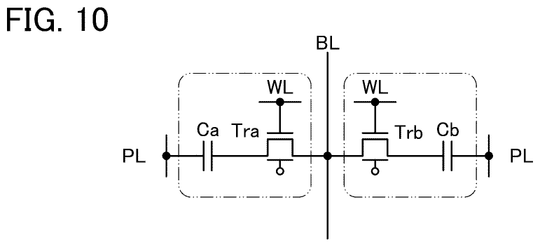

FIG. 10 shows a circuit diagram using the semiconductor device described in this embodiment as a storage device. A semiconductor device including the transistor 200a and the capacitor 100a can be used as a memory cell of the storage device. A semiconductor device including the transistor 200b and the capacitor 100b can be used as a memory cell of the storage device.

As illustrated in FIG. 10, the semiconductor device illustrated in FIG. 9A to FIG. 9D can be referred to as a storage device composed of two memory cells. One of the memory cells includes a transistor Tra and a capacitor Ca. The other memory cell includes a transistor Trb and a capacitor Cb.

Here, the transistor Tra, the transistor Trb, the capacitor Ca, and the capacitor Cb correspond to the transistor 200a, the transistor 200b, the capacitor 100a, and the capacitor 100b, respectively.

In the one of the memory cell, one of a source and a drain of the transistor Tra is electrically connected to a wiring BL. The other of the source and the drain of the transistor Tra is electrically connected to one of a pair of electrodes of the capacitor Ca. A gate of the transistor Tra is connected to a wiring WL. The other of the pair of electrodes of the capacitor Ca is connected to a wiring PL.

In the other memory cell, one of a source and a drain of the transistor Trb is electrically connected to the wiring BL. The other of the source and the drain of the transistor Trb is electrically connected to one of a pair of electrodes of the capacitor Cb. A gate of the transistor Trb is connected to the wiring WL. The other of the pair of electrodes of the capacitor Cb is connected to a wiring PL.

Note that the memory cell will be described in detail in a later embodiment.

### [Transistor 200]

As illustrated in FIG. 9A to FIG. 9D, the transistor 200 includes an insulator 216 over the insulator 214, the conductor 205 (the conductor 205a and the conductor 205b) placed to be embedded in the insulator 216, the insulator 222 over the insulator 216 and the conductor 205, the insulator 224 over the insulator 222, an oxide 230a over the insulator 224, an oxide 230b over the oxide 230a, the conductor 242a (a conductor 242a1 and a conductor 242a2) and the conductor 242b (a conductor 242b1 and a conductor 242b2) over the oxide 230b, the insulator 253 over the oxide 230b, the insulator 254 over the insulator 253, the conductor 260 (a conductor 260a and a conductor 260b) that is placed over the insulator 254 and partly overlaps with the oxide 230b, and the insulator 275 placed over the insulator 222, the insulator 224, the oxide 230a, the oxide 230b, the conductor 242a, and the conductor 242b.

In this specification and the like, the oxide 230a and the oxide 230b are collectively referred to as an oxide 230 in some cases. The conductor 242a and the conductor 242b are collectively referred to as a conductor 242 in some cases.

The opening 258 reaching the oxide 230b is provided in the insulator 280 and the insulator 275. That is, the opening 258 includes a region overlapping with the oxide 230b. It can also be said that the insulator 275 includes an opening overlapping with the opening included in the insulator 280. That is, the opening 258 includes an opening provided in the insulator 280 and an opening provided in the insulator 275. The insulator 253, the insulator 254, and the conductor 260 are positioned in the opening 258. That is, the conductor 260 includes a region overlapping with the oxide 230b with the insulator 253 and the insulator 254 therebetween. The conductor 260, the insulator 253, and the insulator 254 are provided between the conductor 242a and the conductor 242b in the channel length direction of the transistor 200. The insulator 254 includes a region in contact with the side surface of the conductor 260 and a region in contact with the bottom surface of the conductor 260. Note that as illustrated in FIG. 9C, the opening 258 reaches the insulator 222 in a region not overlapping with the oxide 230.

The oxide 230 preferably includes the oxide 230a placed over the insulator 224 and the oxide 230b placed over the oxide 230a. With the oxide 230a positioned under the oxide 230b, diffusion of impurities from components formed below the oxide 230a into the oxide 230b can be inhibited.

Although a structure in which two layers, the oxide 230a and the oxide 230b, are stacked as the oxide 230 in the transistor 200 is described, the present invention is not limited thereto. For example, the oxide 230 may be provided as a single layer of the oxide 230b or as stacked-layer structure of three or more layers, or the oxide 230a and the oxide 230b may each have a stacked-layer structure.

The conductor 260 functions as a first gate electrode and the conductor 205 functions as a second gate electrode. The insulator 253 and the insulator 254 function as a first gate insulator, and the insulator 222 and the insulator 224 function as a second gate insulator. The conductor 242a functions as one of a source electrode and a drain electrode, and the conductor 242b functions as the other of the source electrode and the drain electrode. At least part of a region of the oxide 230 overlapping with the conductor 260 functions as a channel formation region.

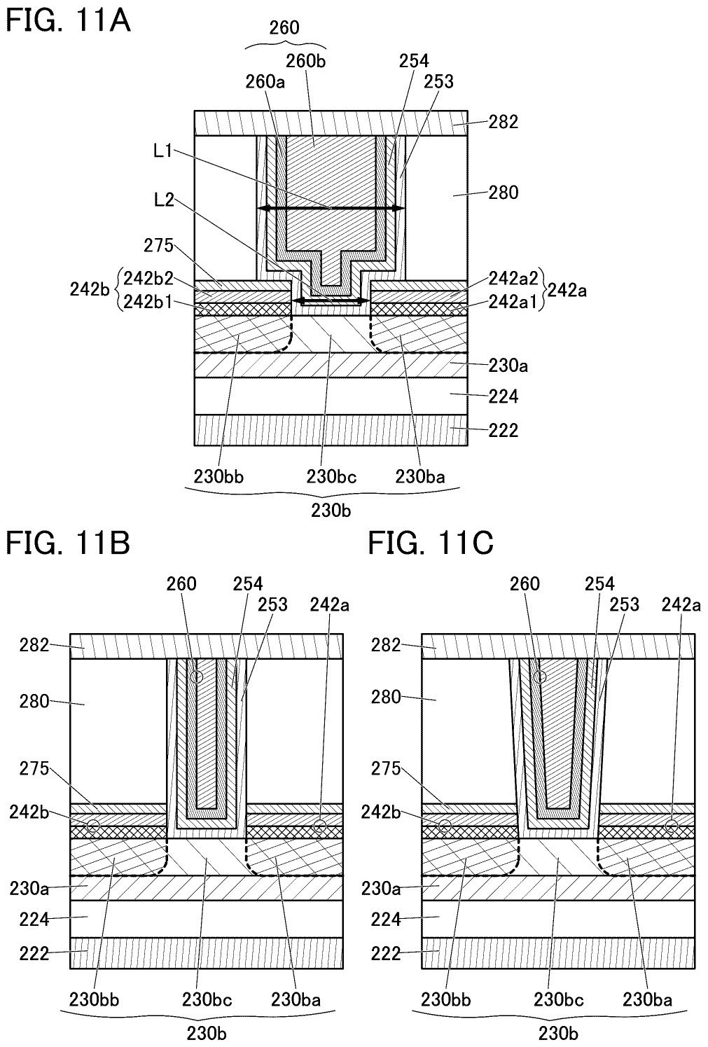

FIG. 11A is an enlarged view of the vicinity of the channel formation region in FIG. 9B. As illustrated in FIG. 11A, in the cross-sectional view of the transistor 200 in the channel length direction, a distance L2 between the conductor 242a and the conductor 242b is preferably smaller than the width of the first opening 258. Here, the width of the opening 258 corresponds to a distance L1 between an interface between the insulator 280 and the insulator 253 on the conductor 242a side and an interface between the insulator 280 and the insulator 253 on the conductor 242b side, which is illustrated in FIG. 11A. Although the description is made later, in this embodiment, channel etching for forming the conductor 242a and the conductor 242b is performed after the formation of the opening 258. With such a structure, the distance L2 between the conductor 242a and the conductor 242b can be relatively easily made an extremely small value (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm). Since the conductor 260 includes a region having the distance L1 larger than the distance L2, a reduction in the conductivity of the conductor 260 positioned in the region having the distance L1 can be inhibited and the conductor 260 can function as a wiring.

As illustrated in FIG. 11A, in a cross-sectional view of the transistor 200 in the channel length direction, the width of the opening in the insulator 280 ranged in the opening 258 is equal to the distance L1, and the width of the opening in the insulator 275 ranged in the opening 258 is equal to the distance L2.

As illustrated in FIG. 11A and FIG. 9C, the opening 258 can be also regarded as having a shape in which part of a structure body including the insulator 224, the oxide 230, the conductor 242, and the insulator 275 protrudes in an opening having the insulator 222 as its bottom surface and the insulator 280 as its side surface. Furthermore, in the structure body including the insulator 224, the oxide 230, the conductor 242, and the insulator 275, a region of the oxide 230 sandwiched between the conductor 242a and the conductor 242b can be regarded as being exposed.

As illustrated in FIG. 11A and FIG. 9C, the insulator 253 is provided in contact with the bottom surface and the inner wall (also referred to as a sidewall) of the opening 258. Thus, the insulator 253 is in contact with at least parts of the top surface of the insulator 222, the side surface of the insulator 224, the side surface of the oxide 230a, the side surface and the top surface of the oxide 230b, the side surfaces of the conductor 242a and the conductor 242b, the side surface and the top surface of the insulator 275, the side surface of the insulator 280, and the bottom surface of the insulator 254. The insulator 254 and the conductor 260 are stacked over the insulator 253. Thus, the insulator 253, the insulator 254, and the conductor 260 are provided to cover the parts of the conductor 242 and the insulator 275 that project in the opening 258.

A channel formation region is formed in a region of the distance L2 in the oxide 230b. Thus, the channel formation region of the transistor 200 is extremely minute. Accordingly, the transistor 200 can have a higher on-state current and higher frequency characteristics.

Note that the shape of the opening 258 is not limited to the shape illustrated in FIG. 11A. As illustrated in FIG. 11B, in the opening 258, the distance L1 and the distance L2 may be equal. At this time, as illustrated in FIG. 11i, the side surface of the conductor 242a and the side surface of the insulator 275 in the opening 258 are substantially aligned with the side surface of the insulator 280. The side surface of the conductor 242b and the side surface of the insulator 275 in the opening 258 are substantially aligned with the side surface of the insulator 280. With this structure, the manufacturing process of the semiconductor device can be simplified and the productivity can be improved. Moreover, a plurality of the transistors 200 can be provided with high density in a small area.

Although FIG. 11B illustrates a structure in which the sidewall of the opening 258 is substantially perpendicular to the top surface of the insulator 222, the present invention is not limited thereto. As illustrated in FIG. 11C, the sidewall of the opening 258 may have a tapered shape. With such tapered shapes of the side surfaces of the opening 258, the coverage with the insulator 253 and the like can be improved in a later step, so that defects such as a void can be reduced.

In this specification and the like, a tapered shape indicates a shape in which at least part of a side surface of a component is inclined to a substrate surface. For example, the tapered shape preferably includes a region where the angle formed between the inclined side surface and the substrate surface (hereinafter, the angle is sometimes referred to as a taper angle) is less than 90°. Note that the side surface of the component and the substrate surface are not necessarily completely flat and may be substantially flat with a slight curvature or substantially flat with slight unevenness.

As illustrated in FIG. 11A, the oxide 230b includes a region 230bc functioning as the channel formation region of the transistor 200 and a region 230ba and a region 230bb that are provided to sandwich the region 230bc and function as a source region and a drain region. At least part of the region 230bc overlaps with the conductor 260. In other words, the region 230bc is provided in a region between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than the region 230ba and the region 230bb, and thus is a high-resistance region with a low carrier concentration. Thus, the region 230bc can be regarded as being i-type (intrinsic) or substantially i-type.

The region 230ba and the region 230bb functioning as the source region and the drain region include a large amount of oxygen vacancies or have a high concentration of an impurity such as hydrogen, nitrogen, or a metal element, and thus are each a low-resistance region with an increased carrier concentration. In other words, the region 230ba and the region 230bb are each an n-type region having a higher carrier concentration and a lower resistance than the region 230bc.

Here, as illustrated in FIG. 11A, the side surfaces of the conductor 242a and the conductor 242b that face each other are preferably substantially perpendicular to the top surface of the oxide 230b. With such a structure, the side end portion of the region 230ba on the region 230bc side that is formed under the conductor 242a can be inhibited from excessively receding from the side end portion of the conductor 242a on the region 230bc side. Similarly, the side end portion of the region 230bb on the region 230bc side that is formed under the conductor 242b can be inhibited from excessively receding from the side end portion of the conductor 242b on the region 230bc side. This can inhibit formation of what is called a Loff region between the region 230ba and the region 230bc and between the region 230bb and the region 230bc. Here, recession of the side end portion of the region 230ba on the region 230bc side refers to a state where the side end portion of the region 230ba is positioned closer to the conductor 240 than the side surface of the conductor 242a on the region 230bc side is. In addition, recession of the side end portion of the region 230bb on the region 230bc side refers to a state where the side end portion of the region 230bb is positioned closer to the conductor 160 than the side surface of the conductor 242b on the region 230bc side is.

Accordingly, the frequency characteristics of the transistor 200 can be improved, and the operation speed of the semiconductor device of one embodiment of the present invention can be improved. For example, in the case where the semiconductor device of one embodiment of the present invention is used as a memory cell of a storage device, the writing speed and the reading speed can be improved.

The carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration of the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations in the region 230ba and the region 230bb and higher than or substantially equal to the carrier concentration in the region 230bc may be formed. That is, the region functions as a junction region between the region 230bc and the region 230ba or the region 230bb. The hydrogen concentration in the junction region is lower than or substantially equal to the hydrogen concentrations in the region 230ba and the region 230bb and higher than or substantially equal to the hydrogen concentration in the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 11A illustrates an example where the region 230ba, the region 230bb, and the region 230bc are formed in the oxide 230b, the present invention is not limited thereto. For example, the above regions may be formed not only in the oxide 230b but also in the oxide 230a.

In the oxide 230, the boundaries between the regions are difficult to detect clearly in some cases. The concentrations of a metal element and impurity elements such as hydrogen and nitrogen, which are detected in each region, may be not only gradually changed between the regions but also continuously changed in each region. That is, the region closer to the channel formation region has lower concentrations of impurity elements such as hydrogen and nitrogen.

In the transistor 200, a metal oxide functioning as a semiconductor (such a metal oxide is hereinafter also referred to as an oxide semiconductor) is preferably used for the oxide 230 (the oxide 230a and the oxide 230b) including the channel formation region.

The metal oxide functioning as a semiconductor preferably has a band gap wider than or equal to 2 eV, further preferably wider than or equal to 2.5 eV. With use of a metal oxide having a wide band gap, the off-state current of the transistor can be reduced.

For the oxide 230, a metal oxide such as indium oxide, gallium oxide, or zinc oxide is preferably used, for example. Alternatively, for the oxide 230, a metal oxide containing two or three selected from indium, an element M, and zinc is preferably used, for example. The element M is one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, cobalt, and magnesium. In particular, the element M is preferably one or more kinds selected from aluminum, gallium, yttrium, and tin. Note that a metal oxide containing indium, the element M, and zinc is referred to as an In-M-Zn oxide in some cases.

The oxide 230 preferably has a stacked-layer structure of a plurality of oxide layers with different chemical compositions. For example, the atomic ratio of the element M to a metal element that is a main component in the metal oxide used as the oxide 230a is preferably higher than the atomic ratio of the element M to a metal element that is a main component in the metal oxide used as the oxide 230b. Moreover, the atomic ratio of the element M to In in the metal oxide used as the oxide 230a is preferably higher than the atomic ratio of the element M to In in the metal oxide used as the oxide 230b. With this structure, impurities and oxygen can be inhibited from diffusing into the oxide 230b from the components formed below the oxide 230a.

Furthermore, the atomic ratio of In to the element Min the metal oxide used as the oxide 230b is preferably higher than the atomic ratio of In to the element Min the metal oxide used as the oxide 230a. With this structure, the transistor 200 can have a high on-state current and high frequency characteristics.

When the oxide 230a and the oxide 230b include a common element as the main component besides oxygen, the density of defect states at the interface between the oxide 230a and the oxide 230b can be reduced. Thus, the influence of interface scattering on carrier conduction is small, and the transistor 200 can have a high on-state current and high frequency characteristics.

Specifically, as the oxide 230a, a metal oxide with a composition of In:M:Zn=1:3:4 [atomic ratio] or in the neighborhood thereof, or a composition of In:M:Zn=1:1:0.5 [atomic ratio] or in the neighborhood thereof is used. As the oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the oxide 230b is provided as the oxide 230, a metal oxide that can be used as the oxide 230a may be used as the oxide 230b.

When a film of the metal oxide is formed by a sputtering method, the above atomic ratio is not limited to the atomic ratio of the formed film of the metal oxide and may be the atomic ratio of a sputtering target used for forming the film of the metal oxide.

The oxide 230b preferably has crystallinity. It is particularly preferable to use a CAAC-OS (c-axis aligned crystalline oxide semiconductor) as the oxide 230b.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as CAAC-OS, is used as the oxide 230b, oxygen extraction from the oxide 230b by the source electrode or the drain electrode can be inhibited. This can reduce oxygen extraction from the oxide 230b even when heat treatment is performed; thus, the transistor 200 is stable with respect to high temperatures in a manufacturing process (what is called thermal budget).

A transistor using an oxide semiconductor is likely to have its electrical characteristics changed by impurities and oxygen vacancies in a channel formation region in the oxide semiconductor, which might degrade the reliability. In some cases, hydrogen in the vicinity of an oxygen vacancy forms a defect that is the oxygen vacancy into which hydrogen enters (hereinafter sometimes referred to as VoH), which generates an electron serving as a carrier. Therefore, when the channel formation region in the oxide semiconductor includes oxygen vacancies, the transistor is likely to have normally-on characteristics (characteristics with which, even when no voltage is applied to the gate electrode, the channel exists and current flows through the transistor). Therefore, impurities, oxygen vacancies, and VoH are preferably reduced as much as possible in the channel formation region in the oxide semiconductor. In other words, it is preferable that the channel formation region of the oxide semiconductor have a reduced carrier concentration and be of an i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and VoH. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into conductors such as the gate electrode, the source electrode, and the drain electrode, the conductors might be oxidized and the conductivity might be impaired, for example, so that the electrical characteristics and reliability of the transistor might be adversely affected.

Therefore, the region 230bc functioning as the channel formation region in the oxide semiconductor is preferably an i-type or substantially i-type region with reduced carrier concentration, whereas the region 230ba and the region 230bb functioning as the source region and the drain region are preferably n-type regions with high carrier concentrations. That is, the amounts of oxygen vacancies and VoH in the region 230bc of the oxide semiconductor are preferably reduced. Furthermore, it is preferable that the region 230ba and the region 230bb not be supplied with an excessive amount of oxygen and the amount of VoH in the region 230ba and the region 230bb not be excessively reduced. For example, a reduction in conductivity of the conductor 260, the conductor 242a, and the conductor 242b, and the like is preferably inhibited. For example, oxidation of the conductor 260, the conductor 242a, and the conductor 242b, and the like is preferably inhibited. Note that hydrogen in an oxide semiconductor can form VoH; thus, the hydrogen concentration needs to be reduced in order to reduce the amount of VoH.

The semiconductor device of this embodiment has a structure in which the hydrogen concentration in the region 230bc is reduced, oxidation of the conductor 242a, the conductor 242b, and the conductor 260 is inhibited, and the hydrogen concentration in the region 230ba and the region 230bb is inhibited from being reduced.

In order to reduce the hydrogen concentration in the region 230bc, the insulator 253 preferably has a function of capturing and fixing hydrogen. As illustrated in FIG. 9C, the insulator 253 includes a region in contact with the region 230bc of the oxide 230b. With this structure, the hydrogen concentration in the region 230bc of the oxide 230b can be reduced. In this manner, the amount of VoH in the region 230bc can be removed, whereby the region 230bc can be an i-type or substantially i-type region.

An example of the insulator having a function of capturing and fixing hydrogen is metal oxide having an amorphous structure. For example, a metal oxide, such as a magnesium oxide or an oxide containing aluminum and/or hafnium, is preferably used. In such a metal oxide having an amorphous structure, an oxygen atom has a dangling bond and sometimes has a property of capturing or fixing hydrogen with the dangling bond. That is, it can be said that the metal oxide having an amorphous structure has high capability of capturing or fixing hydrogen.

The insulator 253 and the insulator 153 that is included in the capacitor 100 are preferably formed using the same insulating film. That is, the insulator 253 and the insulator 153 preferably contain the same material. The insulator 153 functions as a dielectric of the capacitor 100. A high dielectric constant (high-k) material is preferably used for the insulator 153. At this time, the insulator 253 contains the high-k material. An example of the high-k material is an oxide containing one or both of aluminum and hafnium. Accordingly, with use of the high-k material for the insulator 253, a gate potential applied during the operation of the transistor can be reduced while the physical thickness of the gate insulator is maintained. In addition, the equivalent oxide thickness (EOT) of the insulator functioning as the gate insulator can be reduced.

As described above, for the insulator 253, an oxide containing aluminum and/or hafnium is preferably used, more preferably, an oxide containing aluminum and/or hafnium and having an amorphous structure is used, and further preferably, a hafnium oxide having an amorphous structure is used. In this embodiment, hafnium oxide is used as the insulator 253. In this case, the insulator 253 includes at least oxygen and hafnium. The hafnium oxide has an amorphous structure. In this case, the insulator 253 has an amorphous structure.

Furthermore, in order to inhibit oxidation of the conductor 242a, the conductor 242b, and the conductor 260, an insulator of a barrier against oxygen is preferably provided in the vicinity of each of the conductor 242a, the conductor 242b, and the conductor 260. In the semiconductor device described in this embodiment, the insulator corresponds to the insulator 253, the insulator 254, and the insulator 275, for example.

Note that in this specification and the like, a barrier insulator refers to an insulator having a barrier property. A barrier property in this specification and the like means a function of inhibiting diffusion of a targeted substance (also referred to as having low permeability). Alternatively, the barrier property means a function of capturing and fixing (also referred to as gettering) a targeted substance.

Examples of a barrier insulator against oxygen include an oxide containing aluminum and/or hafnium, magnesium oxide, gallium oxide, indium gallium zinc oxide, silicon nitride, and silicon nitride oxide. Note that as the insulator including an oxide of one or both of aluminum and hafnium, aluminum oxide, hafnium oxide, an oxide containing aluminum and hafnium (hafnium aluminate), an oxide containing silicon and hafnium (hafnium silicate), or the like is preferably used. For example, each of the insulator 253, the insulator 254, and the insulator 275 may have a single-layer structure or a stacked-layer structure of the barrier insulator against oxygen.

The insulator 253 preferably has a barrier property against oxygen. The insulator 253 is less permeable to oxygen than at least the insulator 280 is. Moreover, the insulator 253 includes a region in contact with the side surface of the conductor 242a and the side surface of the conductor 242b. When the insulator 253 has a barrier property against oxygen, oxidation of the side surfaces of the conductor 242a and the conductor 242b, which forms oxide films on the side surfaces, can be inhibited. Accordingly, a decrease in the on-state current or field-effect mobility of the transistor 200 can be inhibited.

The insulator 253 is provided in contact with the top surface and the side surface of the oxide 230b, the side surface of the oxide 230a, the side surface of the insulator 224, and the top surface of the insulator 222. When the insulator 253 has a barrier property against oxygen, release of oxygen from the region 230bc of the oxide 230b caused by heat treatment or the like can be inhibited. This can reduce formation of oxygen vacancies in the oxide 230a and the oxide 230b.

Even when an excess amount of oxygen is contained in the insulator 280, oxygen can be inhibited from being excessively supplied to the oxide 230a and the oxide 230b. Thus, the region 230ba and the region 230bb are inhibited from being excessively oxidized; a reduction in on-state current or field-effect mobility of the transistor 200 can be inhibited.

An oxide containing aluminum and/or hafnium has a barrier property against oxygen and thus can be suitably used for the insulator 253.

The insulator 254 preferably has a barrier property against oxygen. The insulator 254 is provided between the conductor 260 and the region 230bc of the oxide 230b and between the insulator 280 and the conductor 260. Such a structure can inhibit oxygen contained in the region 230bc of the oxide 230b from diffusing into the conductor 260 and thus can inhibit formation of oxygen vacancies in the region 230bc of the oxide 230b. Oxygen contained in the oxide 230b and oxygen contained in the insulator 280 can be inhibited from diffusing into the conductor 260 and oxidizing the conductor 260. Note that the insulator 254 is less permeable to oxygen than at least the insulator 280 is. For example, silicon nitride is preferably used for the insulator 254. In this case, the insulator 254 includes at least nitrogen and silicon.

The insulator 275 preferably has a barrier property against oxygen. The insulator 275 is provided between the insulator 280 and the conductor 242a and between the insulator 280 and the conductor 242b. The structure can inhibit diffusion of oxygen contained in the insulator 280 into the conductor 242a and the conductor 242b. Thus, the conductor 242a and the conductor 242b can be inhibited from being oxidized by oxygen included in the insulator 280, so that an increase in resistivity and a reduction in on-state current can be inhibited. The insulator 275 is less permeable to oxygen than at least the insulator 280 is. For example, silicon nitride is preferably used for the insulator 275. In this case, the insulator 275 includes at least nitrogen and silicon.

In order to inhibit a reduction in the hydrogen concentration in the region 230ba and the region 230bb, a barrier insulator against hydrogen is preferably provided in the vicinity of each of the region 230ba and the region 230bb. In the semiconductor device described in this embodiment, the barrier insulator against hydrogen is, for example, the insulator 275.

Examples of the barrier insulator against hydrogen include an oxide such as aluminum oxide, hafnium oxide, and tantalum oxide and a nitride such as silicon nitride. For example, the insulator 275 has a single-layer structure or a stacked-layer structure of the barrier insulator against hydrogen.

The insulator 275 preferably has a barrier property against hydrogen. The insulator 275 is placed in contact with the side surface of the region 230ba in the oxide 230b and the side surface of the region 230bb in the oxide 230b. The insulator 275 is placed between the insulator 253 and the side surface of the region 230ba in the oxide 230b and between the insulator 253 and the side surface of the region 230bb in the oxide 230b. When the insulator 275 has a barrier property against hydrogen, capturing and fixing of hydrogen in the region 230ba and the region 230bb by the insulator 253 can be inhibited. Thus, the region 230ba and the region 230bb can be n-type regions.

With the above structure, the region 230bc functioning as the channel formation region can be an i-type or substantially i-type region, the region 230ba and the region 230bb functioning as the source region and the drain region can be n-type regions, and thus a semiconductor device with favorable electrical characteristics can be provided. The semiconductor device with the above structure can have favorable electrical characteristics even when miniaturized or highly integrated. For example, the semiconductor device can have favorable electrical characteristics even when the distance L2 illustrated in FIG. 11A is less than or equal to 20 nm, less than or equal to 15 nm, less than or equal to 10 nm, or less than or equal to 7 nm and greater than or equal to 2 nm, greater than or equal to 3 nm, or greater than or equal to 5 nm.

Miniaturization of the transistor 200 can improve the high frequency characteristics. Specifically, the cutoff frequency can be improved. When the gate length is within any of the above ranges, the cutoff frequency of the transistor can be greater than or equal to 50 GHz or greater than or equal to 100 GHz at room temperature, for example.

The insulator 253 functions as part of the gate insulator. As illustrated in FIG. 9B, the insulator 253 is provided in contact with the side surface and part of the top surface of the insulator 275 and the side surface of the insulator 280.

Furthermore, the insulator 253 needs to be provided in an opening formed in the insulator 280 and the like, together with the insulator 254 and the conductor 260. The thickness of the insulator 253 is preferably small for miniaturization of the transistor 200. The thickness of the insulator 253 is greater than or equal to 0.1 nm and less than or equal to 5.0 nm, preferably greater than or equal to 0.5 nm and less than or equal to 5.0 nm, further preferably greater than or equal to 1.0 nm and less than 5.0 nm, still further preferably greater than or equal to 1.0 nm and less than or equal to 3.0 nm. In this case, at least part of the insulator 253 includes a region having a thickness like the above-described thickness.

To form the insulator 253 having a small thickness as described above, an ALD method is preferably used for film formation. Examples of the ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because film formation at a lower temperature is possible.

An ALD method, which enables an atomic layer to be deposited one by one, has advantages such as formation of an extremely thin film, film formation on a component with a high aspect ratio, formation of a film with a small number of defects such as pinholes, film formation with excellent coverage, and low-temperature film formation. Therefore, the insulator 253 can be formed on the side surface of the opening formed in the insulator 280 and the like, the side end portion of the conductor 242, and the like, with a small thickness like the above-described thickness and favorable coverage.

Note that some of precursors usable in an ALD method contain carbon or the like. Thus, in some cases, a film provided by an ALD method includes impurities such as carbon in a larger amount than a film provided by another film formation method. Note that impurities can be quantified by secondary ion mass spectrometry (SIMS), X-ray photoelectron spectroscopy (XPS), or auger electron spectroscopy (AES).

The insulator 254 functions as part of a gate insulator. The insulator 254 preferably has a barrier property against hydrogen. This can prevent diffusion of impurities such as hydrogen contained in the conductor 260 into the oxide 230b.

Furthermore, the insulator 254 needs to be provided in an opening formed in the insulator 280 and the like, together with the insulator 253 and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 includes a region having a thickness like the above-described thickness.

For example, silicon nitride deposited by a PEALD method may be used as the insulator 254.

Note that an insulator having a function of inhibiting the passage of oxygen and impurities such as hydrogen, e.g., hafnium oxide, is used as the insulator 253, whereby the insulator 253 can also have the function of the insulator 254. In such a case, the structure without the insulator 254 enables simplification of the manufacturing process and the improvement in productivity of the semiconductor device.

The insulator 275 is provided to cover the insulator 224, the oxide 230a, the oxide 230b, and the conductor 242. Specifically, the insulator 275 includes a region in contact with the side surface of the oxide 230b, the side surface of the conductor 242a, and the side surface of the conductor 242b.

In a region overlapping with the opening 258, the insulator 275 overlaps with the conductor 242. With this structure, the physical distance between the conductor 242 and the conductor 260 is increased, so that the parasitic capacitance between the conductor 242 and the conductor 260 can be reduced. Thus, a semiconductor device with favorable electrical characteristics can be provided.

A conductive material that is less likely to be oxidized, a conductive material having a function of inhibiting diffusion of oxygen, or the like is preferably used for the conductor 242a, the conductor 242b, and the conductor 260. Examples of the conductive material include a conductive material containing nitrogen, a conductive material containing oxygen, and the like. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

One or both of the conductor 242 and the conductor 260 may have a stacked-layer structure. For example, as illustrated in FIG. 9B, the conductor 242a and the conductor 242b may each have a stacked-layer structure of two layers. In such a case, a conductive material that is less likely to be oxidized, a conductive material having a function of inhibiting diffusion of oxygen, or the like is preferably used for a layer (the conductor 242a1 and the conductor 242b1) in contact with the oxide 230b. For example, in the case where the conductor 260 has a stacked-layer structure of the conductor 260a and the conductor 260b as illustrated in FIG. 9B, a conductive material that is less likely to be oxidized, a conductive material having a function of inhibiting diffusion of oxygen, or the like is preferably used for the conductor 260a.

To inhibit a decrease in the conductivity of the conductor 242, an oxide having crystallinity, such as a CAAC-OS, is preferably used as the oxide 230b. As the oxide, a metal oxide that can be used as the oxide 230 described above is preferably used. In particular, a metal oxide containing indium, zinc, and one or more selected from gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting oxygen from the oxide 230b. Furthermore, it is possible to inhibit a reduction in the conductivity of the conductor 242a and the conductor 242b.

In this embodiment, microwave treatment is performed in an atmosphere containing oxygen in a state where the conductor 242a and the conductor 242b are provided over the oxide 230b so that the amounts of oxygen vacancies and VoH in the region 230bc can be reduced. Here, the microwave treatment refers to, for example, treatment using an apparatus including a power source that generates high-density plasma with the use of a microwave. In this specification and the like, a microwave refers to an electromagnetic wave having a frequency higher than or equal to 300 MHz and lower than or equal to 300 GHz.

The microwave treatment in an oxygen-containing atmosphere converts an oxygen gas into plasma using a high-frequency wave such as a microwave or RF and activates the oxygen plasma. At this time, the region 230bc can also be irradiated with the high-frequency wave such as a microwave or RF. By the effect of the plasma, the microwave, or the like, VoH in the region 230bc can be divided into an oxygen vacancy and hydrogen; the hydrogen can be removed from the region 230bc and the oxygen vacancy can be filled with oxygen. As a result, the hydrogen concentration, oxygen vacancies and VoH of the region 230bc can be reduced to lower the carrier concentration.

In the microwave treatment in an oxygen-containing atmosphere, the high-frequency wave such as the microwave or RF, the oxygen plasma, or the like is blocked by the conductor 242a and the conductor 242b and does not affect the region 230ba nor the region 230bb. In addition, the effect of the oxygen plasma can be reduced by the insulator 275 and the insulator 280 that are provided to cover the oxide 230b and the conductor 242. Hence, a reduction in VoH and supply of an excess amount of oxygen do not occur in the region 230ba and the region 230bb in the microwave treatment, preventing a decrease in carrier concentration.

After an insulating film to be the insulator 253 is deposited, microwave treatment is preferably performed in an oxygen-containing atmosphere. By performing the microwave treatment in an oxygen-containing atmosphere through the insulating film to be the insulator 253 in such a manner, oxygen can be efficiently supplied into the region 230bc. In addition, the insulating film to be the insulator 253 is placed to be in contact with the side surface of the conductor 242 and the surface of the region 230bc, thereby inhibiting oxygen more than necessary from being supplied to the region 230bc and inhibiting the side surface of the conductor 242 from being oxidized.

The oxygen implanted into the region 230bc is in any of a variety of forms such as an oxygen atom, an oxygen molecule, an oxygen ion (a charged oxygen atom or a charged oxygen molecule), and an oxygen radical (also referred to as O radical, which is an oxygen atom, an oxygen molecule, or an oxygen ion having an unpaired electron). Note that the oxygen implanted into the region 230bc is in any one or more of the above forms, and is particularly suitably an oxygen radical. Furthermore, the film quality of the insulator 253 can be improved, leading to higher reliability of the transistor 200.

In the above manner, oxygen vacancies and VoH can be selectively removed from the region 230bc of the oxide semiconductor, whereby the region 230bc can be an i-type or substantially i-type region. Furthermore, supply of an excess amount of oxygen to the region 230ba and the region 230bb functioning as the source region and the drain region can be inhibited and the state of the n-type regions before the microwave treatment is performed can be maintained. As a result, a change in the electrical characteristics of the transistor 200 can be inhibited, and thus a variation in the electrical characteristics of the transistors 200 in the substrate plane can be inhibited.

With the above structure, a semiconductor device with a small variation in transistor characteristics can be provided. Furthermore, a semiconductor device with favorable frequency characteristics can be provided. Furthermore, a semiconductor device with high operating speed can be provided. Furthermore, a semiconductor device with favorable reliability can be provided. Furthermore, a semiconductor device having favorable electrical characteristics can be provided. Furthermore, a semiconductor device that can be miniaturized or highly integrated can be provided.

As illustrated in FIG. 9C, a curved surface may be provided between the side surface of the oxide 230b and the top surface of the oxide 230b in a cross-sectional view of the transistor 200 in the channel width direction. That is, an end portion of the side surface and an end portion of the top surface may be curved (hereinafter also referred to as rounded).

The radius of curvature of the curved surface is preferably greater than 0 nm and less than the thickness of the oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, further preferably greater than or equal to 2 nm and less than or equal to 10 nm. Such a shape can improve the coverage of the oxide 230b with the insulator 253, the insulator 254, and the conductor 260.

In the manufacturing process of the transistor 200, heat treatment is preferably performed with a surface of the oxide 230 exposed. For example, the heat treatment is performed at higher than or equal to 100° C. and lower than or equal to 600° C., preferably higher than or equal to 350° C. and lower than or equal to 550° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. This can supply oxygen to the oxide 230 to reduce oxygen vacancies. The heat treatment may be performed under a reduced pressure. Alternatively, the heat treatment may be performed in such a manner that heat treatment is performed in a nitrogen gas atmosphere or an inert gas atmosphere, and then another heat treatment is performed in an atmosphere containing an oxidizing gas at 10 ppm or more, 1% or more, or 10% or more in order to compensate for released oxygen. Alternatively, the heat treatment may be performed in such a manner that heat treatment is performed in an atmosphere containing an oxidizing gas at 10 ppm or more, 1% or more, or 10% or more, and then another heat treatment is successively performed in a nitrogen gas atmosphere or an inert gas atmosphere.

Note that by oxygen adding treatment performed on the oxide 230, oxygen vacancies in the oxide 230 can be repaired with supplied oxygen. Furthermore, hydrogen remaining in the oxide 230 reacts with supplied oxygen, so that the hydrogen can be removed as H₂O (dehydration). This can inhibit recombination of hydrogen remaining in the oxide 230 with oxygen vacancies and formation of VoH.

As illustrated in FIG. 9C or the like, the insulator 253 is provided in contact with the top surface and side surfaces of the oxide 230, whereby indium contained in the oxide 230 is unevenly distributed, in some cases, at the interface between the oxide 230 and the insulator 253 and in its vicinity. Accordingly, the vicinity of the surface of the oxide 230 has an atomic ratio close to that of indium oxide or that of In—Zn oxide. Such an increase in the atomic ratio of indium in the vicinity of the surface of the oxide 230, especially the oxide 230b, can increase the field-effect mobility of the transistor 200.

In addition to the above structure, the semiconductor device of this embodiment preferably has a structure in which hydrogen is inhibited from entering the transistor 200. For example, an insulator having a function of inhibiting diffusion of hydrogen is preferably provided to cover the transistor 200. In the semiconductor device described in this embodiment, the insulator corresponds to, for example, the insulator 212.

As the insulator 212, an insulator having a function of inhibiting diffusion of hydrogen is preferably used. This can inhibit diffusion of hydrogen into the transistor 200 from below the insulator 212. As the insulator 212, an insulator that can be used as the insulator 275 described above is preferably used.

At least one of the insulator 212, the insulator 214, the insulator 282, and the insulator 285 preferably functions as a barrier insulating film, which inhibits diffusion of impurities such as water and hydrogen from the substrate side or above the transistor 200 into the transistor 200. Thus, for at least one of the insulator 212, the insulator 214, the insulator 282, and the insulator 285, an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), or a copper atom (an insulating material through which the impurities are less likely to pass) is preferably used. Alternatively, it is preferable to use an insulating material having a function of inhibiting diffusion of oxygen (e.g., at least one of an oxygen atom, an oxygen molecule, and the like) (an insulating material that is less permeable to the oxygen).

An insulator having a function of inhibiting diffusion of impurities, such as water and hydrogen, and oxygen is preferably used for the insulator 212, the insulator 214, the insulator 282, and the insulator 285; for example, aluminum oxide, magnesium oxide, hafnium oxide, gallium oxide, indium gallium zinc oxide, silicon nitride, or silicon nitride oxide can be used. For example, silicon nitride, which has a higher hydrogen barrier property, is preferably used for the insulator 212. For example, aluminum oxide or magnesium oxide, which has a function of capturing or fixing hydrogen, is preferably used for the insulator 214, the insulator 282, and the insulator 285. In this case, impurities such as water and hydrogen can be inhibited from diffusing to the transistor 200 side from the substrate side through the insulator 212 and the insulator 214. Impurities such as water and hydrogen can be inhibited from diffusing to the transistor 200 side from an interlayer insulating film and the like which are provided outside the insulator 285. Alternatively, oxygen contained in the insulator 224 and the like can be inhibited from diffusing to the substrate side through the insulator 212 and the insulator 214. Alternatively, oxygen included in the insulator 280 and the like can be inhibited from diffusing to above the transistor 200 through the insulator 282 and the like. In this manner, the transistor 200 is preferably surrounded by the insulator 212, the insulator 214, the insulator 282, and the insulator 285 which have a function of inhibiting diffusion of oxygen and impurities such as water and hydrogen.

Here, an oxide having an amorphous structure is preferably used for the insulator 212, the insulator 214, the insulator 282, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as a component of the transistor 200 or provided around the transistor 200, hydrogen included in the transistor 200 or hydrogen around the transistor 200 can be captured or fixed. In particular, hydrogen included in the channel formation region of the transistor 200 is preferably captured or fixed. When the metal oxide having an amorphous structure is used as a component of the transistor 200 or provided around the transistor 200, the transistor 200 and the semiconductor device which have favorable characteristics and high reliability can be manufactured.

Although the insulator 212, the insulator 214, the insulator 282, and the insulator 285 preferably have an amorphous structure, they may partly include a region with a polycrystalline structure. Alternatively, the insulator 212, the insulator 214, the insulator 282, and the insulator 285 may each have a multilayer structure where a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 282, and the insulator 285 can be formed by a sputtering method, for example. Since a sputtering method does not need to use a molecule containing hydrogen as a film formation gas, the hydrogen concentrations in the insulator 212, the insulator 214, the insulator 282, and the insulator 285 can be reduced. Note that the film formation method is not limited to a sputtering method, and a CVD method, an MBE method, a PLD method, an ALD method, or the like may be used as appropriate.

The resistivity of the insulator 212 is preferably low in some cases. For example, by setting the resistivity of the insulator 212 to approximately 1×10¹³ Ωcm, the insulator 212 can sometimes reduce charge up of the conductor 205 or the conductor 240 in treatment using plasma or the like in the manufacturing process of a semiconductor device. The resistivity of the insulator 212 is preferably higher than or equal to 1×10¹⁰ Ωcm and lower than or equal to 1×10¹⁵ Ωcm.

The permittivity of the insulator 216, the insulator 280, and the insulator 285 are preferably lower than that of the insulator 214. When a material with a low permittivity is used for the interlayer film, parasitic capacitance generated between wirings can be reduced. For the insulator 216, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

The conductor 205 is positioned to overlap with the oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion defined by the conductor 205a. Here, the top surface of the conductor 205b is level with or substantially level with the top surface of the conductor 205a and the top surface of the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When a conductive material having a function of inhibiting diffusion of hydrogen is used for the conductor 205a, impurities such as hydrogen included in the conductor 205b can be prevented from diffusing into the oxide 230 through the insulator 216, the insulator 224, and the like. When a conductive material having a function of inhibiting diffusion of oxygen is used for the conductor 205a, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, the conductor 205a may be a single layer or a stacked layer of the above conductive materials. For example, titanium nitride is used for the conductor 205a.

A conductive material containing tungsten, copper, or aluminum as its main component is preferably used for the conductor 205b. For example, tungsten is used for the conductor 205b.

The conductor 205 sometimes functions as the second gate electrode. In that case, by changing a potential applied to the conductor 205 out of synchronization with and independently of a potential applied to the conductor 260, the threshold voltage (Vth) of the transistor 200 can be controlled. In particular, by applying a negative potential to the conductor 205, Vth of the transistor 200 can be made higher, and its off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. When the thickness of the insulator 216 is reduced, the absolute amount of impurities such as hydrogen contained in the insulator 216 can be reduced, which makes it possible to reduce the amount of the impurities to be diffused into the oxide 230.

As illustrated in FIG. 9A, the conductor 205 is preferably provided so as to be larger than a region of the oxide 230 that does not overlap with the conductor 242a or the conductor 242b. As illustrated in FIG. 9C, it is particularly preferable that the conductor 205 extend to a region outside end portions of the oxide 230a and the oxide 230b in the channel width direction. That is, the conductor 205 and the conductor 260 preferably overlap with each other with the insulators therebetween on the outer side of the side surface of the oxide 230 in the channel width direction. With this structure, the channel formation region of the oxide 230 can be electrically surrounded by the electric field of the conductor 260 functioning as the first gate electrode and the electric field of the conductor 205 functioning as the second gate electrode.

In this specification and the like, a transistor structure in which a channel formation region is electrically surrounded by at least the electric field of a first gate electrode is referred to as a surrounded channel (S-channel) structure. The S-channel structure disclosed in this specification and the like has a structure different from a Fin-type structure and a planar structure. Meanwhile, the S-channel structure disclosed in this specification and the like can also be regarded as a kind of the Fin-type structure. In this specification and the like, the Fin-type structure refers to a structure where at least two surfaces (specifically, two surfaces, three surfaces, four surfaces, or the like) of a channel are covered with a gate electrode. With the Fin-type structure and the S-channel structure, resistance to a short-channel effect can be enhanced; that is, a transistor in which a short-channel effect is less likely to occur can be provided.

When the transistor 200 has the above-described S-channel structure, the channel formation region can be electrically surrounded. Since the S-channel structure is a structure with the electrically surrounded channel formation region, the S-channel structure is, in a sense, equivalent to a GAA (Gate All Around) structure or a LGAA (Lateral Gate All Around) structure. When the transistor 200 has the S-channel structure, the GAA structure, or the LGAA structure, the channel formation region that is formed at the interface between the oxide 230 and the gate insulator or in the vicinity of the interface can be formed in the entire bulk of the oxide 230. Accordingly, the density of current flowing in the transistor can be improved, which can be expected to improve the on-state current of the transistor or increase the field-effect mobility of the transistor.

Note that although a transistor with an S-channel structure is exemplified as the transistor 200 illustrated in FIG. 9B, the semiconductor device of one embodiment of the present invention is not limited thereto. For example, a transistor structure that can be used in one embodiment of the present invention may be one or more selected from the planar structure, the Fin-type structure, and the GAA structure.

Furthermore, as illustrated in FIG. 9C, the conductor 205 extends to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 each function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., hafnium zirconium oxide, is preferably used. In the case where the insulator 222 is formed using such a material, the insulator 222 functions as a layer that inhibits release of oxygen from the oxide 230 to the substrate side and diffusion of impurities such as hydrogen from the periphery of the transistor 200 into the oxide 230. Thus, providing the insulator 222 can inhibit diffusion of impurities such as hydrogen into the transistor 200 and inhibit generation of oxygen vacancies in the oxide 230. Moreover, the conductor 205 can be inhibited from reacting with oxygen contained in the insulator 224 and the oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, these insulators may be subjected to nitriding treatment. A stack of the insulator and any of silicon oxide, silicon oxynitride, and silicon nitride may be used for the insulator 222.

For example, a single layer or stacked layers of an insulator(s) containing what is called a high-k material such as aluminum oxide, hafnium oxide, tantalum oxide, zirconium oxide, or hafnium-zirconium oxide may be used for the insulator 222. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) may be used for the insulator 222.

Silicon oxide or silicon oxynitride, for example, is used as appropriate for the insulator 224 that is in contact with the oxide 230.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the oxide 230a. In this case, the insulator 275 is in contact with the side surface of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface of the oxide 230b. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is less likely to be oxidized or a material that maintains the conductivity even after absorbing oxygen.

Note that hydrogen contained in the oxide 230b or the like is diffused into the conductor 242a or the conductor 242b in some cases. In particular, when a nitride containing tantalum is used for each of the conductor 242a and the conductor 242b, hydrogen contained in the oxide 230b or the like is likely to be diffused into the conductor 242a or the conductor 242b, and the diffused hydrogen is bonded to nitrogen contained in the conductor 242a or the conductor 242b in some cases. That is, hydrogen contained in the oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 9D. Accordingly, the conductivity of the conductor 242 is increased, so that the on-state current of the transistor 200 can be increased.

As illustrated in FIG. 9A, the conductor 242a has an opening in a region between the transistor 200a and the transistor 200b. The conductor 240 is placed to overlap with the opening. Note that in the top view of the transistor 200, the size of the opening is preferably smaller than the size of the conductor 240. With this structure, the conductor 242a can include a region in contact with the conductor 240. Thus, the conductor 242a and the conductor 240 are electrically connected to each other.

When heat treatment is performed in the state where the conductor 242a (conductor 242b) and the oxide 230b are in contact with each other, the sheet resistance of the oxide 230b in a region overlapping with the conductor 242a (conductor 242b) is decreased in some cases. Furthermore, the carrier concentration sometimes increases. Thus, the resistance of the oxide 230b in the region overlapping with the conductor 242a (conductor 242b) can be lowered in a self-aligned manner.

The conductor 242a and the conductor 242b are preferably formed using a conductive film having compressive stress. This can form distortion extended in the tensile direction (hereinafter, such distortion is sometimes referred to as tensile distortion) in the region 230ba and the region 230bb. When VoH is stably formed by the tensile distortion, the region 230ba and the region 230bb can be stable n-type regions. Note that the compressive stress of the conductor 242a refers to stress for relaxing the compressive shape of the conductor 242a that has a vector in a direction from a center portion to an end portion of the conductor 242a. The same applies to the compressive stress of the conductor 242b.

The level of the compressive stress of the conductor 242a is, for example, higher than or equal to 500 MPa, preferably higher than or equal to 1000 MPa, further preferably higher than or equal to 1500 MPa, still further preferably higher than or equal to 2000 MPa. Note that the level of the stress of the conductor 242a may be determined from the measured stress of a sample fabricated by forming a conductive film to be used for the conductor 242a on a substrate. The same applies to the level of the compressive stress of the conductor 242b. An example of a conductor having the above level of compressive stress is a nitride containing tantalum.

Due to the action of the compressive stress in the conductor 242a and the conductor 242b, distortion is formed in each of the region 230ba and the region 230bb. The distortion is distortion (tensile distortion) caused by extension in the tensile direction by the action of the compressive stress in the conductor 242a and the conductor 242b. In the case where the region 230ba and the region 230bb have a CAAC structure, the distortion corresponds to extension in the direction perpendicular to the c-axis of the CAAC structure. When the CAAC structure is extended in the direction perpendicular to the c-axis of the CAAC structure, oxygen vacancies are likely to be formed in the distortion. Furthermore, hydrogen is likely to be taken in the distortion, so that VoH is likely to be formed. Thus, oxygen vacancies and VoH are likely to be formed in the distortion and likely to have a stable structure. Thus, the region 230ba and the region 230bb can be stable n-type regions with high carrier concentrations.

Note that although the distortion formed in the oxide 230b is described above, the present invention is not limited thereto. In some cases, a similar distortion is formed in the oxide 230a.

In the semiconductor device illustrated in FIGS. 9A to 9D, the conductor 242 has a stacked-layer structure of two layers. Specifically, the conductor 242a includes the conductor 242a1 and the conductor 242a2 over the conductor 242a1. Similarly, the conductor 242b includes the conductor 242b1 and the conductor 242b2 over the conductor 242b1. In that case, the conductor 242a1 and the conductor 242b1 are positioned on the side in contact with the oxide 230b.

The conductor 242a1 and the conductor 242a2 can be formed using the same material in the same step as the conductor 242b1 and the conductor 242b2, respectively; the details will be described later. Thus, the conductor 242a1 is preferably formed using the same conductive material as the conductor 242b1. The conductor 242a2 is preferably formed using the same conductive material as the conductor 242b2.

Hereinafter, the conductor 242a1 and the conductor 242b1 are collectively referred to as a lower layer of the conductor 242 in some cases. The conductor 242a2 and the conductor 242b2 are collectively referred to as an upper layer of the conductor 242 in some cases.

The lower layer (the conductor 242a1 and the conductor 242b1) of the conductor 242 is preferably formed using a conductive material having a property of being less likely to be oxidized. This can inhibit the oxidation of the lower layer of the conductor 242 and a reduction in the conductivity of the conductor 242. Note that the lower layer of the conductor 242 may have a property of being likely to absorb (extract) hydrogen. Accordingly, hydrogen in the oxide 230 diffuses into the lower layer of the conductor 242, so that the hydrogen concentration of the oxide 230 can be reduced. Thus, the transistor 200 can have stable electrical characteristics. The lower layer of the conductor 242 preferably has high compressive stress as described above, and preferably has higher compressive stress than the upper layer of the conductor 242. Thus, as described above, the region 230ba and the region 230bb that are in contact with the lower layer of the conductor 242 can be stable n-type regions with a high carrier concentration.

The upper layer of the conductor 242 (the conductor 242a2 and the conductor 242b2) preferably has higher conductivity than the lower layer of the conductor 242 (the conductor 242a1 and the conductor 242b1). For example, the upper layer of the conductor 242 is thicker than the lower layer of the conductor 242. In this case, at least part of the upper layer of the conductor 242 includes a region having higher conductivity than the lower layer of the conductor 242. Alternatively, the upper layer of the conductor 242 is preferably formed using a conductive material having lower resistivity than the lower layer of the conductor 242. Accordingly, a semiconductor device with reduced wiring delay can be manufactured.

Note that the upper layer of the conductor 242 may have a property of being likely to absorb hydrogen. Accordingly, hydrogen absorbed by the lower layer of the conductor 242 also diffuses into the upper layer of the conductor 242, so that the hydrogen concentration in the oxide 230 can be further reduced. Thus, the transistor 200 can have stable electrical characteristics.

When the conductor 242 has a stacked-layer structure of two layers, one or more selected from the constituent elements, chemical composition, and film formation conditions may be different between the lower layer of the conductor 242 and the upper layer of the conductor 242.

For example, tantalum nitride or titanium nitride can be used for the lower layer of the conductor 242 (the conductor 242a1 and the conductor 242b1), and tungsten can be used for the upper layer of the conductor 242 (the conductor 242a2 and the conductor 242b2). In this case, the conductor 242a1 and the conductor 242b1 each contain tantalum or titanium and nitrogen. This structure can inhibit the oxidation of the lower layer of the conductor 242 and a reduction in the conductivity of the conductor 242. With this structure, the conductor 242a2 can be surrounded by the insulator 275 having a barrier property against oxygen and the conductor 242a1 having a property of being less likely to be oxidized, and the conductor 242b2 can be surrounded by the insulator 275 having a barrier property against oxygen and the conductor 242b1 having a property of being less likely to be oxidized. Thus, a semiconductor device in which oxidation of the conductor 242a2 and the conductor 242b2 and wiring delay are inhibited can be manufactured. When tungsten is used for the upper layer of the conductor 242, the conductor 242 can function as a wiring.

Alternatively, a nitride containing tantalum (e.g., tantalum nitride) may be used for the lower layer of the conductor 242, and a nitride containing titanium (e.g., titanium nitride) may be used for the upper layer of the conductor 242. Titanium nitride can have higher conductivity than tantalum nitride; thus, the conductivity of the upper layer of the conductor 242 can be higher than that of the lower layer of the conductor 242. Thus, the contact resistance between the conductor 242 and the conductor 240 provided in contact with the top surface of the conductor 242 can be reduced, so that a semiconductor device with reduced wiring delay can be manufactured.

Although the lower layer of the conductor 242 and the upper layer of the conductor 242 are formed using different conductive materials in the above-described example, the present invention is not limited thereto.

Here, for the lower layer of the conductor 242 and the upper layer of the conductor 242, conductive materials containing the same constituent elements and having different chemical compositions may be used. In this case, the lower layer of the conductor 242 and the upper layer of the conductor 242 can be formed successively without being exposed to an atmospheric environment. By the formation without exposure to the atmosphere, impurities or moisture from the atmospheric environment can be prevented from being attached onto the surface of the lower layer of the conductor 242, so that the vicinity of the interface between the lower layer of the conductor 242 and the upper layer of the conductor 242 can be kept clean.

In addition, a nitride containing tantalum with a high atomic ratio of nitrogen to tantalum is preferably used for the lower layer of the conductor 242, and a nitride containing tantalum with a low atomic ratio of nitrogen to tantalum is preferably used for the upper layer of the conductor 242. For example, a nitride containing tantalum with an atomic ratio of nitrogen to tantalum being greater than or equal to 1.0 and less than or equal to 2.0, preferably greater than or equal to 1.1 and less than or equal to 1.8, further preferably greater than or equal to 1.2 and less than or equal to 1.5 is used for the lower layer of the conductor 242. In addition, for example, a nitride containing tantalum with an atomic ratio of nitrogen to tantalum being greater than or equal to 0.3 and less than or equal to 1.5, preferably greater than or equal to 0.5 and less than or equal to 1.3, further preferably greater than or equal to 0.6 and less than or equal to 1.0 is used for the upper layer of the conductor 242.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the lower layer of the conductor 242. It is thus possible to prevent an oxide layer from being formed between the lower layer of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the upper layer of the conductor 242. As a result, a semiconductor device with reduced wiring delay can be fabricated.

Note that the boundary between the upper layer and the lower layer of the conductor 242 is difficult to detect clearly in some cases. In the case where a nitride containing tantalum is used for the conductor 242, the tantalum concentration and the nitrogen concentration detected in each layer may gradually change within each layer or may change continuously (or in a gradation manner) in a region between the upper layer and the lower layer. That is, the atomic ratio of nitrogen to tantalum is higher in the region of the conductor 242 that is closer to the oxide 230. Thus, the atomic ratio of nitrogen to tantalum in a lower region of the conductor 242 is preferably higher than the atomic ratio of nitrogen to tantalum in an upper region of the conductor 242.

Although the transistor 200 having a structure in which the conductor 242 has a stacked-layer structure of two layers is illustrated, the present invention is not limited thereto. For example, the conductor 242 may have a single-layer structure or a stacked-layer structure of three or more layers. In the case where a component has a stacked-layer structure, layers may be distinguished by ordinal numbers corresponding to the formation order.

The top surface of the conductor 260 is positioned to be level or substantially level with the uppermost portion of the insulator 254, the uppermost portion of the insulator 253, and the top surface of the insulator 280.

The conductor 260 functions as the first gate electrode of the transistor 200. The conductor 260 preferably includes the conductor 260a and the conductor 260b placed over the conductor 260a. For example, the conductor 260a is preferably positioned to cover the bottom surface and the side surface of the conductor 260b. Although the conductor 260 is illustrated to have a two-layer structure of the conductor 260a and the conductor 260b in FIG. 9B and FIG. 9C, the conductor 260 may have a single-layer structure or a stacked-layer structure of three or more layers.

For the conductor 260a, it is preferable to use a conductive material having a function of inhibiting diffusion of impurities such as a hydrogen atom, a hydrogen molecule, a water molecule, a nitrogen atom, a nitrogen molecule, a nitrogen oxide molecule, and a copper atom. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen included in the insulator 280 and the like. As the conductive material having a function of inhibiting diffusion of oxygen, for example, titanium, titanium nitride, tantalum, tantalum nitride, ruthenium, or ruthenium oxide is preferably used.

The conductor 260 is formed to fill the opening 258 extending in the channel width direction, i.e., the conductor 260 extends in the channel width direction. Thus, when the plurality of transistors 200 are provided, the conductor 260 can function as a wiring. In this case, the insulator 253 and the insulator 254 also extend together with the conductor 260.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280 and the like. The formation of the conductor 260 in this manner allows the conductor 260 to be positioned properly in a region between the conductor 242a and the conductor 242b without alignment.

As illustrated in FIG. 9C, in the channel width direction of the transistor 200, with reference to a bottom surface of the insulator 222, the level of the bottom surface of the conductor 260 in a region where the conductor 260 and the oxide 230b do not overlap is preferably lower than the level of a bottom surface of the oxide 230b. When the conductor 260 functioning as the gate electrode covers the side surface and the top surface of the channel formation region of the oxide 230b with the insulator 253 and the like therebetween, the electric field of the conductor 260 is likely to act on the entire channel formation region of the oxide 230b. Thus, the on-state current of the transistor 200 can be increased, and the frequency characteristics of the transistor 200 can be improved. With a reference to the bottom surface of the insulator 222, the difference between the level of the bottom surface of the conductor 260 in a region where the conductor 260 do not overlap with the oxide 230a or the oxide 230b and the level of the bottom surface of the oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275 and has the opening in a region where the insulator 253, the insulator 254, and the conductor 260 are to be provided. In addition, the top surface of the insulator 280 may be planarized.

The insulator 280 functioning as an interlayer film preferably has a low permittivity. In the case where a material with a low dielectric constant is used for an interlayer film, the parasitic capacitance between wirings can be reduced. The insulator 280 is preferably provided using a material similar to that for the insulator 216, for example. In particular, silicon oxide and silicon oxynitride, which are thermally stable, are preferable. In particular, preferred materials are silicon oxide, silicon oxynitride, and porous silicon oxide with which a region containing oxygen to be released by heating can be easily formed.

The concentration of impurities such as water and hydrogen in the insulator 280 is preferably reduced. Oxide containing silicon such as silicon oxide, silicon oxynitride, or the like is used as appropriate for the insulator 280, for example.

The insulator 282 is positioned to be in contact with at least parts of the top surfaces of the conductor 260, the insulator 253, the insulator 254, and the insulator 280.

The insulator 282 preferably functions as a barrier insulating film that inhibits impurities such as water and hydrogen from diffusing into the insulator 280 from above and preferably has a function of capturing impurities such as hydrogen. The insulator 282 preferably functions as a barrier insulating film that inhibits passage of oxygen. For the insulator 282, an insulator such as a metal oxide having an amorphous structure, e.g., aluminum oxide, may be used. In that case, the insulator 282 includes at least oxygen and aluminum. When the insulator 282 having a function of capturing impurities such as hydrogen is provided in contact with the insulator 280, impurities such as hydrogen contained in the insulator 280 and the like can be captured. It is preferable to use, in particular, aluminum oxide having an amorphous structure for the insulator 282, in which case hydrogen can be captured or fixed more effectively in some cases. Accordingly, the transistor 200 and the semiconductor device which have favorable characteristics and high reliability can be manufactured.

As the insulator 282, a film of aluminum oxide is preferably formed by a sputtering method, and a film of aluminum oxide is further preferably formed by a pulsed DC sputtering method using an aluminum target in an atmosphere containing an oxygen gas. The use of a pulsed DC sputtering method can achieve more uniform film thickness and improve the sputtering rate and film quality. Here, RF (Radio Frequency) power may be applied to the substrate. The amount of oxygen implanted into a layer below the insulator 282 can be controlled depending on the amount of the RF power applied to the substrate. For example, the amount of oxygen implanted into the layer below the insulator 282 decreases as the RF power decreases, and the amount of oxygen is easily saturated even when the insulator 282 has a small thickness. Moreover, the amount of oxygen implanted into the layer below the insulator 282 increases as the RF power increases.

The RF power is higher than or equal to 0 W/cm² and lower than or equal to 1.86 W/cm², for example. In other words, the amount of oxygen to be implanted can be changed to be appropriate for the characteristics of the transistor, with the RF power used at the time of forming the insulator 282. Accordingly, an appropriate amount of oxygen for improving the reliability of the transistor can be implanted.

The RF frequency is preferably higher than or equal to 10 MHz. The typical frequency is 13.56 MHz. The higher the RF frequency is, the less damage the substrate receives.

Although FIG. 9A to FIG. 9D and the like illustrate a single-layer structure of the insulator 282, the present invention is not limited thereto, and a stacked-layer structure of two or more layers may be employed. The insulator 282 may have a two-layer structure, for example.

An upper layer and a lower layer of the insulator 282 are preferably formed using the same material by different methods. For example, when a film of aluminum oxide is formed as the insulator 282 by a pulsed DC sputtering method using an aluminum target in an atmosphere containing an oxygen gas, RF power applied to the substrate in the formation of the lower layer of the insulator 282 and RF power applied to the substrate in the formation of the upper layer of the insulator 282 are preferably different from each other, and the RF power applied to the substrate in the formation of the lower layer of the insulator 282 is preferably lower than the RF power applied to the substrate in the formation of the upper layer of the insulator 282. Specifically, the lower layer of the insulator 282 is formed with the RF power applied to the substrate being higher than or equal to 0 W/cm² and lower than or equal to 0.62 W/cm², and the upper layer of the insulator 282 is formed with the RF power applied to the substrate being lower than or equal to 1.86 W/cm². More specifically, the lower layer of the insulator 282 is formed with the RF power applied to the substrate being 0 W/cm², and the upper layer of the insulator 282 is formed with the RF power applied to the substrate being 0.31 W/cm². With this structure, the insulator 282 can have an amorphous structure, and the amount of oxygen supplied to the insulator 280 can be adjusted.

Note that the RF power applied to the substrate in the formation of the lower layer of the insulator 282 may be higher than the RF power applied to the substrate in the formation of the upper layer pf the insulator 282. Specifically, the lower layer of the insulator 282 is formed with the RF power applied to the substrate being lower than or equal to 1.86 W/cm², and the upper layer of the insulator 282 is formed with the RF power applied to the substrate being higher than or equal to 0 W/cm² and lower than or equal to 0.62 W/cm². More specifically, the lower layer of the insulator 282 is formed with the RF power applied to the substrate being 1.86 W/cm², and the upper layer of the insulator 282 is formed with the RF power applied to the substrate being 0.62 W/cm². With this structure, the amount of oxygen supplied to the insulator 280 can be increased.

The thickness of the lower layer of the insulator 282 is greater than or equal to 1 nm and less than or equal to 20 nm, preferably greater than or equal to 1.5 nm and less than or equal to 15 nm, further preferably greater than or equal to 2 nm and less than or equal to 10 nm, still further preferably greater than or equal to 3 nm and less than or equal to 8 nm. With such a structure, the lower layer of the insulator 282 can have an amorphous structure regardless of the RF power. When the lower layer of the insulator 282 has an amorphous structure, the upper layer of the insulator 282 is likely to have an amorphous structure, so that the insulator 282 can have an amorphous structure.

Although the lower layer of the insulator 282 and the upper layer of the insulator 282 described above form the stacked-layer structure of the same material, the present invention is not limited thereto. The lower layer of the insulator 282 and the upper layer of the insulator 282 may form a stacked-layer structure of different materials.

The above is the description of structure examples of the transistor 200.

### [Capacitor 100]

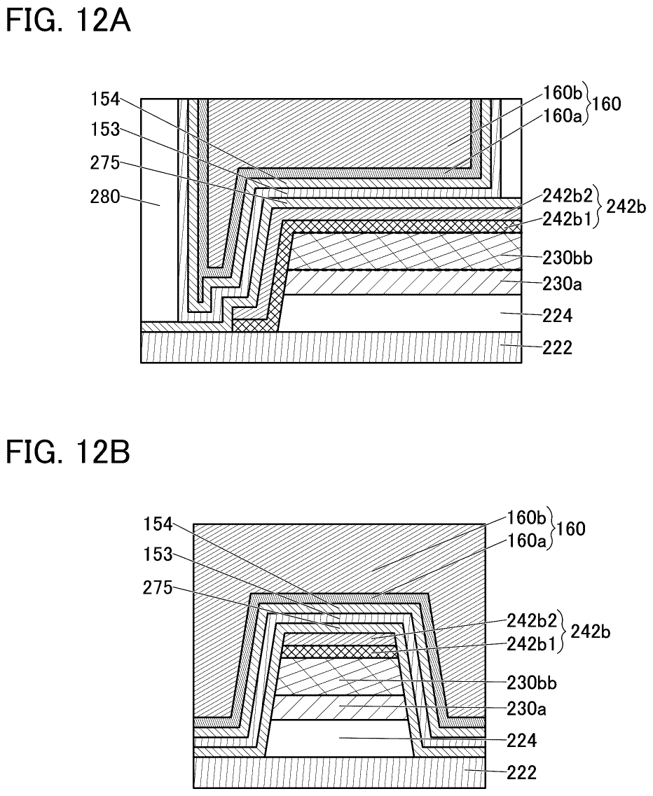

FIG. 12A is an enlarged view of the capacitor 100 in FIG. 9B and the vicinity thereof, and FIG. 12B is an enlarged view of the capacitor 100 in FIG. 9D and the vicinity thereof.

The capacitor 100 includes the conductor 242b, the insulator 275, the insulator 153, the insulator 154, and the conductor 160 (a conductor 160a and a conductor 160b). The conductor 242b functions as one of a pair of electrodes (also referred to as a lower electrode) of the capacitor 100, the conductor 160 functions as the other of the pair of electrodes (also referred to as an upper electrode) of the capacitor 100, and the insulator 275, the insulator 153, and the insulator 154 function as a dielectric of the capacitor 100.

The insulator 153, the insulator 154, the conductor 160a, and the conductor 160b are positioned in the opening 158 provided in the insulator 280. The insulator 153 is provided over the insulator 275, the insulator 154 is provided over the insulator 153, the conductor 160a is provided over the insulator 154, and the conductor 160b is provided over the conductor 160a.

The details will be described later; the insulator 153, the insulator 154, the conductor 160a, and the conductor 160b included in the capacitor 100 can be formed using the same materials in the same steps as the insulator 253, the insulator 254, the conductor 260a, and the conductor 260b included in the transistor 200. Thus, the insulator 153 is preferably formed using the same insulating material as the insulator 253, and the description of the insulator 253 can be referred to for the details. The insulator 154 is preferably formed using the same insulating material as the insulator 254, and the description of the insulator 254 can be referred to for the details. The conductor 160a is preferably formed using the same conductive material as the conductor 260a, and the description of the conductor 260a can be referred to for the details. The conductor 160b is preferably formed using the same conductive material as the conductor 260b, and the description of the conductor 260b can be referred to for the details.

When the insulator 153, the insulator 154, the conductor 160a, and the conductor 160b are formed using the same materials in the same steps as the insulator 253, the insulator 254, the conductor 260a, and the conductor 260b, the number of steps can be reduced in the manufacturing process of the semiconductor device.

The opening 158 is provided in the insulator 280 to reach the insulator 275. That is, the opening 158 can be regarded as including a region overlapping with the insulator 275. Alternatively, the opening 158 can be regarded as including a region overlapping with the conductor 242b with the insulator 275 therebetween. In that case, the conductor 160 includes a region overlapping with the conductor 242b with the insulator 275, the insulator 153, and the insulator 154 therebetween.

As described above, the insulator 280 is provided with the opening 258. That is, the insulator 280 has a first opening corresponding to part of the opening 258 and a second opening corresponding to the opening 158.

As illustrated in FIG. 9A, in a plan view, a region where the conductor 160 and the conductor 242b intersect with each other in the opening 158 functions as the capacitor 100. The region includes a region overlapping with the oxide 230b and functioning as the transistor 200. That is, the capacitor 100 can be provided without an excessive increase in the occupied area as compared with the transistor 200. In that case, miniaturization and high integration of the semiconductor device can be achieved. For example, in the case where the semiconductor device of one embodiment of the present invention is used as a memory cell of a storage device, the storage capacity per unit area can be increased.

The conductor 242b can serve as the lower electrode of the capacitor 100 as well as the other of the source electrode and the drain electrode of the transistor 200. Thus, part of the manufacturing process of the transistor 200 can serve as the manufacturing process of the capacitor 100; therefore, the productivity of the semiconductor device can be improved.

As illustrated in FIG. 12A, the end portion of the conductor 242b on the capacitor 100 side is preferably positioned outwardly from the end portion of the oxide 230. In other words, the conductor 242b covers the side surface of the oxide 230 on the capacitor 100 side. Since the conductor 242b functions as one of the pair of electrodes of the capacitor 100, this structure can increase the area where the pair of electrodes of the capacitor 100 overlap with each other. Thus, the capacitance value of the capacitor 100 can be increased.

As illustrated in FIG. 12A and FIG. 12B, the opening 158 can be also regarded as having a shape in which part of a structure body including the insulator 224, the oxide 230, the conductor 242, and the insulator 275 protrudes in an opening having the insulator 222 as its bottom surface and the insulator 280 as its side surface. Unlike in the opening 258, the top surface of the oxide 230b is covered with the conductor 242b and the insulator 275 in the opening 158; thus, the top surface of the oxide 230b is not exposed in the opening 158.

As illustrated in FIG. 12A and FIG. 12B, the insulator 153 is provided in contact with the bottom surface and the inner wall of the opening 158. Thus, the insulator 153 is in contact with the top surface of the insulator 275 and the side surface of the insulator 280. The insulator 154 is provided over the insulator 153 to be in contact with the top surface of the insulator 153, and the conductor 160 is provided to be in contact with the top surface of the insulator 154. Thus, the insulator 153, the insulator 154, and the conductor 160 are provided to cover the conductor 242b and the insulator 275 that partly protrude in the opening 158.

When the capacitor 100 has the above-described structure, as illustrated in FIG. 12A and FIG. 12B, the conductor 160 is provided to face the top surface of the conductor 242b, the side surface of the conductor 242b that is different from the side surface facing the conductor 242a (corresponding to the side surface on the A1 side in the capacitor 100a and the side surface on the A2 side in the capacitor 100b), the side surface of the conductor 242b on the A5 side, and the side surface of the conductor 242b on the A6 side with the insulator 153 and the insulator 154 therebetween. Accordingly, the capacitor 100 can be formed with the four surfaces of the conductor 242b; thus, the capacitance per unit area of the capacitor 100 can be increased. Thus, miniaturization and high integration of the semiconductor device can be achieved.

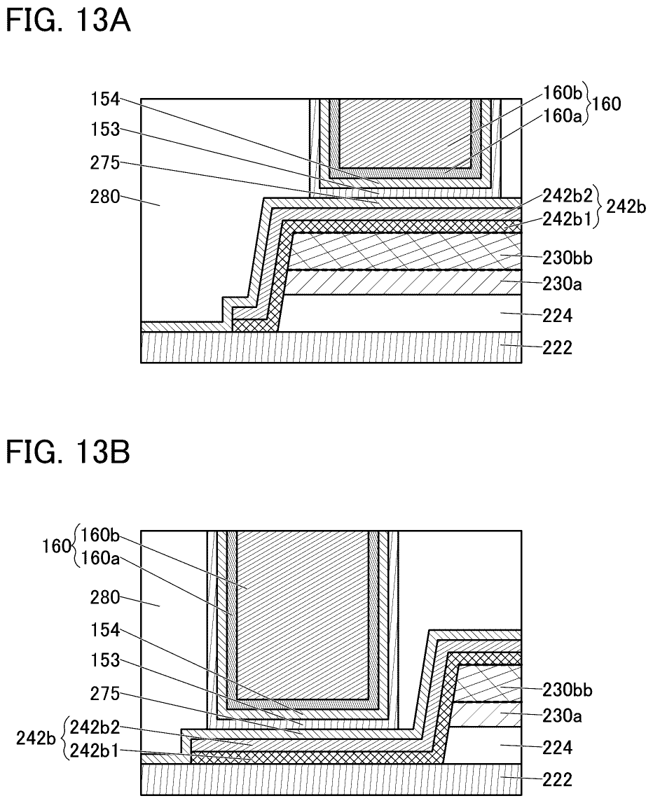

Note that the capacitor 100 may have a shape illustrated in FIG. 13A by optimizing a material used for the insulator functioning as a dielectric, the thickness of the insulator 280, and the like. Specifically, the side surface of the opening 158 that is different from the side surface facing the conductor 242a (corresponding to the side surface on the A1 side in the capacitor 100a and the side surface on the A2 side in the capacitor 100b) may overlap with the oxide 230b. In addition, the conductor 160 may be provided to face the top surface of the conductor 242b, the side surface of the conductor 242b on the A5 side, and the side surface of the conductor 242b on the A6 side with the insulator 153 and the insulator 154 therebetween. In this case, the capacitor 100 can be formed with the three surfaces of the conductor 242b. Alternatively, the capacitor 100 may have a shape illustrated in FIG. 13B, for example. Specifically, the opening 158 may be provided in a region not overlapping with the oxide 230b.

Although FIG. 12A, FIG. 13A, and FIG. 13B each illustrate a structure in which the sidewall of the opening 158 is substantially perpendicular to the top surface of the insulator 222, the present invention is not limited thereto. The sidewall of the opening 158 may have a tapered shape. The opening 258 and the opening 158 are formed in the same step; the details will be described later. For example, in the case where the sidewall of the opening 258 has a tapered shape as illustrated in FIG. 11C, the sidewall of the opening 158 also has a tapered shape. With the tapered shape of the sidewall of the opening 158, the coverage with the insulator 153 and the like can be improved in a later step, so that defects such as a void can be reduced.

The conductor 160 is formed to fill the opening 158 extending in the channel width direction of the transistor 200, i.e., the conductor 160 extends in the channel width direction of the transistor 200. Thus, when a plurality of transistors 200 and capacitors 100 are provided, the conductor 160 can function as a wiring. In this case, the insulator 153 and the insulator 154 also extend together with the conductor 160.

The insulator 275, the insulator 153, and the insulator 154 function as a dielectric of the capacitor 100. A region of the insulator 153 that functions as a dielectric of the capacitor 100 is sandwiched between the insulator 275 and the insulator 154.

The region 230bb of the oxide 230b is a low-resistance region. Thus, the region 230bb of the oxide 230b can function as the lower electrode of the capacitor 100 in some cases. In this case, the area where the pair of electrodes of the capacitor 100 overlap with each other can be increased. Thus, the capacitance value of the capacitor 100 can be increased.

The above is the description of the capacitor 100.

The conductor 240 is provided in contact with the inner wall of the opening in the insulator 285, the insulator 282, the insulator 280, the insulator 275, the conductor 242a, the insulator 222, the insulator 216, the insulator 214, and the insulator 212. The conductor 240 includes a region in contact with the top surface of the conductor 209.

The conductor 240 functions as a plug or a wiring for electrically connecting the transistor 200 to a circuit element such as a switch, a transistor, a capacitor, an inductor, a resistor, or a diode, a wiring, an electrode, or a terminal.

The conductor 240 preferably has a stacked-layer structure of the conductor 240a and the conductor 240b. For example, as illustrated in FIG. 9B, the conductor 240 can have a structure in which the conductor 240a is provided in contact with the inner wall of the opening and the conductor 240b is provided more inwardly than the conductor 240a. That is, the conductor 240a is positioned in the vicinity of the insulator 285, the insulator 282, the insulator 280, the insulator 275, the conductor 242a, the insulator 222, the insulator 216, the insulator 214, and the insulator 212.

A conductive material having a function of inhibiting passage of impurities such as water and hydrogen is preferably used for the conductor 240a. For example, tantalum, tantalum nitride, titanium, titanium nitride, ruthenium, ruthenium oxide, or the like is preferably used. The conductive material having a function of inhibiting passage of impurities such as water and hydrogen may be used as a form of a single layer or stacked layers. Moreover, impurities such as water and hydrogen contained in a layer above the insulator 282 can be inhibited from entering the oxide 230 through the conductor 240.

The conductor 240 also functions as a wiring and thus is preferably formed using a conductor having high conductivity. For example, a conductive material containing tungsten, copper, or aluminum as its main component can be used for the conductor 240b.

For example, it is preferable to use titanium nitride for the conductor 240a and use tungsten for the conductor 240b. In that case, the conductor 240a contains titanium and nitrogen, and the conductor 240b contains tungsten.

Although the transistor 200 having a structure in which the conductor 240 is a stack of the conductor 240a and the conductor 240b is illustrated, the present invention is not limited thereto. For example, the conductor 240 may have a single-layer structure or a stacked-layer structure of three or more layers. In the case where a structural body has a stacked-layer structure, layers may be distinguished by ordinal numbers corresponding to the formation order. Although not illustrated in FIG. 9B, the level of the top surface of the conductor 240 is higher than that of the top surface of the insulator 285 in some cases.

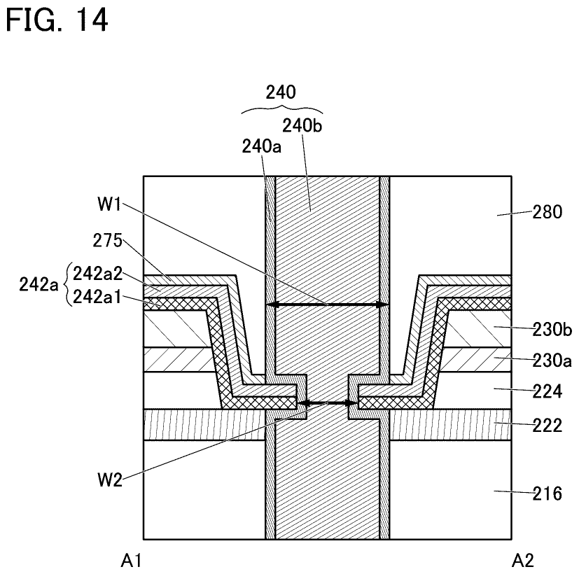

FIG. 14 is an enlarged view illustrating a region where the conductor 240 and the conductor 242a are in contact with each other and its vicinity. As illustrated in FIG. 14, in the A1-A2 direction, the conductor 240 includes a region with a width W1 and a with having a width W2. The width W1 corresponds to, for example, a distance between the interface between the insulator 280 and the conductor 240a on the transistor 200a side and the interface between the insulator 280 and the conductor 240a on the transistor 200b side. The width W2 corresponds to the width of the opening provided in the conductor 242a. Note that the width W1 corresponds to the width W1 described in Embodiment 1, and the width W2 corresponds to the width Wₘ described in Embodiment 1.

As illustrated in FIG. 14, the width W1 is preferably larger than the width W2. In this structure, the conductor 240 is in contact with at least part of the top surface and part of the side surface of the conductor 242a. Accordingly, the area of the region where the conductor 240 and the conductor 242a are in contact with each other can be increased. Note that in this specification and the like, a contact between the conductor 240 and the conductor 242a is referred to as a top side contact in some cases. As illustrated in FIG. 14, the conductor 240 may be in contact with part of the bottom surface of the conductor 242a. With such a structure, the area of the region where the conductor 240 and the conductor 242a are in contact with each other can be further increased.

The conductor 209 functions as part of a circuit element such as a switch, a transistor, a capacitor, an inductor, a resistor, or a diode, a wiring, an electrode, or a terminal.

The insulator 210 functions as an interlayer film. As the insulator 210, an insulator that can be used for the insulator 214, the insulator 216, or the like, described above, is preferably used.

### <Component Material for Semiconductor Device>

Component materials that can be used for the semiconductor device are described below.

### <<Substrate>>

As a substrate where the transistor 200 is formed, an insulator substrate, a semiconductor substrate, or a conductor substrate may be used. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate having an insulator region in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate including a metal nitride and a substrate including a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a storage element.

### <<Insulator>>

Examples of the insulator include an insulating oxide, an insulating nitride, an insulating oxynitride, an insulating nitride oxide, an insulating metal oxide, an insulating metal oxynitride, and an insulating metal nitride oxide.

As miniaturization and high integration of transistors progress, for example, a problem such as a leakage current may arise because of a thinner gate insulator. When a high-k material is used for the insulator functioning as a gate insulator, the voltage at the time of the operation of the transistor can be reduced while the physical thickness is maintained. By contrast, when a material with a low dielectric constant is used for the insulator functioning as an interlayer film, parasitic capacitance generated between wirings can be reduced. Thus, a material is preferably selected depending on the function of the insulator.

Examples of the insulator with a high dielectric constant include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the insulator with a low dielectric constant include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

When a transistor including a metal oxide is surrounded by an insulator having a function of inhibiting passage of oxygen and impurities such as hydrogen, the transistor can have stable electrical characteristics. As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

The insulator functioning as the gate insulator is preferably an insulator including a region containing oxygen to be released by heating. For example, when a structure is employed in which silicon oxide or silicon oxynitride including a region containing oxygen to be released by heating is in contact with the oxide 230, oxygen vacancies included in the oxide 230 can be compensated for.

### <<Conductor>>

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are conductive materials that are less likely to be oxidized or materials that maintain their conductivity even after absorbing oxygen. Alternatively, a semiconductor having high electrical conductivity, typified by polycrystalline silicon containing an impurity element such as phosphorus, or silicide such as nickel silicide may be used.

A stack of a plurality of conductive layers formed of the above materials may be used. For example, a stacked-layer structure combining a material containing the above metal element and a conductive material containing oxygen may be employed. In addition, a stacked-layer structure combining a material containing the above metal element and a conductive material containing nitrogen may be employed. Furthermore, a stacked-layer structure combining a material containing the above metal element, a conductive material containing oxygen, and a conductive material containing nitrogen may be employed.

In the case where an oxide is used for the channel formation region of the transistor, the conductor functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in the metal oxide where the channel is formed. A conductive material containing the above metal element and nitrogen may be used. For example, a conductive material containing nitrogen, such as titanium nitride or tantalum nitride, may be used. Indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon is added may be used. Indium gallium zinc oxide containing nitrogen may be used. With use of such a material, hydrogen contained in the metal oxide where the channel is formed can be captured in some cases. Alternatively, hydrogen entering from an external insulator or the like can be captured in some cases.

### <<Metal Oxide>>

The oxide 230 is preferably formed using a metal oxide functioning as a semiconductor (an oxide semiconductor). A metal oxide that can be used as the oxide 230 of the present invention is described below.

The metal oxide preferably contains at least indium or zinc. In particular, indium and zinc are preferably contained. Furthermore, aluminum, gallium, yttrium, tin, or the like is preferably contained in addition to them. Furthermore, one or more kinds selected from boron, titanium, iron, nickel, germanium, zirconium, molybdenum, lanthanum, cerium, neodymium, hafnium, tantalum, tungsten, magnesium, cobalt, and the like may be contained.

Here, the case where the metal oxide is an In-M-Zn oxide containing indium, the element M, and zinc is considered. The element M is aluminum, gallium, yttrium, or tin. Other elements that can be used as the element M include boron, titanium, iron, nickel, germanium, zirconium, molybdenum, lanthanum, cerium, neodymium, hafnium, tantalum, tungsten, magnesium, and cobalt. Note that two or more of the above elements may be used in combination as the element M. In particular, the element M is preferably one or more kinds selected from gallium, aluminum, yttrium, and tin.

It is particularly preferable to use an oxide containing indium (In), gallium (Ga), and zinc (Zn) (also referred to as IGZO) for the semiconductor layer of the transistor. Alternatively, an oxide containing indium (In), aluminum (Al), and zinc (Zn) (also referred to as IAZO) may be used for the semiconductor layer of the transistor. Alternatively, an oxide containing indium (In), aluminum (Al), gallium (Ga), and zinc (Zn) (IAGZO or IGAZO) may be used for the semiconductor layer.

Note that in this specification and the like, a metal oxide containing nitrogen is also collectively referred to as a metal oxide in some cases. A metal oxide containing nitrogen may be referred to as a metal oxynitride.

Hereinafter, an oxide containing indium (In), gallium (Ga), and zinc (Zn) is described as an example of the metal oxide. Note that an oxide containing indium (In), gallium (Ga), and zinc (Zn) may be referred to as In—Ga—Zn oxide.

### <Classification of Crystal Structure>

Amorphous (including completely amorphous), CAAC (c-axis-aligned crystalline), nc (nanocrystalline), CAC (cloud-aligned composite), single crystal, and polycrystalline (poly crystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum that is obtained by GIXD (Grazing-Incidence XRD) measurement. Note that a GIXD method is also referred to as a thin film method or a Seemann-Bohlin method. Hereinafter, an XRD spectrum obtained from GIXD measurement is simply referred to as an XRD spectrum in some cases.

For example, the XRD spectrum of a quartz glass substrate shows a peak with a substantially bilaterally symmetrical shape. On the other hand, the peak of the XRD spectrum of an In—Ga—Zn oxide film having a crystal structure has a bilaterally asymmetrical shape. The bilaterally asymmetrical peak of the XRD spectrum clearly shows the existence of a crystal in the film or the substrate. In other words, the film or the substrate cannot be regarded as being in an amorphous state unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of a quartz glass substrate, which indicates that quartz glass is in an amorphous state. Furthermore, not a halo pattern but a spot-like pattern is observed in the diffraction pattern of an In—Ga—Zn oxide film formed at room temperature. This suggests that the In—Ga—Zn oxide film formed at room temperature is in an intermediate state, which is neither a single crystal nor polycrystal nor an amorphous state, and it cannot be concluded that the In—Ga—Zn oxide film is in an amorphous state.

### <<Structure of Oxide Semiconductor>>

Note that oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the thickness direction of a CAAC-OS film, the normal direction of the surface where the CAAC-OS film is formed, or the normal direction of the surface of the CAAC-OS film. The crystal region refers to a region having a periodic atomic arrangement. Note that when an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the orientation of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more minute crystals (crystals each of which has a maximum diameter less than 10 nm). In the case where the crystal region is formed of one minute crystal, the maximum diameter of the crystal region is less than 10 nm. In the case where the crystal region is formed of a large number of minute crystals, the maximum diameter of the crystal region may be approximately several tens of nanometers.

In the case of In—Ga—Zn oxide, the CAAC-OS tends to have a layered crystal structure (also referred to as a layered structure) in which a layer including indium (In) and oxygen (hereinafter, an In layer) and a layer including gallium (Ga), zinc (Zn), and oxygen (hereinafter, a (Ga,Zn) layer) are stacked. Note that indium and gallium can be replaced with each other. Therefore, indium may be included in the (Ga,Zn) layer. In addition, gallium may be included in the In layer. Note that zinc may be included in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at or around 2θ of 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of an incident electron beam passing through a sample (also referred to as a direct spot) as a symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (also referred to as grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure where a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably included to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be reduced by entry of impurities, formation of defects, or the like, the CAAC-OS can also be regarded as an oxide semiconductor that has small amounts of impurities and defects (e.g., oxygen vacancies). Thus, the physical properties of an oxide semiconductor including the CAAC-OS are stable. Therefore, the oxide semiconductor including the CAAC-OS is resistant to heat and has high reliability. In addition, the CAAC-OS is also stable with respect to high temperatures in the manufacturing process (what is called thermal budget). Accordingly, the use of the CAAC-OS for the transistor including a metal oxide in its channel formation region (referred to as an OS transistor in some cases) can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a minute crystal. Note that the size of the minute crystal is, for example, greater than or equal to 1 nm and less than or equal to 10 nm, particularly greater than or equal to 1 nm and less than or equal to 3 nm; thus, the minute crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2θ scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter greater than the diameter of a nanocrystal (e.g., greater than or equal to 50 nm). Meanwhile, in some cases, a plurality of spots in a ring-like region with a direct spot as the center are observed in the obtained electron diffraction pattern when the nc-OS film is subjected to electron diffraction (also referred to as nanobeam electron diffraction) using an electron beam with a probe diameter nearly equal to or less than the diameter of a nanocrystal (e.g., greater than or equal to 1 nm and less than or equal to 30 nm).

### [A-Like OS]

The a-like OS is an oxide semiconductor having a structure between those of the nc-OS and the amorphous oxide semiconductor. The a-like OS includes a void or a low-density region. That is, the a-like OS has lower crystallinity than the nc-OS and the CAAC-OS. Moreover, the a-like OS has a higher hydrogen concentration in the film than the nc-OS and the CAAC-OS.

### <<Composition of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state where one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide is a region having [In] higher than [In] in the composition of the CAC-OS film. Moreover, the second region is a region having [Ga] higher than [Ga] in the composition of the CAC-OS film. Alternatively, for example, the first region is a region having [In] higher than [In] in the second region and [Ga] lower than [Ga] in the second region. Moreover, the second region is a region having [Ga] higher than [Ga] in the first region and [In] lower than [In] in the first region.

Specifically, the first region is a region including indium oxide, indium zinc oxide, or the like as its main component. The second region is a region including gallium oxide, gallium zinc oxide, or the like as its main component. That is, the first region can be rephrased as a region including In as its main component. The second region can be rephrased as a region including Ga as its main component.

Note that a clear boundary between the first region and the second region cannot be observed in some cases.

In addition, in a material composition of a CAC-OS in In—Ga—Zn oxide that includes In, Ga, Zn, and O, there are regions including Ga as a main component in part of the CAC-OS and regions including In as a main component in another part of the CAC-OS. These regions are randomly present to form a mosaic pattern. Thus, it is suggested that the CAC-OS has a structure where metal elements are unevenly distributed.

The CAC-OS can be formed by a sputtering method under a condition where a substrate is not heated, for example. In addition, in the case of forming the CAC-OS by a sputtering method, one or more selected from an inert gas (typically, argon), an oxygen gas, and a nitrogen gas are used as a film formation gas. The proportion of the flow rate of an oxygen gas in the total flow rate of the film formation gas during film formation is preferably as low as possible. For example, the proportion of the flow rate of an oxygen gas in the total flow rate of the film formation gas during film formation is higher than or equal to 0% and lower than 30%, preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure where the region including In as its main component (the first region) and the region including Ga as its main component (the second region) are unevenly distributed and mixed.

Here, the first region is a region having higher conductivity than the second region. That is, when carriers flow through the first region, the conductivity of a metal oxide is exhibited. Accordingly, when the first regions are distributed in a metal oxide like a cloud, high field-effect mobility (μ) can be achieved.

On the other hand, the second region is a region having a higher insulating property than the first region. In other words, when the second regions are distributed in a metal oxide, leakage current can be inhibited.

Thus, in the case where the CAC-OS is used for a transistor, the complementary action of the conductivity due to the first region and the insulating property due to the second region enables the CAC-OS to have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when a CAC-OS is used for a transistor, high on-state current (Iₒₙ), a high field-effect mobility (μ), and favorable switching operation can be achieved.

A transistor using the CAC-OS has high reliability. Thus, the CAC-OS is most suitable for a variety of semiconductor devices such as a display device.

Oxide semiconductors have various structures with different properties. Two or more kinds among an amorphous oxide semiconductor, a polycrystalline oxide semiconductor, an a-like OS, a CAC-OS, an nc-OS, and a CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be achieved. In addition, a transistor with high reliability can be achieved.

An oxide semiconductor having a low carrier concentration is preferably used for a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet still further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, nitrogen, an alkali metal, an alkaline earth metal, iron, nickel, and silicon. Note that an impurity in an oxide semiconductor refers to, for example, an element other than the main components of the oxide semiconductor. For example, an element with a concentration lower than 0.1 atomic % can be regarded as an impurity.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon (the concentration obtained by SIMS) in the semiconductor is set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor including an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. Alternatively, when the oxide semiconductor contains nitrogen, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm³, preferably lower than or equal to 5×10¹⁸ atoms/cm³, further preferably lower than or equal to 1×10¹⁸ atoms/cm³, still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the oxide semiconductor is preferably reduced as much as possible. Specifically, the concentration of hydrogen in the oxide semiconductor, which is obtained by SIMS, is set lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, the transistor can have stable electrical characteristics.

### <<Other Semiconductor Materials>>

The oxide 230 can be rephrased as a semiconductor layer including a channel formation region of the transistor 200. A semiconductor material that can be used for the semiconductor layer is not limited to the above metal oxides. A semiconductor material that has a band gap (a semiconductor material that is not a zero-gap semiconductor) may be used for the semiconductor layer. For example, a single element semiconductor such as silicon, a compound semiconductor such as gallium arsenide, or a layered substance functioning as a semiconductor (also referred to as an atomic layer material or a two-dimensional material) is preferably used as a semiconductor material. In particular, a layered substance functioning as a semiconductor is favorably used as a semiconductor material.

Here, in this specification and the like, the layered substance generally refers to a group of materials having a layered crystal structure. In the layered crystal structure, layers formed by covalent bonding or ionic bonding are stacked with bonding such as the Van der Waals force, which is weaker than covalent bonding or ionic bonding. The layered substance has high electrical conductivity in a unit layer, that is, high two-dimensional electrical conductivity. When a material that functions as a semiconductor and has high two-dimensional electrical conductivity is used for a channel formation region, a transistor having a high on-state current can be provided.

Examples of the layered substance include graphene, silicene, and chalcogenide. Chalcogenide is a compound containing chalcogen. Chalcogen is a general term for elements belonging to Group 16 and includes oxygen, sulfur, selenium, tellurium, polonium, and livermorium. Examples of chalcogenide include transition metal chalcogenide and chalcogenide of Group 13 elements.

For a semiconductor layer of a transistor, transition metal chalcogenide functioning as a semiconductor is preferably used, for example. Specific examples of the transition metal chalcogenide that can be used for the semiconductor layer include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂). The use of the transition metal chalcogenide for the semiconductor layer enables a semiconductor device with a high on-state current to be provided.

### <Example of Manufacturing Method of Semiconductor Device>

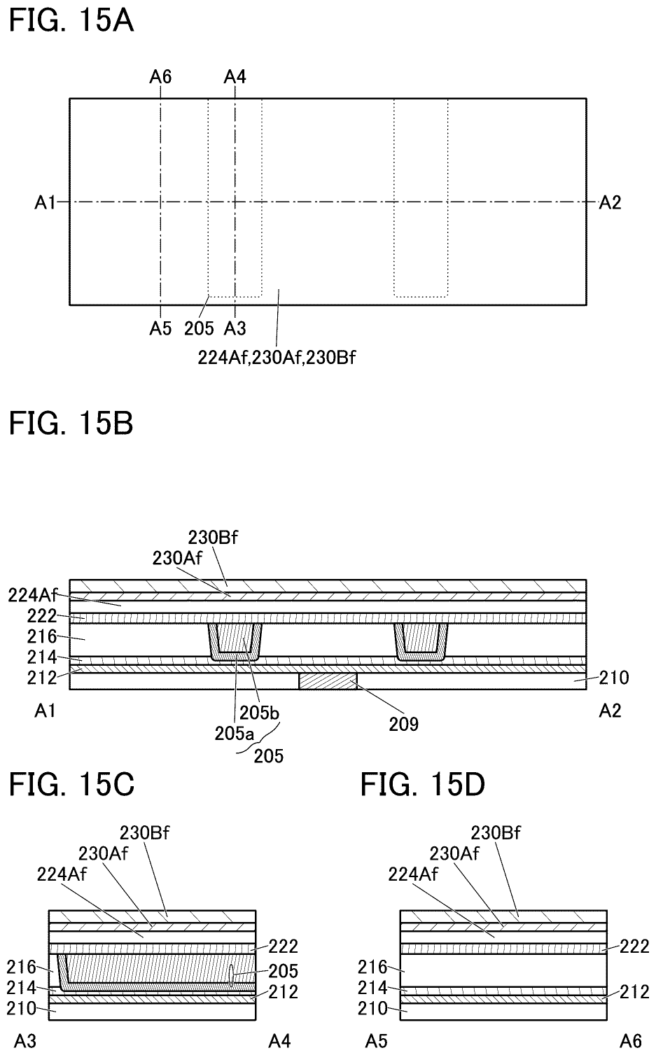

Next, a method for manufacturing the semiconductor device of one embodiment of the present invention illustrated in FIG. 9A to FIG. 9D is described with reference to FIG. 15A to FIG. 27D.

Note that A of each drawing is a top view. Moreover, B of each drawing is a cross-sectional view corresponding to a portion indicated by the dashed-dotted line A1-A2 in A of each drawing, and is also a cross-sectional view in the channel length direction of the transistor 200. Furthermore, C of each drawing is a cross-sectional view corresponding to a portion indicated by the dashed-dotted line A3-A4 in A of each drawing, and is also a cross-sectional view in the channel width direction of the transistor 200. Furthermore, D of each drawing is a cross-sectional view of a portion indicated by the dashed-dotted line A5-A6 in A of each drawing. Note that for clarity of the drawing, some components are omitted in the top view of A of each drawing.

Hereinafter, a film of an insulating material for forming an insulator, a film of a conductive material for forming a conductor, or a film of a semiconductor material for forming a semiconductor can be formed by a sputtering method, a CVD method, an MBE method, a PLD method, an ALD method, or the like as appropriate.

Examples of a sputtering method include an RF sputtering method in which a high-frequency power source is used as a sputtering power source, a DC sputtering method in which a DC power source is used, and a pulsed DC sputtering method in which a voltage applied to an electrode is changed in a pulsed manner. An RF sputtering method is mainly used in the case where an insulating film is formed, and a DC sputtering method is mainly used in the case where a metal conductive film is formed. A pulsed DC sputtering method is mainly used in the case where a film of a compound such as an oxide, a nitride, or a carbide is formed by a reactive sputtering method.

Note that the CVD method can be classified into a plasma CVD (PECVD) method using plasma, a thermal CVD (TCVD) method using heat, a photo CVD method using light, and the like. Moreover, the CVD methods can be classified into a metal CVD (MCVD) method and a metal organic CVD (MOCVD) method depending on a source gas to be used.

A high-quality film can be obtained at a relatively low temperature by a plasma CVD method. Furthermore, a thermal CVD method is a film formation method that does not use plasma and thus enables less plasma damage to an object. For example, a wiring, an electrode, an element (a transistor, a capacitor, or the like), or the like included in a semiconductor device may be charged up by receiving charge from plasma. In that case, accumulated charge may break the wiring, the electrode, the element, or the like included in the semiconductor device. In contrast, such plasma damage is not caused in the case of a thermal CVD method, which does use plasma, and thus the yield of the semiconductor device can be increased. In addition, a thermal CVD method does not cause plasma damage during film formation, so that a film with few defects can be obtained.

As an ALD method, a thermal ALD method, in which a precursor and a reactant react with each other only by a thermal energy, a PEALD method, in which a reactant excited by plasma is used, or the like can be used.

A CVD method and an ALD method are different from a sputtering method in which particles ejected from a target or the like are deposited. Thus, a CVD method and an ALD method are film formation methods that enable favorable step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a CVD method, in some cases.

By a CVD method, a film with a certain composition can be formed depending on the flow rate ratio of the source gases. For example, by a CVD method, a film whose composition is continuously changed can be formed by changing the flow rate ratio of the source gases during film formation. In the case where the film is formed while the flow rate ratio of the source gases is changed, as compared with the case where the film is formed using a plurality of film formation chambers, the time taken for the film formation can be shortened because the time taken for transfer or pressure adjustment is not required. Thus, the productivity of the semiconductor device can be increased in some cases.

By an ALD method, a film with a freely selected composition can be formed by concurrently introducing different kinds of precursors. In the case where different kinds of precursors are introduced, a film with a freely selected composition can be formed by controlling the number of cycles for each of the precursors.

First, a substrate (not illustrated) is prepared, and the insulator 210 and the conductor 209 are formed over the substrate (see FIG. 15A to FIG. 15D).

Next, the insulator 212 is deposited over the insulator 210 and the conductor 209 (see FIG. 15A to FIG. 15D). The insulator 212 is preferably formed by a sputtering method. By using a sputtering method that does not need to use a molecule containing hydrogen as a film formation gas, the hydrogen concentration in the insulator 212 can be reduced. Without limitation to a sputtering method, the insulator 212 may be formed by a CVD method, an MBE method, a PLD method, an ALD method, or the like as appropriate.

In this embodiment, as the insulator 212, a film of silicon nitride is formed by a pulsed DC sputtering method using a silicon target in an atmosphere containing a nitrogen gas. The use of a pulsed DC sputtering method can inhibit generation of particles due to arcing on the target surface, achieving more uniform film thickness. In addition, by using the pulsed voltage, rising and falling in discharge can be made steep as compared with the case where a high-frequency voltage is used. As a result, power can be supplied to an electrode more efficiently to improve the sputtering rate and film quality.

The use of an insulator that is less permeable to impurities such as water and hydrogen, e.g., silicon nitride, can inhibit diffusion of impurities such as water and hydrogen included in a layer below the insulator 212. When an insulator that is less permeable to copper, such as silicon nitride, is used for the insulator 212, even in the case where a metal that is likely to diffuse, such as copper, is used for a conductor (not illustrated) in a layer below the insulator 212, upward diffusion of the metal through the insulator 212 can be inhibited.

Next, the insulator 214 is deposited over the insulator 212 (see FIG. 15A to FIG. 15D). The insulator 214 is preferably formed by a sputtering method. By using a sputtering method that does not need to use a molecule containing hydrogen as a film formation gas, the hydrogen concentration in the insulator 214 can be reduced. Without limitation to a sputtering method, the insulator 214 may be formed by a CVD method, an MBE method, a PLD method, an ALD method, or the like as appropriate.

In this embodiment, as the insulator 214, a film of aluminum oxide is formed by a pulsed DC sputtering method using an aluminum target in an atmosphere containing an oxygen gas. The use of a pulsed DC sputtering method can achieve more uniform film thickness and improve the sputtering rate and film quality. Here, RF power may be applied to the substrate. The amount of oxygen implanted into a layer below the insulator 214 can be controlled depending on the amount of the RF power applied to the substrate. The RF power is higher than or equal to 0 W/cm² and lower than or equal to 1.86 W/cm². In other words, the amount of oxygen to be implanted can be changed to be appropriate for the characteristics of the transistor, with the RF power used at the time of forming the insulator 214. Accordingly, an appropriate amount of oxygen for improving the reliability of the transistor can be implanted. The RF frequency is preferably higher than or equal to 10 MHz. The typical frequency is 13.56 MHz. The higher the RF frequency is, the less damage the substrate receives.

A metal oxide having an amorphous structure and an excellent function of capturing and fixing hydrogen, such as aluminum oxide, is preferably used for the insulator 214. In this case, the insulator 214 captures or fixes hydrogen included in the insulator 216 and the like and prevents the hydrogen from diffusing into the oxide 230. Aluminum oxide having an amorphous structure or amorphous aluminum oxide is particularly preferably used for the insulator 214, in which case hydrogen can sometimes be captured or fixed more effectively. Accordingly, the transistor 200 and the semiconductor device which have favorable characteristics and high reliability can be manufactured.

Next, the insulator 216 is deposited over the insulator 214. The insulator 216 is preferably formed by a sputtering method. By using a sputtering method that does not need to use a molecule containing hydrogen as a film formation gas, the hydrogen concentration in the insulator 216 can be reduced. Without limitation to a sputtering method, the insulator 216 may be formed by a CVD method, an MBE method, a PLD method, an ALD method, or the like as appropriate.

In this embodiment, as the insulator 216, a film of silicon oxide is formed by a pulsed DC sputtering method using a silicon target in an atmosphere containing an oxygen gas. The use of a pulsed DC sputtering method can achieve more uniform film thickness and improve the sputtering rate and film quality.

The insulator 212, the insulator 214, and the insulator 216 are preferably successively formed without exposure to the air. For example, a multi-chamber film formation apparatus is used. As a result, the amounts of hydrogen in the formed insulator 212, insulator 214, and insulator 216 can be reduced, and furthermore, entry of hydrogen into the films in intervals between film formation steps can be inhibited.

Then, an opening reaching the insulator 214 is formed in the insulator 216. Examples of the opening include a groove and a slit. A region where an opening is formed is referred to as an opening portion in some cases. Wet etching may be used for the formation of the opening; however, dry etching is preferably used for microfabrication. As the insulator 214, it is preferable to select an insulator that functions as an etching stopper film used in forming the groove by etching the insulator 216. For example, in the case where silicon oxide or silicon oxynitride is used for the insulator 216 in which the groove is to be formed, silicon nitride, aluminum oxide, or hafnium oxide is preferably used for the insulator 214.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, a structure may be employed in which different high-frequency voltages are applied to one of the parallel plate electrodes. Alternatively, a structure may be employed in which high-frequency voltages with the same frequency are applied to the parallel plate electrodes. Alternatively, a structure may be employed in which high-frequency voltages with different frequencies are applied to the parallel plate electrodes. Alternatively, a dry etching apparatus including a high-density plasma source can be used. As the dry etching apparatus including a high-density plasma source, an inductively coupled plasma (ICP) etching apparatus or the like can be used, for example.

After the formation of the opening, a conductive film to be the conductor 205a is deposited. The conductive film desirably includes a conductor having a function of inhibiting passage of oxygen. For example, tantalum nitride, tungsten nitride, or titanium nitride can be used. Alternatively, a stacked-layer film of the conductor having a function of inhibiting passage of oxygen and tantalum, tungsten, titanium, molybdenum, aluminum, copper, or a molybdenum-tungsten alloy can be used. The conductive film can be formed by a sputtering method, a CVD method, an MBE method, a PLD method, an ALD method, or the like.

In this embodiment, a film of titanium nitride is formed as the conductive film to be the conductor 205a. When such a metal nitride is used for a layer below the conductor 205b, oxidation of the conductor 205b by the insulator 216 or the like can be inhibited. Furthermore, even when a metal that is likely to diffuse, such as copper, is used for the conductor 205b, the metal can be prevented from diffusing to the outside through the conductor 205a.

Next, a conductive film to be the conductor 205b is formed. Tantalum, tungsten, titanium, molybdenum, aluminum, copper, a molybdenum-tungsten alloy, or the like can be used for the conductive film. The conductive film can be formed by a plating method, a sputtering method, a CVD method, an MBE method, a PLD method, an ALD method, or the like. In this embodiment, a film of tungsten is formed as the conductive film.

Then, CMP treatment is performed to remove parts of the conductive film to be the conductor 205a and the conductive film to be the conductor 205b, so that the insulator 216 is exposed (see FIG. 15A to FIG. 15D). As a result, the conductor 205a and the conductor 205b remain only in the opening portion. Note that the insulator 216 is partly removed by the CMP treatment in some cases.

Next, the insulator 222 is deposited over the insulator 216 and the conductor 205 (see FIG. 15A to FIG. 15D). A film of an insulator containing an oxide of one or both of aluminum and hafnium is preferably formed as the insulator 222. Note that as the insulator containing an oxide of one or both of aluminum and hafnium, aluminum oxide, hafnium oxide, an oxide containing aluminum and hafnium (hafnium aluminate), or the like is preferably used. Alternatively, hafnium-zirconium oxide is preferably used. The insulator containing an oxide of one or both of aluminum and hafnium has a barrier property against oxygen, hydrogen, and water. When the insulator 222 has a barrier property against hydrogen and water, hydrogen and water included in components provided around the transistor 200 are inhibited from diffusing into the transistor 200 through the insulator 222, and generation of oxygen vacancies in the oxide 230 can be inhibited.

The insulator 222 can be formed by a sputtering method, a CVD method, an MBE method, a PLD method, an ALD method, or the like. In this embodiment, as the insulator 222, a film of hafnium oxide is formed by an ALD method. It is particularly preferable to use a method for forming hafnium oxide with a reduced hydrogen concentration, which is one embodiment of the present invention.

Subsequently, heat treatment is preferably performed. The heat treatment is performed at higher than or equal to 250° C. and lower than or equal to 650° C., preferably higher than or equal to 300° C. and lower than or equal to 500° C., further preferably higher than or equal to 320° C. and lower than or equal to 450° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in an atmosphere of mixing a nitrogen gas and an oxygen gas, the proportion of the oxygen gas is approximately 20%. The heat treatment may be performed under a reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the insulator 222 and the like as much as possible.

In this embodiment, as the heat treatment, treatment is performed at 400° C. for one hour with a flow rate ratio of a nitrogen gas to an oxygen gas being 4:1 after the formation of the insulator 222. By the heat treatment, impurities such as water and hydrogen contained in the insulator 222 can be removed, for example. In the case where an oxide containing hafnium is used for the insulator 222, the insulator 222 is partly crystallized by the heat treatment in some cases. The heat treatment can also be performed after the deposition of the insulator 224, for example.

Next, an insulating film 224Af is formed over the insulator 222 (see FIG. 15A to FIG. 15D). The insulating film 224Af can be formed by a sputtering method, a CVD method, an MBE method, a PLD method, an ALD method, or the like. In this embodiment, for the insulating film 224Af, a film of silicon oxide is deposited by a sputtering method. By using a sputtering method that does not need to use a molecule containing hydrogen as a film formation gas, the hydrogen concentration in the insulating film 224Af can be reduced. The hydrogen concentration in the insulating film 224Af is preferably reduced in this manner because the insulating film 224Af is in contact with the oxide 230a in a later step.

Next, an oxide film 230Af and an oxide film 230Bf are formed in this order over the insulating film 224Af (see FIG. 15A to FIG. 15D). Note that the oxide film 230Af and the oxide film 230Bf are preferably formed successively without being exposed to an atmospheric environment. By the film formation without exposure to the air, impurities or moisture from the atmospheric environment can be prevented from being attached onto the oxide film 230Af and the oxide film 230Bf, so that the vicinity of the interface between the oxide film 230Af and the oxide film 230Bf can be kept clean.

The oxide film 230Af and the oxide film 230Bf can be deposited using a sputtering method, a CVD method, an MBE method, a PLD method, an ALD method, or the like. In this embodiment, the oxide film 230Af and the oxide film 230Bf are deposited by a sputtering method.

For example, in the case where the oxide film 230Af and the oxide film 230Bf are deposited by a sputtering method, oxygen or a mixed gas of oxygen and a noble gas is used as a sputtering gas. Increasing the proportion of oxygen contained in the sputtering gas can increase the amount of excess oxygen in the formed oxide films. In the case where the oxide films are formed by a sputtering method, the above In-M-Zn oxide target or the like can be used.

In particular, when the oxide film 230Af is formed, part of oxygen contained in the sputtering gas is supplied to the insulator 224 in some cases. Thus, the proportion of oxygen contained in the sputtering gas is higher than or equal to 70%, preferably higher than or equal to 80%, further preferably 100%.

In the case where the oxide film 230Bf is deposited by a sputtering method and the proportion of oxygen contained in the sputtering gas for film formation is higher than 30% and lower than or equal to 100%, preferably higher than or equal to 70% and lower than or equal to 100%, an oxygen-excess oxide semiconductor is formed. In a transistor including an oxygen-excess oxide semiconductor for its channel formation region, relatively high reliability can be obtained. Note that one embodiment of the present invention is not limited thereto. In the case where the oxide film 230Bf is formed by a sputtering method and the proportion of oxygen contained in the sputtering gas for film formation is higher than or equal to 1% and lower than or equal to 30%, preferably higher than or equal to 5% and lower than or equal to 20%, an oxygen-deficient oxide semiconductor is formed. In a transistor including an oxygen-deficient oxide semiconductor for its channel formation region, relatively high field-effect mobility can be obtained. Furthermore, when the film formation is performed while the substrate is being heated, the crystallinity of the oxide film can be improved.

In this embodiment, the oxide film 230Af is deposited by a sputtering method using an oxide target with In:Ga:Zn=1:3:4 [atomic ratio]. In addition, the oxide film 230Bf is de by a sputtering method using an oxide target with In:Ga:Zn=4:2:4.1 [atomic ratio], an oxide target with In:Ga:Zn=1:1:1 [atomic ratio], an oxide target with In:Ga:Zn=1:1:1.2 [atomic ratio], or an oxide target with In:Ga:Zn=1:1:2 [atomic ratio]. Note that each of the oxide films is preferably formed so as to have characteristics required for the oxide 230a and the oxide 230b by selecting the film formation conditions and the atomic ratios as appropriate.

Note that the insulating film 224Af, the oxide film 230Af, and the oxide film 230Bf are preferably formed by a sputtering method without exposure to the air. For example, a multi-chamber film formation apparatus is used. As a result, entry of hydrogen into the insulating film 224Af, the oxide film 230Af, and the oxide film 230Bf in intervals between film formation steps can be inhibited.

The oxide film 230Af and the oxide film 230Bf may be formed by an ALD method. An ALD method is preferably employed for the deposition of the oxide film 230Af and the oxide film 230Bf, in which case a film with a uniform thickness can be formed even in a groove or an opening portion having a high aspect ratio. Employing a PEALD method is preferable because the oxide film 230Af and the oxide film 230Bf can be formed at a lower temperature than that in the case of employing a thermal ALD method.

Next, heat treatment is preferably performed. The heat treatment is performed in a temperature range where the oxide film 230Af and the oxide film 230Bf do not become polycrystals, i.e., at higher than or equal to 250° C. and lower than or equal to 650° C., preferably higher than or equal to 400° C. and lower than or equal to 600° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, in the case where the heat treatment is performed in an atmosphere of mixing a nitrogen gas and an oxygen gas, the proportion of the oxygen gas is approximately 20%. The heat treatment may be performed under a reduced pressure. Alternatively, the heat treatment may be performed in an atmosphere containing an oxidizing gas at 10 ppm or more, 1% or more, or 10% or more in order to compensate for oxygen released, after heat treatment is performed in a nitrogen gas or inert gas atmosphere.

The gas used in the above heat treatment is preferably highly purified. For example, the amount of moisture contained in the gas used in the above heat treatment is less than or equal to 1 ppb, preferably less than or equal to 0.1 ppb, further preferably less than or equal to 0.05 ppb. The heat treatment performed using a highly purified gas can prevent entry of moisture or the like into the oxide film 230Af, the oxide film 230Bf, and the like as much as possible.

In this embodiment, as the heat treatment, treatment is performed at 400° C. for one hour with a flow rate ratio of a nitrogen gas to an oxygen gas being 4:1. By the heat treatment using the oxygen gas, impurities such as carbon, water, and hydrogen in the oxide film 230Af and the oxide film 230Bf can be reduced, for example. The reduction of impurities in the films in this manner improves the crystallinity of the oxide film 230Bf, thereby offering a dense structure with a higher density. Thus, crystalline regions in the oxide film 230Af and the oxide film 230Bf are expanded, so that in-plane variations of the crystalline regions in the oxide film 230Af and the oxide film 230Bf o can be reduced. Accordingly, an in-plane variation of electrical characteristics of the transistor 200 can be reduced.

By performing the heat treatment, hydrogen in the insulator 216, the insulating film 224Af, the oxide film 230Af, and the oxide film 230Bf moves into the insulator 222 and is absorbed by the insulator 222. In other words, hydrogen in the insulator 216, the insulating film 224Af, the oxide film 230Af, and the oxide film 230Bf diffuses into the insulator 222. Accordingly, the hydrogen concentration in the insulator 222 increases, while the hydrogen concentrations in the insulator 216, the insulating film 224Af, the oxide film 230Af, and the oxide film 230Bf decrease.

In particular, the insulating film 224Af functions as a gate insulator of the transistor 200, and the oxide film 230Af and the oxide film 230Bf function as the channel formation region of the transistor 200. Thus, the transistor 200 preferably includes the insulating film 224Af, the oxide film 230Af, and the oxide film 230Bf with reduced hydrogen concentrations to have favorable reliability.

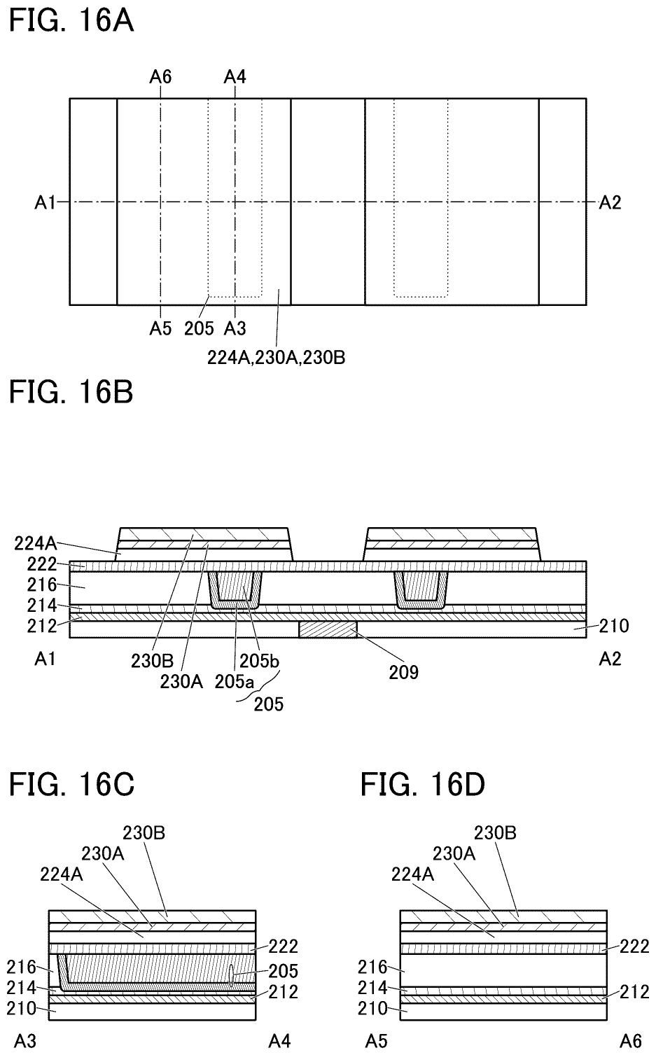

Next, the insulating film 224Af, the oxide film 230Af, and the oxide film 230Bf are processed into a band shape by a lithography method to form an insulating layer 224A, an oxide layer 230A, and an oxide layer 230B (see FIG. 16A to FIG. 16D). Here, the insulating layer 224A, the oxide layer 230A, and the oxide layer 230B are formed to extend in a direction parallel to the dashed-dotted line A3-A4 (the channel width direction of the transistor 200 or the Y direction illustrated in FIG. 9A). Here, the insulating layer 224A, the oxide layer 230A, and the oxide layer 230B are formed to at least partly overlap with the conductor 205. A dry etching method or a wet etching method can be used for the processing. Processing by a dry etching method is suitable for microfabrication. The insulating film 224Af, the oxide film 230Af, and the oxide film 230Bf may be processed under different conditions.

Note that in a lithography method, first, a resist is exposed to light through a mask. Next, a region exposed to light is removed or left using a developing solution, so that a resist mask is formed. Then, etching treatment through the resist mask is conducted, whereby a conductor, a semiconductor, an insulator, or the like can be processed into a desired shape. The resist mask is formed through, for example, exposure of the resist to KrF excimer laser light, ArF excimer laser light, EUV (Extreme Ultraviolet) light, or the like. A liquid immersion technique may be employed in which a gap between a substrate and a projection lens is filled with a liquid (e.g., water) in light exposure. An electron beam or an ion beam may be used instead of the light. Note that a mask is unnecessary in the case of using an electron beam or an ion beam. Note that the resist mask can be removed by dry etching treatment such as ashing, wet etching treatment, wet etching treatment after dry etching treatment, or dry etching treatment after wet etching treatment.

In addition, a hard mask formed of an insulator or a conductor may be used under the resist mask. In the case where a hard mask is used, a hard mask with a desired shape can be formed in the following manner: an insulating film or a conductive film that is the hard mask material is formed over the oxide film 230Bf, a resist mask is formed thereover, and then the hard mask material is etched. The etching of the oxide film 230Bf may be performed after removing the resist mask or with the resist mask remaining. In the latter case, the resist mask sometimes disappears during the etching. The hard mask may be removed by etching after the etching of the oxide film 230Bf. Meanwhile, the hard mask is not necessarily removed when the hard mask material does not affect later steps or can be utilized in later steps.

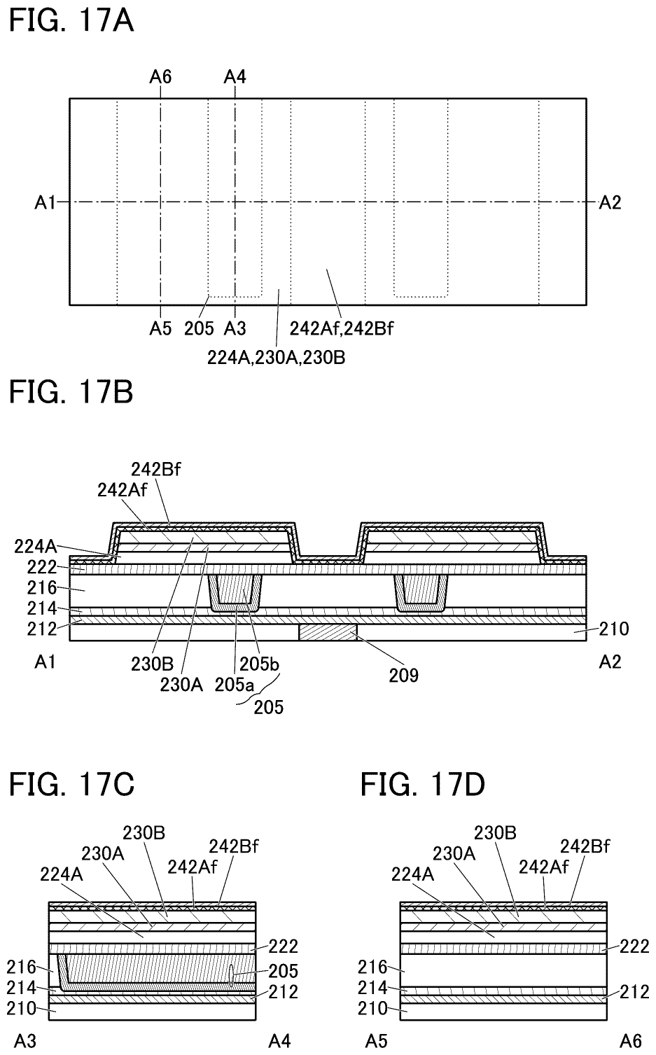

Next, a conductive film 242Af and a conductive film 242Bf are formed in this order over the insulator 222 and the oxide layer 230B (see FIG. 17A to FIG. 17D). The conductive film 242Af and the conductive film 242Bf can be formed by a sputtering method, a CVD method, an MBE method, a PLD method, an ALD method, or the like. For example, tantalum nitride may be deposited by a sputtering method for the conductive film 242Af and tungsten may be deposited for the conductive film 242Bf. Note that heat treatment may be performed before the deposition of the conductive film 242Af. This heat treatment may be performed under reduced pressure, and the conductive film 242Af may be successively formed without exposure to the air. Such treatment can remove moisture and hydrogen adsorbed onto the surface of the oxide layer 230B, and further can reduce the moisture concentration and the hydrogen concentration in the oxide layer 230A and the oxide layer 230B. The heat treatment is preferably performed at a temperature higher than or equal to 100° C. and lower than or equal to 400° C. In this embodiment, the heat treatment is performed at 200° C.

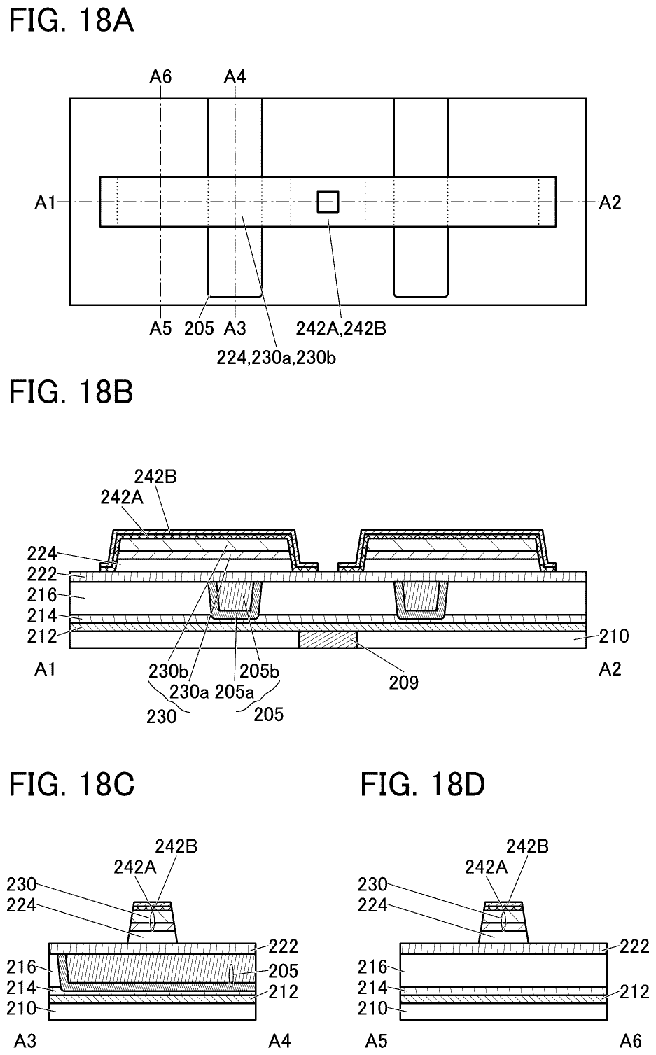

Next, the insulating layer 224A, the oxide layer 230A, the oxide layer 230B, the conductive film 242Af, and the conductive film 242Bf are processed by a lithography method to form an island-shaped insulator 224, an island-shaped oxide 230a, an island-shaped oxide 230b, and island-shaped conductive layer 242A and conductive layer 242B each having an opening (see FIG. 18A to FIG. 18D). For example, the insulating layer 224A, the oxide layer 230A, the oxide layer 230B, the conductive film 242Af, and the conductive film 242Bf are processed into the island-shaped insulator 224, the island-shaped oxide 230a, the island-shaped oxide 230b, and the conductive layer 242A and the conductive layer 242B each extending in a direction parallel to the dashed-dotted line A1-A2 (the channel length direction of the transistor 200 or the X direction illustrated in FIG. 9A). Then, the conductive layer 242A and the conductive layer 242B are processed into the island-shaped conductive layer 242A and conductive layer 242B each having an opening. Alternatively, for example, the insulating layer 224A, the oxide layer 230A, the oxide layer 230B, the conductive film 242Af, and the conductive film 242Bf may be each processed to have an island shape, so that the insulator 224, the oxide 230a, the oxide 230b, the conductive layer 242A, and the conductive layer 242B may be formed. Then, an opening may be provided in the conductive layer 242A and the conductive layer 242B.

Here, the insulator 224, the oxide 230a, the oxide 230b, the conductive layer 242A, and the conductor layer 242B are formed to at least partly overlap with the conductor 205. The opening provided in the conductive layer 242A and the conductive layer 242B is positioned not to overlap with the oxide 230b. A dry etching method or a wet etching method can be used for the processing. Processing by a dry etching method is suitable for microfabrication. The insulating film 224A, the oxide film 230A, the oxide film 230B, the conductive film 242Af, and the conductive film 242Bf may be processed under different conditions.

Furthermore, as illustrated in FIG. 18C and FIG. 18D, the side surfaces of the insulator 224, the oxide 230a, the oxide 230b, the conductive layer 242A, and the conductive layer 242B may have tapered shapes. Each of the insulator 224, the oxide 230a, the oxide 230b, the conductive layer 242A, and the conductive layer 242B may have a taper angle greater than or equal to 600 and less than 90°. With such tapered shapes of the side surfaces, the coverage with the insulator 275 and the like can be improved in a later step, so that defects such as a void can be reduced.

Not being limited to the above, the insulator 224, the oxide 230a, the oxide 230b, the conductive layer 242A, and the conductive layer 242B may be processed to have side surfaces that are substantially perpendicular to the top surface of the insulator 222. With such a structure, a plurality of the transistors 200 can be provided with high density in a small area.

A by-product generated in the above etching step is sometimes formed in a layered manner on the side surfaces of the insulator 224, the oxide 230a, the oxide 230b, the conductive layer 242A, and the conductive layer 242B. In this case, the layered by-product is formed between the insulator 275 and the insulator 224, the oxide 230a, the oxide 230b, the conductive layer 242A, and the conductive layer 242B. Hence, the layered by-product formed in contact with the top surface of the insulator 222 is preferably removed.

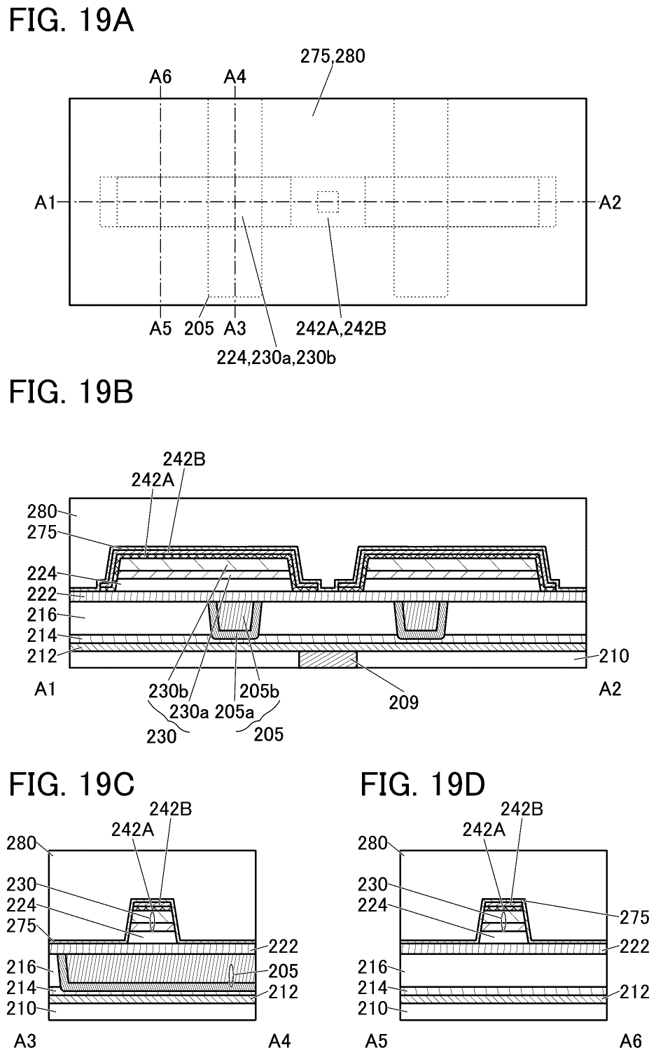

Next, the insulator 275 is deposited to cover the insulator 224, the oxide 230a, the oxide 230b, the conductive layer 242A, and the conductive layer 242B (see FIG. 19A to FIG. 19D). Here, it is preferable that the insulator 275 be in contact with the top surface of the insulator 222 and the side surface of the insulator 224. The insulator 275 can be formed by a sputtering method, a CVD method, an MBE method, a PLD method, an ALD method, or the like. As the insulator 275, an insulating film having a function of inhibiting passage of oxygen is preferably used. For example, a film of silicon nitride is formed as the insulator 275 by an ALD method. Alternatively, as the insulator 275, a film of aluminum oxide is deposited by a sputtering method, and a film of silicon nitride is formed thereover by a PEALD method. When the insulator 275 has such a stacked-layer structure, the function of inhibiting diffusion of oxygen and impurities such as water and hydrogen is improved in some cases.

In this manner, the oxide 230a, the oxide 230b, the conductive layer 242A, and the conductive layer 242B can be covered with the insulator 275 having a function of inhibiting diffusion of oxygen. This structure can reduce direct diffusion of oxygen from the insulator 280 or the like into the insulator 224, the oxide 230a, the oxide 230b, the conductive layer 242A, and the conductive layer 242B in a later step.

Next, an insulating film to be the insulator 280 is formed over the insulator 275. The insulating film can be formed by a sputtering method, a CVD method, an MBE method, a PLD method, an ALD method, or the like. For example, a silicon oxide film may be deposited by a sputtering method as the insulating film. When the insulating film is deposited by a sputtering method in an oxygen-containing atmosphere, the insulator 280 including excess oxygen can be formed. By using a sputtering method that does not need to use a molecule containing hydrogen as a film formation gas, the hydrogen concentration in the insulator 280 can be reduced. Note that heat treatment may be performed before the insulating film is deposited. The heat treatment may be performed under reduced pressure, and the insulating film may be successively formed without exposure to the air. The treatment can remove moisture and hydrogen adsorbed onto the surface of the insulator 275 and the like, and further can reduce the moisture concentration and the hydrogen concentration in the oxide 230a, the oxide 230b, and the insulator 224. For the heat treatment, the above heat treatment conditions can be used.

Next, the insulating film to be the insulator 280 is subjected to CMP treatment, so that the insulator 280 with a flat top surface is formed (see FIG. 19A to FIG. 19D). Note that, for example, silicon nitride may be deposited over the insulator 280 by a sputtering method and CMP treatment may be performed on the silicon nitride until the insulator 280 is reached.

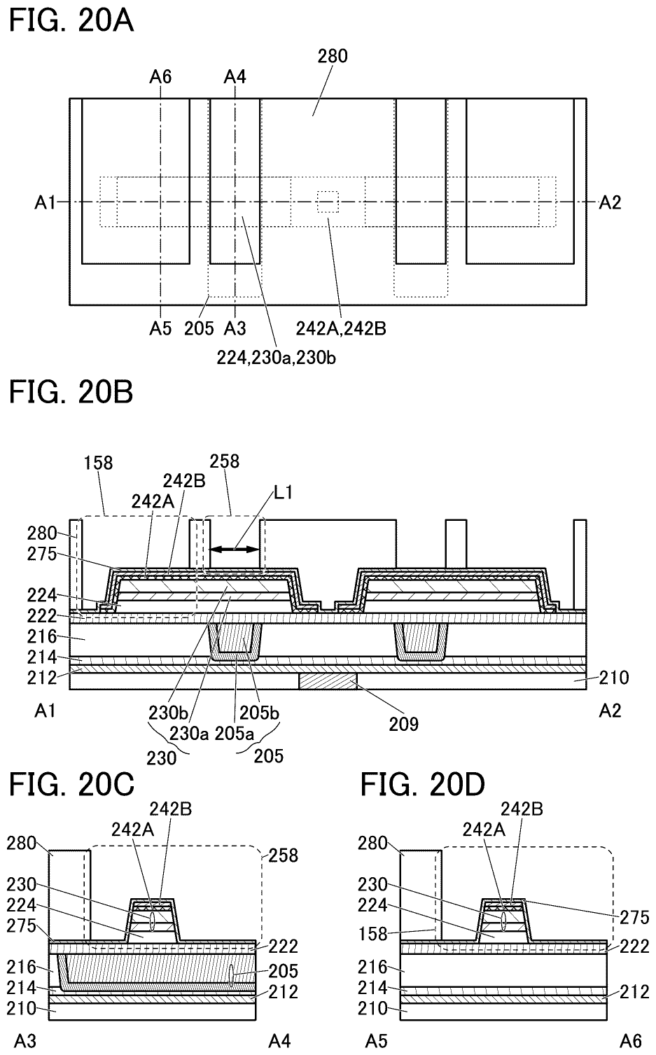

Next, part of the insulator 280 is processed to form the opening 258 and the opening 158 reaching the insulator 275 (see FIG. 20A to FIG. 20D). As illustrated in FIG. 20B to FIG. 20D, the top surface of the insulator 275 is exposed in each of the opening 258 and the opening 158.

Here, as illustrated in FIG. 20B, the width of the opening 258 in the cross-sectional view of the transistor in the channel length direction is referred to as a distance L1.

The opening 258 and the opening 158 are preferably formed to extend in a direction parallel to the dashed-dotted line A3-A4 (the channel width direction of the transistor or the Y direction illustrated in FIG. 9A) as illustrated in FIG. 20A. When the opening 258 and the opening 158 are formed in this manner, the conductor 260 and the conductor 160 that are formed later can be provided to extend in the above direction and function as wirings. The opening 258 is preferably formed to overlap with the conductor 205.

As illustrated in FIG. 20B to FIG. 20D, it is preferable that the side surface of the insulator 280 that forms the inner walls of the opening 258 and the opening 158 be substantially perpendicular and not have a tapered shape.

A dry etching method or a wet etching method can be used for the processing of part of the insulator 280. Processing by a dry etching method is suitable for microfabrication.

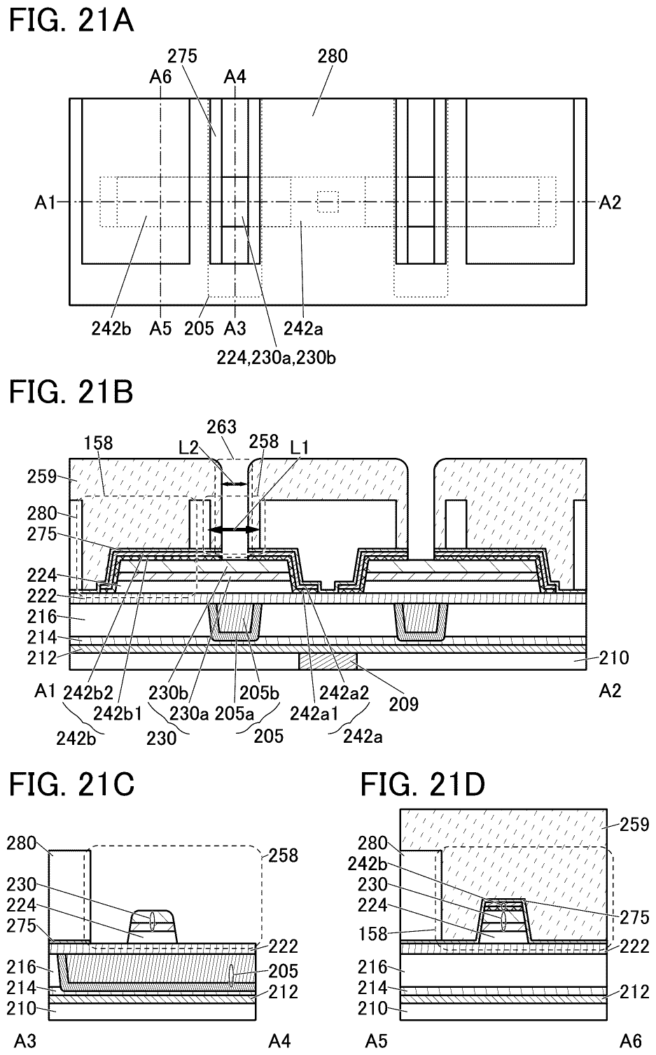

Next, a mask layer 259 is formed to cover the insulator 280 and the opening 158 (see FIG. 21A to FIG. 21D). The mask layer 259 has an opening 263 overlapping with part of the opening 258. The mask layer 259 has the opening 263 having a region overlapping with the opening 258. A resist may be used for the mask layer 259, for example. In that case, to improve the adhesion of the resist, an organic coating film such as an SOG (Spin On Glass) film or an SOC (Spin On Carbon) film is preferably provided under the resist. A hard mask formed of an insulator or a conductor may be used below the resist mask.

Here, as illustrated in FIG. 21B, the width of the opening 263 in the cross-sectional view of the transistor in the channel length direction is referred to as a distance L2. As illustrated in FIG. 21B, in the cross-sectional view of the transistor in the channel length direction, the distance L2 is shorter than the distance L1, and the opening 263 is formed inside the opening 258. Thus, part of the bottom surface of the mask layer 259 is in contact with the top surface of the conductive layer 242B inside the opening 258.

Since the width of the opening 263 affects the distance between the conductor 242a and the conductor 242b, the distance L2 is preferably small. For example, the distance L2 is preferably less than or equal to 60 nm, less than or equal to 50 nm, less than or equal to 40 nm, less than or equal to 30 nm, less than or equal to 20 nm, or less than or equal to 10 nm, and greater than or equal to 1 nm or greater than or equal to 5 nm.

In order to process the opening 263 such finely, an electron beam or short-wavelength light such as EUV light is preferably used for the lithography method.

As described above, the mask layer 259 having the opening 263 with a width of the distance L2 is provided inside the opening 258 with a width of the distance L1, whereby the opening 263 can be provided with a margin. Thus, a transistor with a short channel length can be formed relatively easily.

In the case where the opening 258 illustrated in FIG. 11B and FIG. 11C is formed, in the steps described with reference to FIG. 20A to FIG. 20D, the opening 258 is formed so that the width of the opening 258 in the cross-sectional view in the channel length direction of the transistor is equal to or smaller than the distance L2. After that, the steps described with reference to FIG. 21A to FIG. 21D are performed, whereby the opening 258 illustrated in FIG. 11B and FIG. 11C can be formed.

Next, portions of the insulator 275, the conductive layer 242B, and the conductive layer 242A that are exposed from the mask layer 259 are removed using the mask layer 259, so that the oxide 230b is exposed. Thus, the conductor 242a1 and the conductor 242b1 can be formed from the conductive layer 242A, and the conductor 242a2 and the conductor 242b2 can be formed from the conductive layer 242B (see FIG. 21A to FIG. 21D).

Part of the insulator 275, part of the conductive layer 242B, and part of the conductive layer 242A are preferably processed by anisotropic etching. Processing by a dry etching method is particularly preferable because it is suitable for microfabrication. The processing may be performed under different conditions.

By processing the insulator 275, the conductive layer 242B, and the conductive layer 242A with the anisotropic etching, the conductor 242a and the conductor 242b can be formed so that their side surfaces are substantially perpendicular to the top surface of the oxide 230b. Such a structure can inhibit formation of what is called an Loff region between the region 230ba and the region 230bc and between the region 230bb and the region 230bc. Accordingly, the frequency characteristics of the transistor 200 can be improved, and the operation speed of the semiconductor device of one embodiment of the present invention can be improved.

After the formation of the conductor 242a and the conductor 242b, the mask layer 259 may be removed. In the case where a resist mask is used as the mask layer 259, the mask layer 259 can be removed by dry etching treatment such as ahing, wet etching treatment, wet etching treatment after dry etching treatment, or dry etching treatment after wet etching treatment.

By the above etching treatment, impurities are attached onto the side surface of the oxide 230a, the top surface and the side surface of the oxide 230b, the side surface of the conductor 242, the side surface of the insulator 280, and the like or the impurities might be diffused thereinto in some cases. A step of removing the impurities may be performed. In addition, a damaged region might be formed on the surface of the oxide 230b by the above dry etching. Such a damaged region may be removed. The impurities result from components contained in the insulator 280, the insulator 275, the conductive layer 242B, and the conductive layer 242A; components contained in a member of an apparatus used to form the opening; and components contained in a gas or a liquid used for etching, for instance. Examples of the impurities include hafnium, aluminum, silicon, tantalum, fluorine, and chlorine.

In particular, impurities such as aluminum and silicon might reduce the crystallinity of the oxide 230b. Thus, it is preferable that impurities such as aluminum and silicon be removed from the surface of the oxide 230b and the vicinity thereof. The concentration of the impurities is preferably reduced. For example, the concentration of aluminum atoms of the oxide 230b and the vicinity thereof is lower than or equal to 5.0 atomic %, preferably lower than or equal to 2.0 atomic %, further preferably lower than or equal to 1.5 atomic %, still further preferably lower than or equal to 1.0 atomic %, and yet further preferably lower than 0.3 atomic %.

Note that since the density of a low-crystallinity region of the oxide 230b is reduced owing to impurities such as aluminum and silicon, a large amount of VoH is formed; thus, the transistor is likely to be normally on. Hence, the low-crystallinity region of the oxide 230b is preferably reduced or removed.

In contrast, the oxide 230b preferably has a layered CAAC structure. In particular, the CAAC structure preferably reaches a lower end portion of a drain in the oxide 230b. Here, in the transistor 200, the conductor 242a or the conductor 242b, and its vicinity function as a drain. In other words, the oxide 230b in the vicinity of the lower edge portion of the conductor 242a (conductor 242b) preferably has a CAAC structure. In this manner, the low-crystallinity region of the oxide 230b is removed and the CAAC structure is formed also in the edge portion of the drain, which significantly affects the drain breakdown voltage, so that a variation in electrical characteristics of the transistor 200 can be further suppressed. In addition, the reliability of the transistor 200 can be improved.

In order to remove impurities and the like attached to the surface of the oxide 230b in the above etching step, cleaning treatment is performed. Examples of the cleaning method include wet cleaning using a cleaning solution or the like (which can also be referred to as wet etching treatment), plasma treatment using plasma, and cleaning by heat treatment, and any of these cleanings may be performed in appropriate combination. Note that the cleaning treatment sometimes makes the groove portion deeper.

The wet cleaning may be performed using an aqueous solution in which ammonia water, oxalic acid, phosphoric acid, hydrofluoric acid, or the like is diluted with carbonated water or pure water; pure water; carbonated water; or the like. Alternatively, ultrasonic cleaning using such an aqueous solution, pure water, or carbonated water may be performed. Alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution are adjusted as appropriate in accordance with an impurity to be removed, the structure of a semiconductor device to be cleaned, or the like. The concentration of ammonia in the diluted ammonia water is higher than or equal to 0.01% and lower than or equal to 5%, preferably higher than or equal to 0.1% and lower than or equal to 0.5%. The concentration of hydrogen fluoride in the diluted hydrofluoric acid is higher than or equal to 0.01 ppm and lower than or equal to 100 ppm, preferably higher than or equal to 0.1 ppm and lower than or equal to 10 ppm.

For the ultrasonic cleaning, a frequency higher than or equal to 200 kHz is preferable, and a frequency higher than or equal to 900 kHz is further preferable. Damage to the oxide 230b and the like can be reduced when such a frequency is used.

The cleaning treatment may be performed a plurality of times, and the cleaning solution may be changed in every cleaning treatment. For example, the first cleaning treatment may use diluted hydrofluoric acid or diluted ammonia water and the second cleaning treatment may use pure water or carbonated water.

As the cleaning treatment in this embodiment, wet cleaning using diluted ammonia water is performed. The cleaning treatment can remove impurities that are attached onto the surfaces of the oxide 230a, the oxide 230b, and the like or diffuse into the oxide 230a, the oxide 230b, and the like. Furthermore, the crystallinity of the oxide 230b can be increased.

After the etching or the cleaning treatment, heat treatment may be performed. The heat treatment is performed at higher than or equal to 100° C. and lower than or equal to 450° C., preferably higher than or equal to 350° C. and lower than or equal to 400° C. Note that the heat treatment is performed in a nitrogen gas or inert gas atmosphere, or an atmosphere containing an oxidizing gas at higher than or equal to 10 ppm, higher than or equal to 1%, or higher than or equal to 10%. For example, the heat treatment is preferably performed in an oxygen atmosphere. Accordingly, oxygen can be supplied to the oxide 230a and the oxide 230b to reduce oxygen vacancies. In addition, the crystallinity of the oxide 230b can be improved by such heat treatment. The heat treatment may be performed under a reduced pressure. Alternatively, heat treatment may be performed in an oxygen atmosphere, and then heat treatment may be successively performed in a nitrogen atmosphere without exposure to the air.

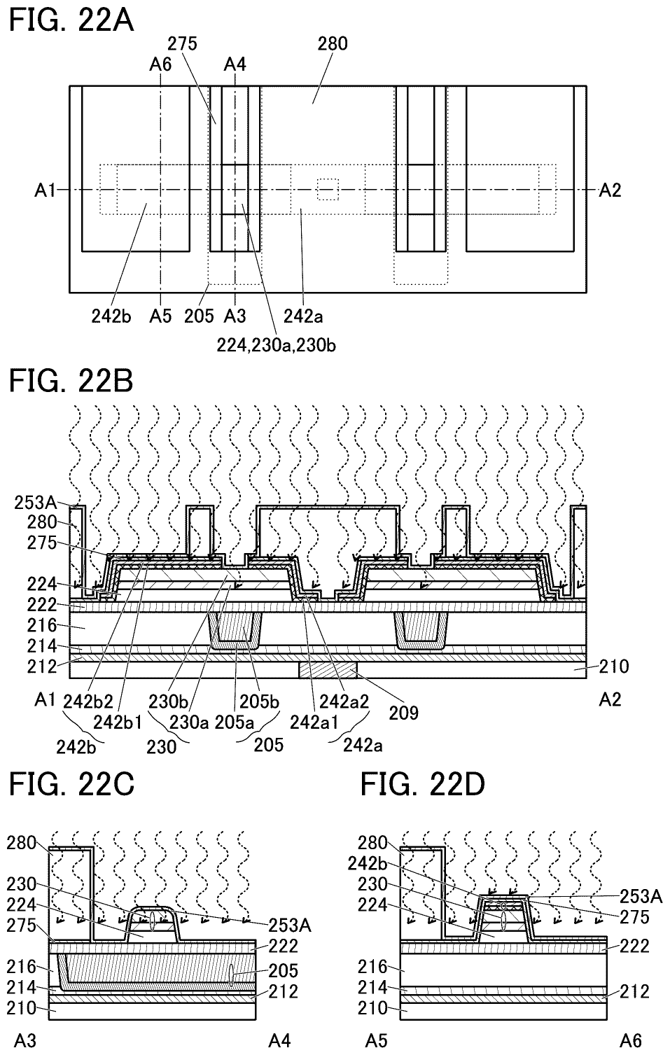

Next, an insulating film 253A is formed (see FIG. 22A to FIG. 22D). The insulating film 253A is an insulating film to be the insulator 253 and the insulator 153 in a later step. The insulating film 253A can be formed by a sputtering method, a CVD method, an MBE method, a PLD method, an ALD method, or the like. The insulating film 253A is preferably formed by an ALD method. As described above, it is preferable to deposit the insulating film 253A to have a small thickness, and an unevenness of the thickness needs to be reduced. Since an ALD method is a film formation method in which a precursor and a reactant (e.g., oxidizer) are alternately introduced and the film thickness can be adjusted with the number of repetition times of the cycle, accurate control of the film thickness is possible. As illustrated in FIG. 22B to FIG. 22D, the insulating film 253A needs to be deposited on the bottom surface and the side surface of the opening 258 and the side surface of the opening 158 with good coverage. In particular, it is preferable that the insulating film 253A be formed on the top surface and the side surface of the oxide 230 and the side surface of the conductor 242 in the opening 258, with good coverage. In the opening 158, the insulating film 253A is preferably deposited on the top surface of the insulator 275 with good coverage. An atomic layer can be deposited one by one on the bottom surface and the side surface of the opening, whereby the insulating film 253A can be formed in the opening with good coverage.

When the insulating film 253A is deposited by an ALD method, ozone (O₃), oxygen (O₂), water (H₂O), or the like can be used as the oxidizer. When an oxidizer without hydrogen, such as ozone (O₃) or oxygen (O₂), is used, the amount of hydrogen diffusing into the oxide 230b can be reduced.

In this embodiment, a film of hafnium oxide is deposited as the insulating film 253A by a thermal ALD method.

Next, microwave treatment is preferably performed in an atmosphere containing oxygen (see FIG. 22A to FIG. 22D).

Here, dotted lines in FIG. 22B to FIG. 22D indicate high-frequency waves such as microwaves or RF, oxygen plasma, oxygen radicals, or the like. The microwave treatment is preferably performed with a microwave treatment apparatus including a power source for generating high-density plasma using microwaves, for example. Here, the frequency of the microwave treatment apparatus is set to higher than or equal to 300 MHz and lower than or equal to 300 GHz, preferably higher than or equal to 2.4 GHz and lower than or equal to 2.5 GHz, for example, 2.45 GHz. Oxygen radicals at a high density can be generated with high-density plasma. The electric power of the power source that applies microwaves of the microwave treatment apparatus is set to higher than or equal to 1000 W and lower than or equal to 10000 W, preferably higher than or equal to 2000 W and lower than or equal to 5000 W. The microwave treatment apparatus may be provided with a power source that applies RF to the substrate side. Furthermore, application of RF to the substrate side allows oxygen ions generated by the high-density plasma to be introduced into the oxide 230b efficiently.

The microwave treatment is preferably performed under reduced pressure, and the pressure is set to higher than or equal to 10 Pa and lower than or equal to 1000 Pa, preferably higher than or equal to 300 Pa and lower than or equal to 700 Pa. The treatment temperature is set to lower than or equal to 750° C., preferably lower than or equal to 500° C., and is approximately 250° C., for example. The oxygen plasma treatment can be followed successively by heat treatment without exposure to the air. For example, the temperature is set to higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) is higher than 0% and lower than or equal to 100%, preferably higher than 0% and lower than or equal to 50%, further preferably higher than or equal to 10% and lower than or equal to 40%, or still further preferably higher than or equal to 10% and lower than or equal to 30%. The carrier concentration in the region 230bc can be reduced by thus performing the microwave treatment in an atmosphere containing oxygen. In addition, the carrier concentrations in the region 230ba and the region 230bb can be prevented from being excessively reduced by preventing an excess amount of oxygen from being introduced into the chamber in the microwave treatment.

As illustrated in FIG. 22B to FIG. 22D, the microwave treatment in an atmosphere containing oxygen can convert an oxygen gas into plasma using a high-frequency wave such as a microwave or RF, and apply the oxygen plasma to a region of the oxide 230b that is between the conductor 242a and the conductor 242b. At this time, the region 230bc can also be irradiated with the high-frequency wave such as a microwave or RF. In other words, the high-frequency wave such as a microwave or RF, the oxygen plasma, or the like can be applied to the region 230bc illustrated in FIG. 11A. The effect of the plasma, the microwave, or the like enables VoH in the region 230bc to be cut, and hydrogen to be removed from the region 230bc. That is, VoH contained in the region 230bc can be reduced. As a result, oxygen vacancies and VoH in the region 230bc can be reduced to lower the carrier concentration. In addition, oxygen radicals generated by the oxygen plasma, for example, can be supplied to oxygen vacancies formed in the region 230bc, thereby further reducing oxygen vacancies and lowering the carrier concentration in the region 230bc.

Meanwhile, the conductor 242a and the conductor 242b are provided over the region 230ba and the region 230bb illustrated in FIG. 11(A). Here, the conductor 242 preferably functions as a blocking film preventing the effect caused by the high-frequency wave such as a microwave or RF, the oxygen plasma, or the like in the microwave treatment in an atmosphere containing oxygen. Therefore, the conductor 242 preferably has a function of blocking an electromagnetic wave higher than or equal to 300 MHz and lower than or equal to 300 GHz, for example, higher than or equal to 2.4 GHz and lower than or equal to 2.5 GHz.

As illustrated in FIG. 22B to FIG. 22D, the effect of the high-frequency oxygen plasma such as a microwave or RF, or the like is blocked by the conductor 242a and the conductor 242b, and thus does not reach the region 230ba nor the region 230bb. Hence, a reduction in VoH and supply of an excess amount of oxygen due to the microwave treatment do not occur in the region 230ba or the region 230bb, preventing a decrease in carrier concentration.

Furthermore, the insulator 253 having a barrier property against oxygen is provided in contact with the side surfaces of the conductor 242a and the conductor 242b. Thus, formation of oxide films on the side surfaces of the conductor 242a and the conductor 242b by the microwave treatment can be inhibited.

Furthermore, the film quality of the insulator 253 can be improved, leading to higher reliability of the transistor 200.

In the above manner, oxygen vacancies and VoH can be selectively removed from the region 230bc in the oxide semiconductor, whereby the region 230bc can be an i-type or substantially i-type region. Furthermore, supply of an excess amount of oxygen to the region 230ba and the region 230bb functioning as the source region and the drain region can be inhibited and the conductivity can be maintained. As a result, a change in the electrical characteristics of the transistor 200 can be inhibited, and thus a variation in the electrical characteristics of the transistors 200 in the substrate plane can be inhibited.

In the microwave treatment, thermal energy is directly transmitted to the oxide 230b in some cases owing to an electromagnetic interaction between the microwave and a molecule in the oxide 230b. The oxide 230b may be heated by this thermal energy. Such heat treatment is sometimes referred to as microwave annealing. When microwave treatment is performed in an atmosphere containing oxygen, an effect equivalent to that of oxygen annealing is sometimes obtained. In the case where hydrogen is included in the oxide 230b, it is probable that the thermal energy is transmitted to the hydrogen in the oxide 230b and the hydrogen activated by the energy is released from the oxide 230b.

Alternatively, microwave treatment may be performed before the formation of the insulating film 253A, without the microwave treatment performed after the formation of the insulating film 253A.

After the microwave treatment that follows the formation of the insulating film 253A, heat treatment may be performed with the reduced pressure being maintained. Such treatment enables hydrogen in the insulating film 253A, the oxide 230b, and the oxide 230a to be removed efficiently. Part of hydrogen is gettered by the conductor 242 (the conductor 242a and the conductor 242b) in some cases. Alternatively, the step of performing microwave treatment and then performing heat treatment with the reduced pressure being maintained may be repeated a plurality of cycles. The repetition of the heat treatment enables hydrogen in the insulating film 253A, the oxide 230b, and the oxide 230a to be removed more efficiently. Note that the temperature of the heat treatment is preferably higher than or equal to 300° C. and lower than or equal to 500° C. The microwave treatment, i.e., the microwave annealing may also serve as the heat treatment. The heat treatment is not necessarily performed in the case where the oxide 230b and the like are adequately heated by the microwave annealing.

Furthermore, the microwave treatment improves the film quality of the insulating film 253A, thereby inhibiting diffusion of hydrogen, water, impurities, and the like. Accordingly, hydrogen, water, impurities, and the like can be inhibited from diffusing into the oxide 230b, the oxide 230a, and the like through the insulator 253 in a later step such as formation of a conductive film to be the conductor 260 or later treatment such as heat treatment.

Next, an insulating film to be the insulator 254 and the insulator 154 is formed. The insulating film can be formed by a sputtering method, a CVD method, an MBE method, a PLD method, an ALD method, or the like. Like the insulating film 253A, the insulating film is preferably deposited by an ALD method. By an ALD method, the insulating film can be formed to have a small thickness and good coverage. In this embodiment, for the insulating film, silicon nitride is deposited by a PEALD method.

Next, a conductive film to be the conductor 260a and the conductor 160a and a conductive film to be the conductor 260b and the conductor 160b are formed in this order. The conductive film to be the conductor 260a and the conductor 160a and the conductive film to be the conductor 260b and the conductor 160b can be formed by a sputtering method, a CVD method, an MBE method, a PLD method, an ALD method, or the like. In this embodiment, titanium nitride is deposited for the conductive film to be the conductor 260a and the conductor 160a by an ALD method, and tungsten is deposited for the conductive film to be the conductor 260b and the conductor 160b by a CVD method.

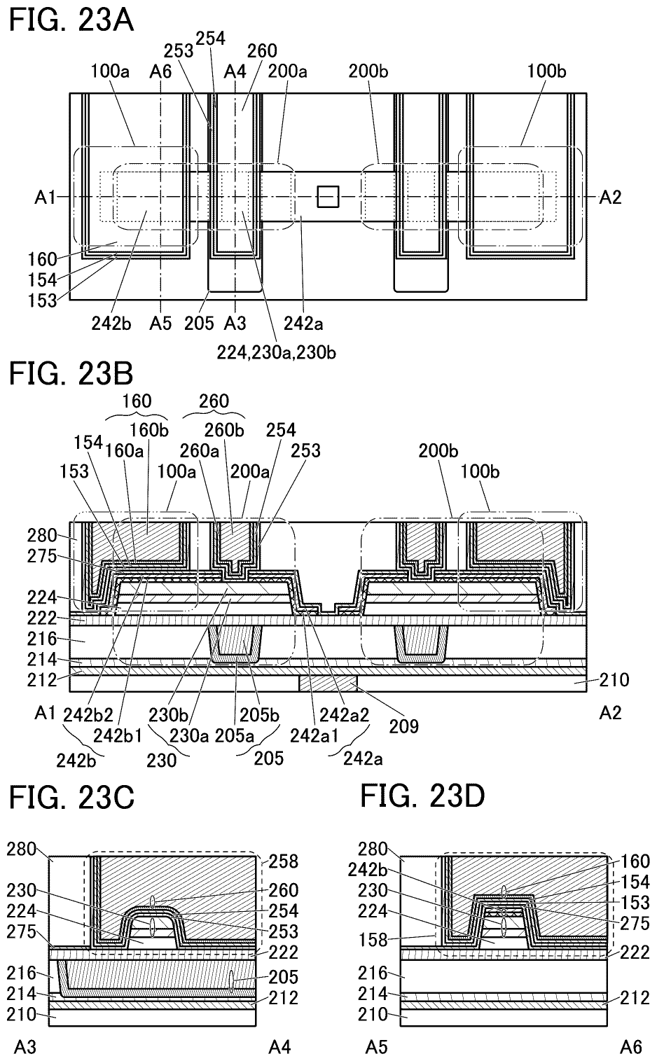

Then, the insulating film to be the insulating film 253A, the insulator 254, and the insulator 154, the conductive film to be the conductor 260a and the conductor 160a, and the conductive film to be the conductor 260b and the conductor 160b are polished by CMP treatment until the insulator 280 is exposed. That is, in the insulating film to be the insulating film 253A, the insulator 254, and the insulator 154, the conductive film to be the conductor 260a and the conductor 160a, and the conductive film to be the conductor 260b and the conductor 160b, portions exposed from the opening 258 and the opening 158 are removed. Thus, the insulator 253, the insulator 254, and the conductor 260 (the conductor 260a and the conductor 260b) are formed in the opening 258, and the insulator 153, the insulator 154, and the conductor 160 (the conductor 160a and the conductor 160b) are formed in the opening 158 (see FIG. 23A to FIG. 23D).

Accordingly, the insulator 253 is provided in contact with the inner wall and the side surface of the opening 258 overlapping with the oxide 230b. The conductor 260 is placed to fill the opening 258 with the insulator 253 and the insulator 254 therebetween. In this manner, the transistor 200 is formed.

The insulator 153 is provided in contact with the inner wall and the side surface of the opening 158 overlapping with the conductor 242b. The conductor 160 is placed to fill the opening 158 with the insulator 153 and the insulator 154 therebetween. Through the above, the capacitor 100 is formed.

As described above, the transistor 200 and the capacitor 100 can be fabricated in parallel in the same step. As described above, the same material can be used for formation of the following combinations: the insulator 253 and the insulator 153; the insulator 254 and the insulator 154; the conductor 260a and the conductor 160a; and the conductor 260b and the conductor 160b. Thus, the number of steps in the manufacturing process of the semiconductor device including the transistor 200 and the capacitor 100 can be reduced.

Then, heat treatment may be performed under conditions similar to those for the above heat treatment. In this embodiment, treatment is performed at 400° C. for one hour in a nitrogen atmosphere. The heat treatment can reduce the moisture concentration and hydrogen concentration in the insulator 280. After the heat treatment, the insulator 282 may be deposited successively without exposure to the air.

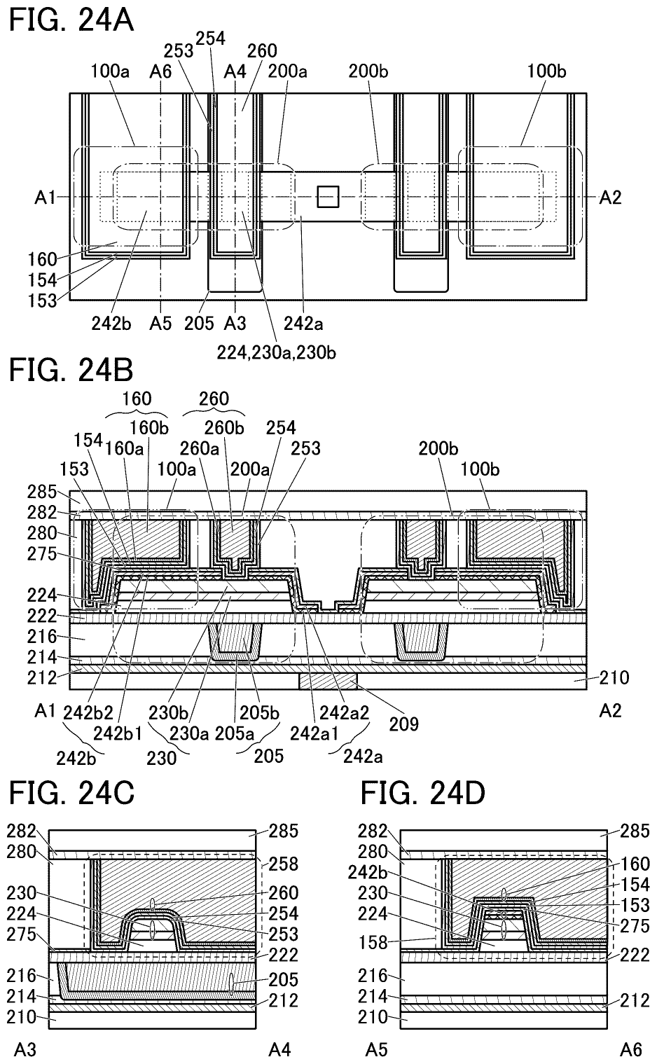

Next, the insulator 282 is formed over the insulator 253, the insulator 254, the conductor 260, the insulator 153, the insulator 154, the conductor 160, and the insulator 280 (see FIG. 24A to FIG. 24D). The insulator 282 can be formed by a sputtering method, a CVD method, an MBE method, a PLD method, an ALD method, or the like. The insulator 282 is preferably deposited by a sputtering method. By using a sputtering method that does not need to use a molecule containing hydrogen as a film formation gas, the hydrogen concentration in the insulator 282 can be reduced.

In this embodiment, as the insulator 282, a film of aluminum oxide is formed by a pulsed DC sputtering method using an aluminum target in an atmosphere containing an oxygen gas. The use of a pulsed DC sputtering method can achieve more uniform film thickness and improve the sputtering rate and film quality. The RF power applied to the substrate is lower than or equal to 1.86 W/cm². The RF power is preferably higher than or equal to 0 W/cm² and lower than or equal to 0.62 W/cm². With low RF power, the amount of oxygen implanted into the insulator 280 can be reduced. Alternatively, the insulator 282 may be formed to have a stacked-layer structure of two layers. In that case, the lower layer of the insulator 282 is formed with an RF power of 0 W/cm² applied to the substrate, and the upper layer of the insulator 282 is formed with an RF power of 0.62 W/cm² applied to the substrate.

When the insulator 282 is formed by a sputtering method in an oxygen-containing atmosphere, oxygen can be added to the insulator 280 during the formation. Thus, excess oxygen can be included in the insulator 280. At this time, the insulator 282 is preferably formed while the substrate is being heated.

Next, the insulator 285 is formed over the insulator 282 (see FIG. 24A to FIG. 24D). The insulator 285 can be formed by a sputtering method, a CVD method, an MBE method, a PLD method, an ALD method, or the like. The insulator 285 is preferably formed by a sputtering method. By using a sputtering method that does not need to use a molecule containing hydrogen as a film formation gas, the hydrogen concentration in the insulator 285 can be reduced.

In this embodiment, as the insulator 285, a film of silicon oxide is formed by a sputtering method.

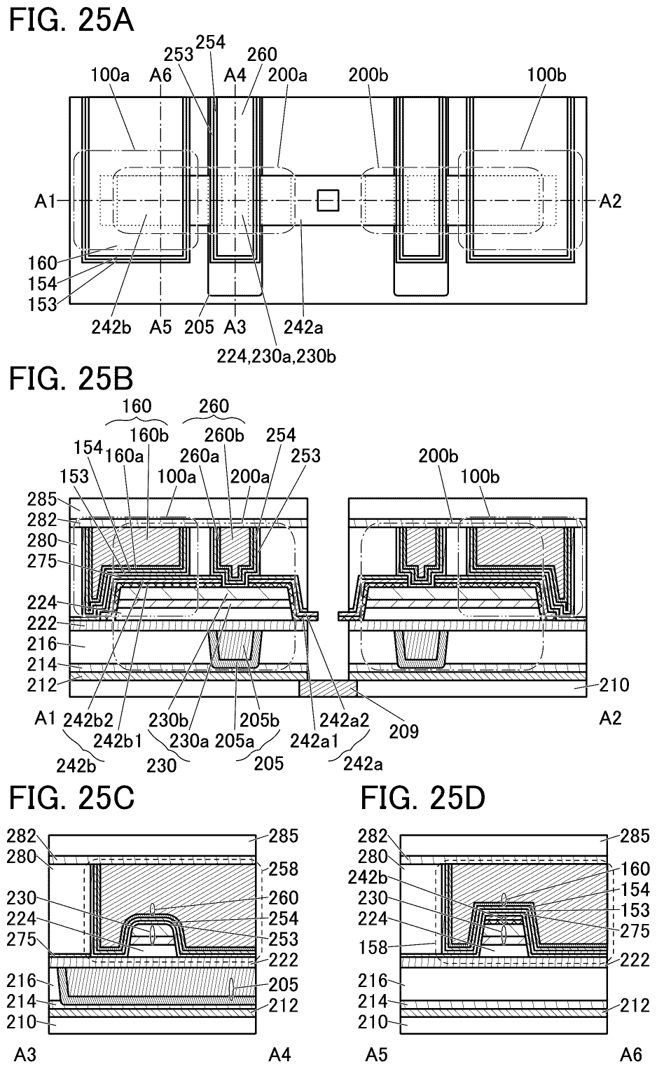

Subsequently, an opening reaching the conductor 209 is formed in the insulator 212, the insulator 214, the insulator 216, the insulator 222, the insulator 275, the insulator 280, the insulator 282, and the insulator 285 (see FIG. 25A to FIG. 25D). The opening may be formed by a lithography method. Note that the opening in the top view may have a quadrangular shape; however, it is not limited thereto. For example, the opening in the top view may have a circular shape, an almost circular shape such as an elliptical shape, a polygonal shape such as a quadrangular shape, or a polygonal shape such as a quadrangular shape with rounded corners.

Next, a conductive film to be the conductor 240a and a conductive film to be the conductor 240b are formed in this order. The conductive film to be the conductor 240a preferably has a function of inhibiting passage of impurities such as water and hydrogen. In the case where the conductive film to be the conductor 240a formed using tantalum nitride, titanium nitride, or the like. Moreover, tungsten, molybdenum, copper, or the like can be used for a conductive film to be the conductor 240b, for example. These conductive films can be deposited by a sputtering method, a CVD method, an MBE method, a PLD method, an ALD method, or the like.

Next, by performing CMP treatment, part of the conductive film to be the conductor 240a and part of the conductive film to be the conductor 240b are removed to expose the top surface of the insulator 285. As a result, the conductive film remains only in the opening, so that the conductor 240 (the conductor 240a and the conductor 240b) having flat top surfaces can be formed (see FIG. 9A to FIG. 9D). Note that the top surface of the insulator 285 is partly removed by the CMP treatment in some cases.

Through the above process, the semiconductor device including the transistor 200 illustrated in FIG. 9A to FIG. 9D can be manufactured. As illustrated in FIG. 15A to FIG. 25D, the capacitor 100 and the transistor 200 can be manufactured in the same process with the method for manufacturing the semiconductor device described in this embodiment. Thus, the number of manufacturing steps of the semiconductor device including the capacitor 100 and the transistor 200 can be reduced.

Note that the methods for forming the insulator 224, the oxide 230a, the oxide 230b, the conductive layer 242A, and the conductive layer 242B are not limited to the above. Different methods for forming the insulator 224, the oxide 230a, the oxide 230b, the conductive layer 242A, and the conductive layer 242B are described below.

The steps up to the formation of the insulating film 224Af, the oxide film 230Af, and the oxide film 230Bf are the same as those described above.

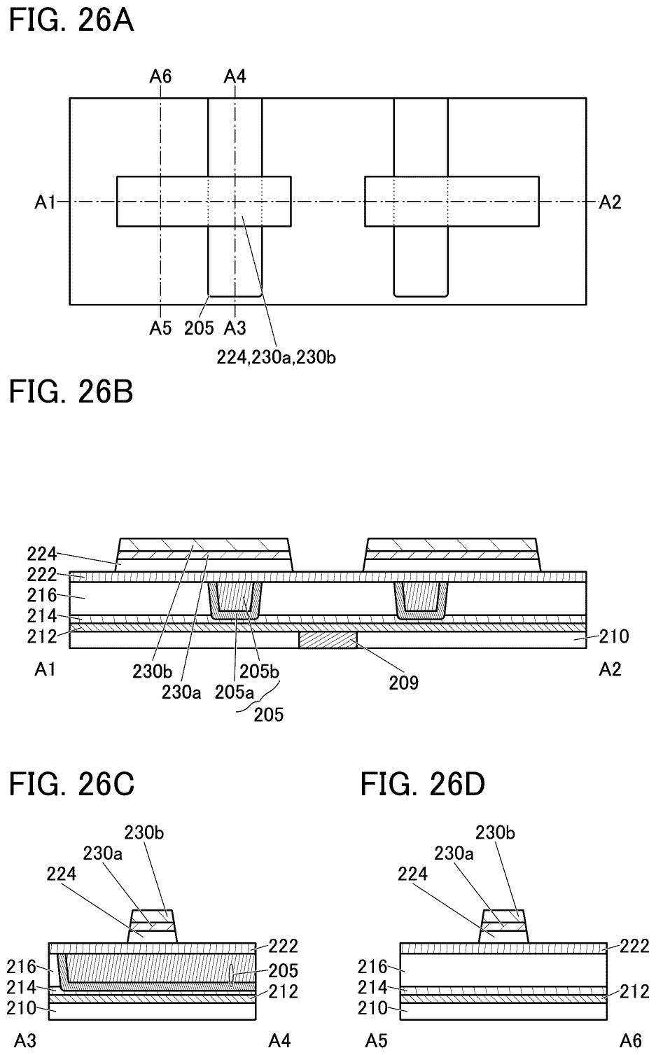

Next, the insulating film 224Af, the oxide film 230Af, and the oxide film 230Bf are processed into island shapes by a lithography method, so that the insulator 224, the oxide 230a, and the oxide layer 230B are formed (see FIG. 26A to FIG. 26D). Here, the insulator 224, the oxide 230a, and the oxide 230b are formed to at least partly overlap with the conductor 205. A dry etching method or a wet etching method can be used for the processing. Processing by a dry etching method is suitable for microfabrication. The insulating film 224Af, the oxide film 230Af, and the oxide film 230Bf may be processed under different conditions.

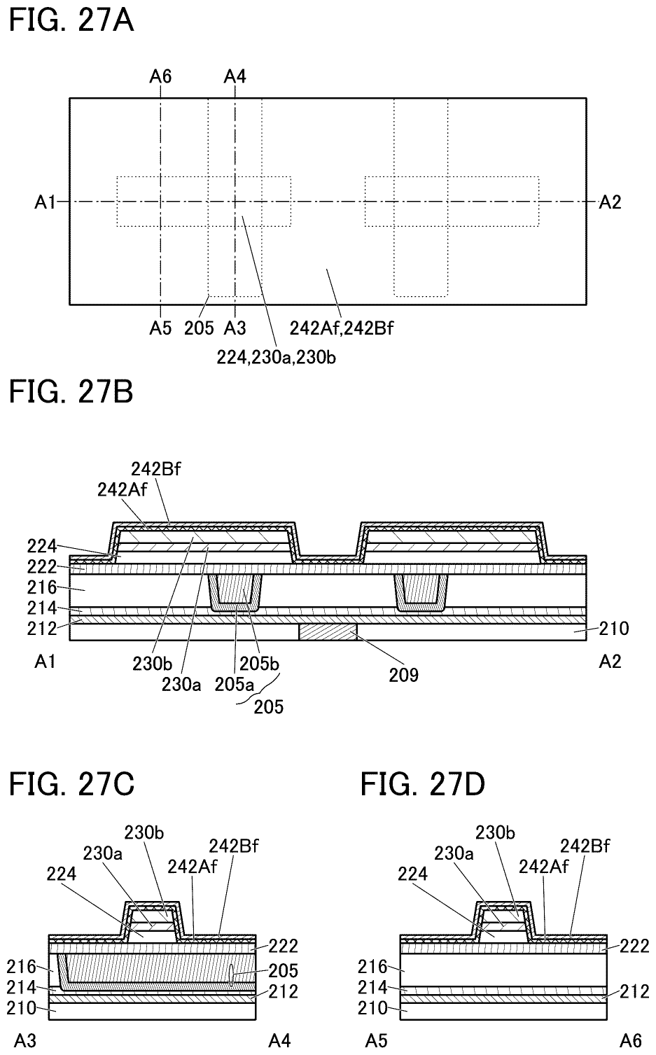

Next, the conductive film 242Af and the conductive film 242Bf are formed in this order over the insulator 222 and the oxide 230b (see FIG. 27A to FIG. 27D). For the formation methods of the conductive film 242Af and the conductive film 242Bf, the description relating to FIG. 17A to FIG. 17D can be referred to.

Next, the conductive film 242Af and the conductive film 242Bf are processed by a lithography method, so that the island-shaped conductive layer 242A and the island-shaped conductive layer 242B are formed (see FIG. 18A to FIG. 18D). Note that an opening may be formed when the conductive film 242Af and the conductive film 242Bf are processed into island shapes.

With use of the above method, processing of the insulator 224, the oxide 230a, and the oxide 230b and processing of the conductive layer 242A and the conductive layer 242B can be performed independently.

The above is the description of different methods for forming the insulator 224, the oxide 230a, the oxide 230b, the conductive layer 242A, and the conductive layer 242B.

### <Microwave Treatment Apparatus>

A microwave treatment apparatus that can be used for the above method for manufacturing the semiconductor device is described below.

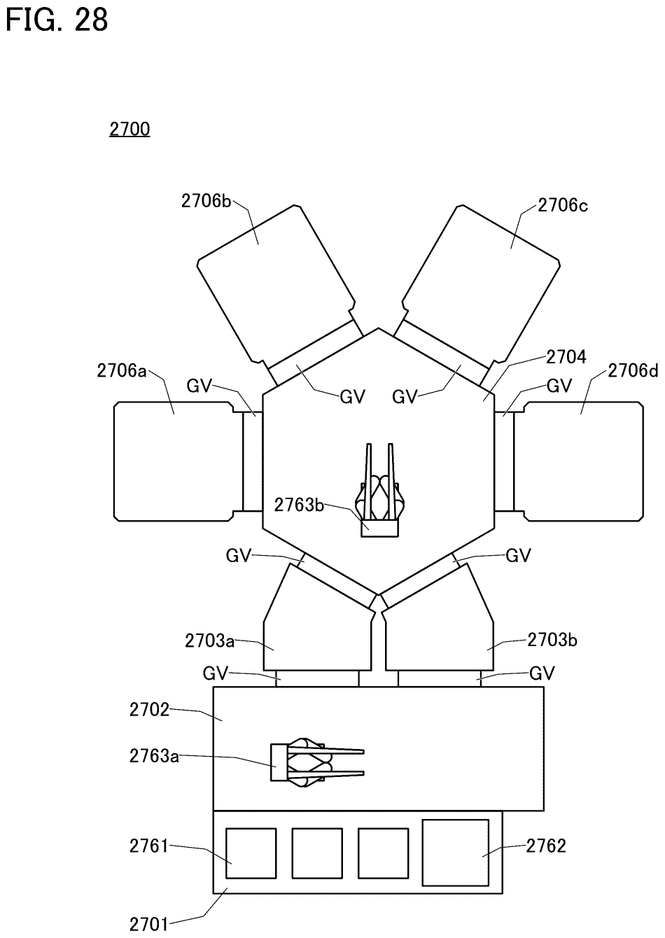

First, a structure of a manufacturing apparatus that hardly allows entry of impurities in manufacturing a semiconductor device or the like is described with reference to FIG. 28 to FIG. 31.

FIG. 28 schematically illustrates a top view of a single wafer multi-chamber manufacturing apparatus 2700. The manufacturing apparatus 2700 includes an atmosphere-side substrate supply chamber 2701 including a cassette port 2761 for storing a substrate and an alignment port 2762 for performing alignment of a substrate; an atmosphere-side substrate transfer chamber 2702 for transferring a substrate from the atmosphere-side substrate supply chamber 2701; a load lock chamber 2703a for carrying in a substrate and switching the pressure inside the chamber from atmospheric pressure to reduced pressure or from reduced pressure to atmospheric pressure; an unload lock chamber 2703b for carrying out a substrate and switching the pressure inside the chamber from reduced pressure to atmospheric pressure or from atmospheric pressure to reduced pressure; a transfer chamber 2704 for transferring a substrate in a vacuum; a chamber 2706a; a chamber 2706b; a chamber 2706c; and a chamber 2706d.

Furthermore, the atmosphere-side substrate transfer chamber 2702 is connected to the load lock chamber 2703a and the unload lock chamber 2703b, the load lock chamber 2703a and the unload lock chamber 2703b are connected to the transfer chamber 2704, and the transfer chamber 2704 is connected to the chamber 2706a, the chamber 2706b, the chamber 2706c, and the chamber 2706d.

Note that gate valves GV are provided in connecting portions between the chambers so that the chambers other than the atmosphere-side substrate supply chamber 2701 and the atmosphere-side substrate transfer chamber 2702 can be each independently kept in a vacuum state. Furthermore, the atmosphere-side substrate transfer chamber 2702 is provided with a transfer robot 2763a, and the transfer chamber 2704 is provided with a transfer robot 2763b. With the transfer robot 2763a and the transfer robot 2763b, a substrate can be transferred inside the manufacturing apparatus 2700.

The back pressure (total pressure) in the transfer chamber 2704 and each of the chambers is, for example, lower than or equal to 1×10⁻⁴ Pa, preferably lower than or equal to 3×10⁻⁵ Pa, further preferably lower than or equal to 1×10⁻⁵ Pa. Furthermore, the partial pressure of a gas molecule (atom) having a mass-to-charge ratio (m/z) of 18 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 28 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa. Furthermore, the partial pressure of a gas molecule (atom) having m/z of 44 in the transfer chamber 2704 and each of the chambers is, for example, lower than or equal to 3×10⁻⁵ Pa, preferably lower than or equal to 1×10⁻⁵ Pa, further preferably lower than or equal to 3×10⁻⁶ Pa.

Note that the total pressure and the partial pressure in the transfer chamber 2704 and each of the chambers can be measured using an ionization vacuum gauge, a mass analyzer, or the like.

Furthermore, the transfer chamber 2704 and the chambers each desirably have a structure in which the amount of external leakage or internal leakage is small. For example, the leakage rate in the transfer chamber 2704 is less than or equal to 1×10⁰ Pa/min, preferably less than or equal to 5×10⁻¹ Pa/min. Furthermore, the leakage rate in each chamber is less than or equal to 1×10⁻¹ Pa/min, preferably less than or equal to 5×10⁻² Pa/min.

Note that a leakage rate is derived from the total pressure and partial pressure measured using the ionization vacuum gauge, the mass analyzer, or the like. For example, the leakage rate is preferably derived from the total pressure at the time when 10 minutes have passed from the start of evacuation to a vacuum using a vacuum pump such as a turbo molecular pump and the total pressure at the time when 10 minutes have passed from the operation of closing the valve. Note that the total pressure at the time when 10 minutes have passed from the start of evacuation to a vacuum is preferably an average value of the total pressures measured a plurality of times.

The leakage rate depends on external leakage and internal leakage. The external leakage refers to inflow of gas from the outside of a vacuum system through a minute hole, a sealing defect, or the like. The internal leakage is due to leakage through a partition, such as a valve, in a vacuum system or released gas from an internal member. Measures need to be taken from both aspects of external leakage and internal leakage in order that the leakage rate can be set to less than or equal to the above-described value.

For example, open/close portions of the transfer chamber 2704 and each of the chambers are preferably sealed with a metal gasket. For the metal gasket, metal covered with iron fluoride, aluminum oxide, or chromium oxide is preferably used. The metal gasket achieves higher adhesion than an O-ring and can reduce the external leakage. Furthermore, with use of passive metal covered with iron fluoride, aluminum oxide, chromium oxide, or the like, the release of gas containing impurities released from the metal gasket is inhibited, so that the internal leakage can be reduced.

Furthermore, for a member of the manufacturing apparatus 2700, aluminum, chromium, titanium, zirconium, nickel, or vanadium, which releases a small amount of gas containing impurities, is used. Furthermore, an alloy containing any of iron, chromium, nickel, and the like and covered with the above-described metal, which releases a small amount of gas containing impurities, may be used. The alloy containing any of iron, chromium, nickel, and the like is rigid, resistant to heat, and suitable for processing. Here, when surface unevenness of the member is reduced by polishing or the like to reduce the surface area, the release of gas can be reduced.

Alternatively, the above-described member of the manufacturing apparatus 2700 may be covered with iron fluoride, aluminum oxide, chromium oxide, or the like.

The member of the manufacturing apparatus 2700 is preferably formed using only metal when possible, and in the case where a viewing window formed of quartz or the like is provided, for example, the surface is preferably thinly covered with iron fluoride, aluminum oxide, chromium oxide, or the like to inhibit release of gas.

An adsorbed substance present in the transfer chamber 2704 and each of the chambers does not affect the pressure in the transfer chamber 2704 and each of the chambers because it is adsorbed onto an inner wall or the like; however, it causes a release of gas when the transfer chamber 2704 and each of the chambers are evacuated. Thus, although there is no correlation between the leakage rate and the exhaust rate, it is important that the adsorbed substance present in the transfer chamber 2704 and each of the chambers be desorbed as much as possible and exhaust be performed in advance with use of a pump having high exhaust capability. Note that the transfer chamber 2704 and each of the chambers may be subjected to baking to promote desorption of the adsorbed substance. By the baking, the desorption rate of the adsorbed substance can be increased about tenfold. The baking is performed at higher than or equal to 100° C. and lower than or equal to 450° C. At this time, when the adsorbed substance is removed while an inert gas is introduced into the transfer chamber 2704 and each of the chambers, the desorption rate of water or the like, which is difficult to desorb simply by exhaust, can be further increased. Note that when the inert gas to be introduced is heated to substantially the same temperature as the baking temperature, the desorption rate of the adsorbed substance can be further increased. Here, a noble gas is preferably used as the inert gas.

Alternatively, treatment for evacuating the transfer chamber 2704 and each of the chambers is preferably performed after a certain period of time after a heated inert gas such as a noble gas, heated oxygen, or the like is introduced to increase the pressure in the transfer chamber 2704 and each of the chambers. The introduction of the heated gas can desorb the adsorbed substance in the transfer chamber 2704 and each of the chambers, and impurities present in the transfer chamber 2704 and each of the chambers can be reduced. Note that this treatment is effective when repeated more than or equal to 2 times and less than or equal to 30 times, preferably more than or equal to 5 times and less than or equal to 15 times. Specifically, an inert gas, oxygen, or the like at a temperature higher than or equal to 40° C. and lower than or equal to 400° C., preferably higher than or equal to 50° C. and lower than or equal to 200° C. is introduced, so that the pressure in the transfer chamber 2704 and each of the chambers can be kept to be higher than or equal to 0.1 Pa and lower than or equal to 10 kPa, preferably higher than or equal to 1 Pa and lower than or equal to 1 kPa, further preferably higher than or equal to 5 Pa and lower than or equal to 100 Pa within the time range of 1 minute to 300 minutes, preferably 5 minutes to 120 minutes. After that, the transfer chamber 2704 and each of the chambers are evacuated within the time range of 5 minutes to 300 minutes, preferably 10 minutes to 120 minutes.

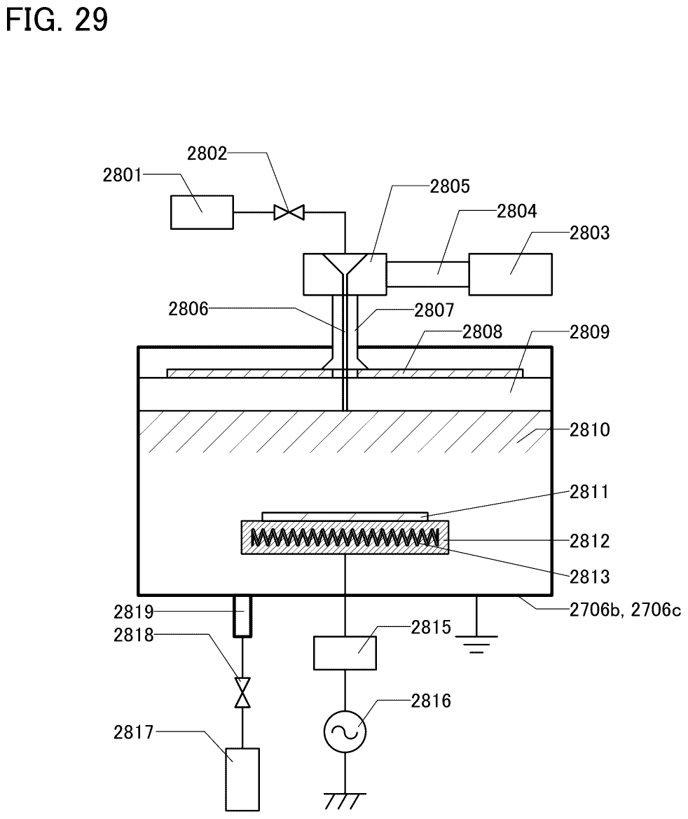

Next, the chamber 2706b and the chamber 2706c are described with reference to a schematic cross-sectional view illustrated in FIG. 29.

The chamber 2706b and the chamber 2706c are chambers in which microwave treatment can be performed on an object, for example. Note that the chamber 2706b is different from the chamber 2706c only in the atmosphere in performing the microwave treatment. The other structures are common and thus collectively described below.

The chamber 2706b and the chamber 2706c each include a slot antenna plate 2808, a dielectric plate 2809, a substrate holder 2812, and an exhaust port 2819. Furthermore, a gas supply source 2801, a valve 2802, a high-frequency generator 2803, a waveguide 2804, a mode converter 2805, a gas pipe 2806, a waveguide 2807, a matching box 2815, a high-frequency power source 2816, a vacuum pump 2817, and a valve 2818 are provided outside the chamber 2706b and the chamber 2706c, for example.

The high-frequency generator 2803 is connected to the mode converter 2805 through the waveguide 2804. The mode converter 2805 is connected to the slot antenna plate 2808 through the waveguide 2807. The slot antenna plate 2808 is placed in contact with the dielectric plate 2809. Furthermore, the gas supply source 2801 is connected to the mode converter 2805 through the valve 2802. Then, gas is transferred to the chamber 2706b and the chamber 2706c through the gas pipe 2806 that runs through the mode converter 2805, the waveguide 2807, and the dielectric plate 2809. Furthermore, the vacuum pump 2817 has a function of exhausting gas or the like from the chamber 2706b and the chamber 2706c through the valve 2818 and the exhaust port 2819. Furthermore, the high-frequency power source 2816 is connected to the substrate holder 2812 through the matching box 2815.

The substrate holder 2812 has a function of holding a substrate 2811. For example, the substrate holder 2812 has a function of an electrostatic chuck or a mechanical chuck for holding the substrate 2811. Furthermore, the substrate holder 2812 has a function of an electrode to which electric power is supplied from the high-frequency power source 2816. Furthermore, the substrate holder 2812 includes a heating mechanism 2813 therein and has a function of heating the substrate 2811.

As the vacuum pump 2817, a dry pump, a mechanical booster pump, an ion pump, a titanium sublimation pump, a cryopump, or a turbomolecular pump can be used, for example. Furthermore, in addition to the vacuum pump 2817, a cryotrap may be used. The cryopump and the cryotrap are particularly preferably used, in which case water can be efficiently exhausted.

Furthermore, for example, the heating mechanism 2813 is a heating mechanism that uses a resistance heater or the like for heating. Alternatively, a heating mechanism that uses heat conduction or heat radiation from a medium such as a heated gas for heating may be used. For example, RTA (Rapid Thermal Annealing) such as GRTA (Gas Rapid Thermal Annealing) or LRTA (Lamp Rapid Thermal Annealing) can be used. In GRTA, heat treatment is performed using a high-temperature gas. An inert gas is used as the gas.

Furthermore, the gas supply source 2801 may be connected to a purifier through a mass flow controller. As the gas, a gas whose dew point is lower than or equal to −80° C., preferably lower than or equal to −100° C. is preferably used. For example, an oxygen gas, a nitrogen gas, or a noble gas (an argon gas or the like) is used.

As the dielectric plate 2809, silicon oxide (quartz), aluminum oxide (alumina), or yttrium oxide (yttria) is used, for example. Furthermore, another protective layer may be further formed on a surface of the dielectric plate 2809. For the protective layer, magnesium oxide, titanium oxide, chromium oxide, zirconium oxide, hafnium oxide, tantalum oxide, silicon oxide, aluminum oxide, yttrium oxide, or the like is used. The dielectric plate 2809 is exposed to an especially high-density region of high-density plasma 2810 described later; thus, provision of the protective layer can reduce the damage. Consequently, an increase in the number of particles or the like during the treatment can be suppressed.

The high-frequency generator 2803 has a function of generating a microwave at, for example, higher than or equal to 0.3 GHz and lower than or equal to 3.0 GHz, higher than or equal to 0.7 GHz and lower than or equal to 1.1 GHz, or higher than or equal to 2.2 GHz and lower than or equal to 2.8 GHz. The microwave generated by the high-frequency generator 2803 is propagated to the mode converter 2805 through the waveguide 2804. The mode converter 2805 converts the microwave propagated in the TE mode into a microwave in the TEM mode. Then, the microwave is propagated to the slot antenna plate 2808 through the waveguide 2807. The slot antenna plate 2808 is provided with a plurality of slot holes, and the microwave passes through the slot holes and the dielectric plate 2809. Then, an electric field is generated below the dielectric plate 2809, and the high-density plasma 2810 can be generated. In the high-density plasma 2810, ions and radicals based on the gas species supplied from the gas supply source 2801 are present. For example, oxygen radicals are present.

At this time, the quality of a film or the like over the substrate 2811 can be modified by the ions and radicals generated in the high-density plasma 2810. Note that it is preferable in some cases to apply a bias to the substrate 2811 side using the high-frequency power source 2816. As the high-frequency power source 2816, an RF (Radio Frequency) power source with a frequency of 13.56 MHz, 27.12 MHz, or the like is used, for example. The application of a bias to the substrate side allows ions in the high-density plasma 2810 to efficiently reach a deep portion of an opening portion of the film or the like over the substrate 2811.

For example, in the chamber 2706b or the chamber 2706c, oxygen radical treatment using the high-density plasma 2810 can be performed by introducing oxygen from the gas supply source 2801.

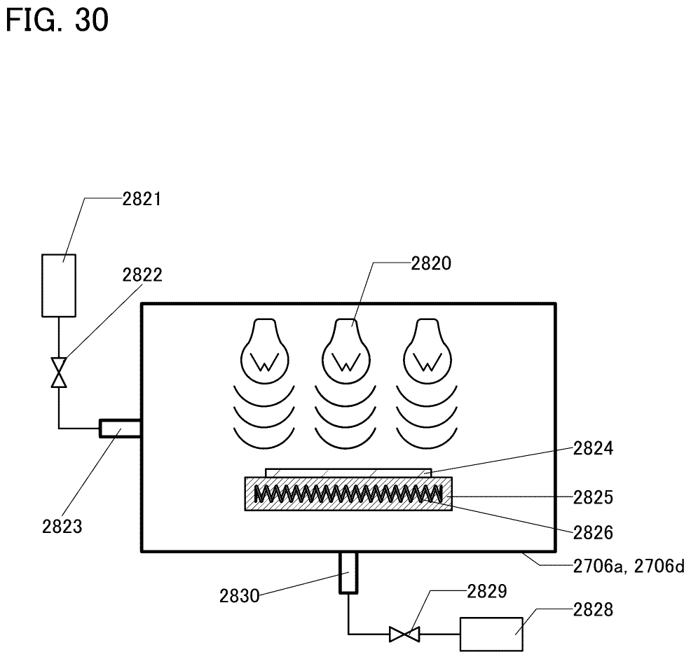

Next, the chamber 2706a and the chamber 2706d are described with reference to a schematic cross-sectional view in FIG. 30.

The chamber 2706a and the chamber 2706d are chambers in which an object can be irradiated with an electromagnetic wave, for example. Note that the chamber 2706a is different from the chamber 2706d only in the kind of the electromagnetic wave. The other structures have many common portions and thus are collectively described below.

The chamber 2706a and the chamber 2706d each include one or more lamps 2820, a substrate holder 2825, a gas inlet 2823, and an exhaust port 2830. Furthermore, a gas supply source 2821, a valve 2822, a vacuum pump 2828, and a valve 2829 are provided outside the chamber 2706a and the chamber 2706d, for example.

The gas supply source 2821 is connected to the gas inlet 2823 through the valve 2822. The vacuum pump 2828 is connected to the exhaust port 2830 through the valve 2829. The lamp 2820 is placed to face the substrate holder 2825. The substrate holder 2825 has a function of holding a substrate 2824. Furthermore, the substrate holder 2825 includes a heating mechanism 2826 therein and has a function of heating the substrate 2824.

As the lamp 2820, a light source having a function of emitting an electromagnetic wave such as visible light or ultraviolet light is used, for example. For example, a light source having a function of emitting an electromagnetic wave which has a peak at a wavelength longer than or equal to 10 nm and shorter than or equal to 2500 nm, longer than or equal to 500 nm and shorter than or equal to 2000 nm, or longer than or equal to 40 nm and shorter than or equal to 340 nm is used.

As the lamp 2820, a light source such as a halogen lamp, a metal halide lamp, a xenon arc lamp, a carbon arc lamp, a high-pressure sodium lamp, or a high-pressure mercury lamp is used, for example.

For example, part or the whole of electromagnetic wave emitted from the lamp 2820 is absorbed by the substrate 2824, so that the quality of a film or the like over the substrate 2824 can be modified. For example, generation or reduction of defects or removal of impurities can be performed. Note that generation or reduction of defects, removal of impurities, or the like can be efficiently performed while the substrate 2824 is heated.

Alternatively, for example, the electromagnetic wave emitted from the lamp 2820 may allow the substrate holder 2825 to generate heat for heating the substrate 2824. In that case, the substrate holder 2825 does not need to include the heating mechanism 2826 therein.

For the vacuum pump 2828, refer to the description of the vacuum pump 2817. Furthermore, for the heating mechanism 2826, refer to the description of the heating mechanism 2813. Furthermore, for the gas supply source 2821, refer to the description of the gas supply source 2801.

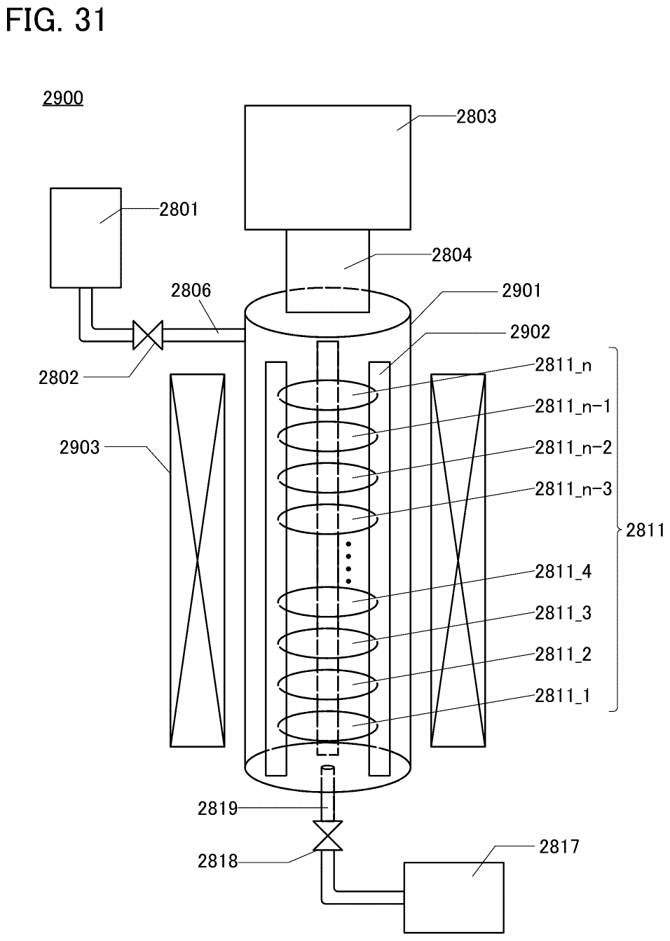

A microwave treatment apparatus that can be used in this embodiment is not limited to the above. A microwave treatment apparatus 2900 illustrated in FIG. 31 can be used. The microwave treatment apparatus 2900 includes a quartz tube 2901, the exhaust port 2819, the gas supply source 2801, the valve 2802, the high-frequency generator 2803, the waveguide 2804, the gas pipe 2806, the vacuum pump 2817, and the valve 2818. Furthermore, the microwave treatment apparatus 2900 includes a substrate holder 2902 that holds a plurality of substrates 2811 (2811_1 to 2811_n, n is an integer greater than or equal to 2) in the quartz tube 2901. The microwave treatment apparatus 2900 may further include a heating means 2903 outside the quartz tube 2901.

The substrate provided in the quartz tube 2901 is irradiated with the microwave generated by the high-frequency generator 2803, through the waveguide 2804. The vacuum pump 2817 is connected to the exhaust port 2819 through the valve 2818 and can adjust the pressure inside the quartz tube 2901. The gas supply source 2801 is connected to the gas pipe 2806 through the valve 2802 and can introduce a desired gas into the quartz tube 2901. The heating means 2903 can heat the substrate 2811 in the quartz tube 2901 to a desired temperature. Alternatively, the heating means 2903 may heat the gas which is supplied from the gas supply source 2801. With use of the microwave treatment apparatus 2900, the substrate 2811 can be subjected to heat treatment and microwave treatment at the same time. Alternatively, the substrate 2811 can be heated and then subjected to microwave treatment. Alternatively, the substrate 2811 can be subjected to microwave treatment and then heat treatment.

All of the substrate 2811_1 to the substrate 2811_n may be substrates to be treated where a semiconductor device or a storage device is to be formed, or some of the substrates may be dummy substrates. For example, the substrate 2811_1 and the substrate 2811_n may be dummy substrates, and the substrate 2811_2 to the substrate 2811_n−1 may be substrates to be treated. Alternatively, the substrate 2811_1, the substrate 2811_2, the substrate 2811_n−1, and the substrate 2811_n may be dummy substrates, and the substrate 2811_3 to the substrate 2811_n−2 may be substrates to be treated. A dummy substrate is preferably used, in which case a plurality of substrates to be treated can be uniformly treated at the time of microwave treatment or heat treatment and a variation between the substrates to be treated can be reduced. For example, a dummy substrate is preferably placed over the substrate to be treated which is the closest to the high-frequency generator 2803 and the waveguide 2804, in which case the substrate to be treated is inhibited from being directly exposed to a microwave.

With use of the above-described manufacturing apparatus, the quality of a film or the like can be modified while the entry of impurities into an object is inhibited.

### <Variation Example of Semiconductor Device>

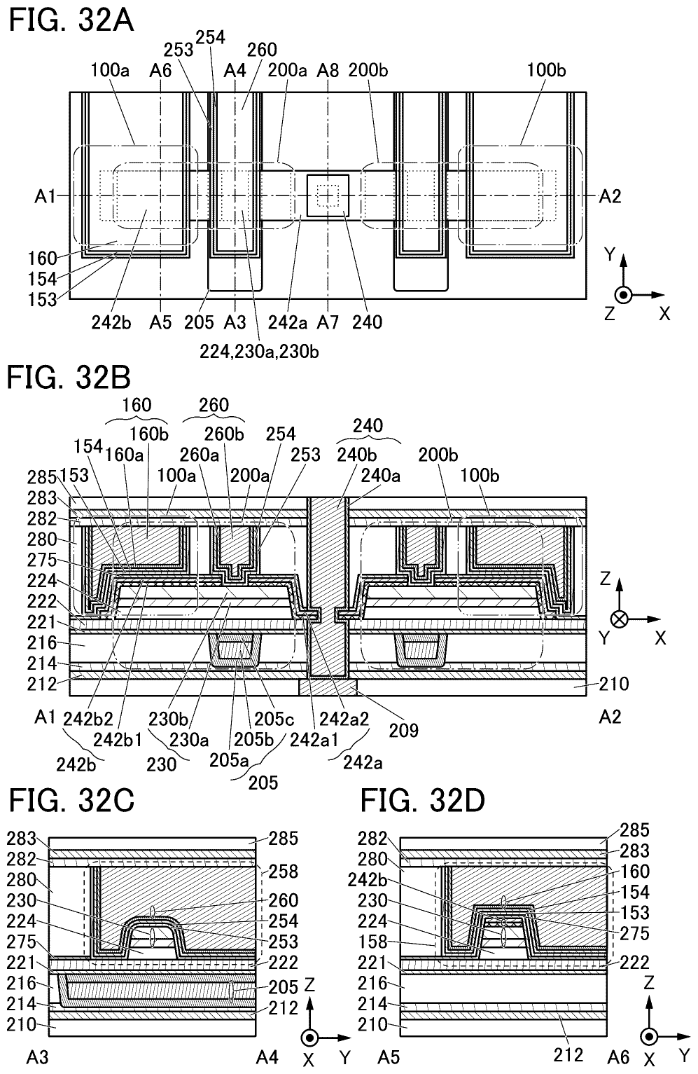

Examples of the semiconductor device of one embodiment of the present invention are described below with reference to FIG. 32A to FIG. 32D.

FIG. 32A is a top view of the semiconductor device. Moreover, FIG. 32B is a cross-sectional view corresponding to a portion indicated by dashed-dotted line A1-A2 in FIG. 32A. Furthermore, FIG. 32C is a cross-sectional view corresponding to a portion indicated by dashed-dotted line A3-A4 in FIG. 32A. Furthermore, FIG. 32D is a cross-sectional view corresponding to a portion indicated by dashed-dotted line A5-A6 in FIG. 32A. For clarity of the drawing, some components are not illustrated in the top view of FIG. 32A.

Note that in the semiconductor device illustrated in FIG. 32A to FIG. 32D, components having the same functions as the components included in the semiconductor device described in <Structure example of semiconductor device> are denoted by the same reference numerals. Note that the materials described in detail in <Structure example of semiconductor device> can be used as component materials of the semiconductor devices also in this section.

The semiconductor device shown in FIG. 32A to FIG. 32D is a variation example of the semiconductor device illustrated in FIG. 9A to FIG. 9D. The semiconductor device illustrated in FIG. 32A to FIG. 32D differs from the semiconductor device illustrated in FIG. 9A to FIG. 9D in including an insulator 283 and an insulator 221.

The insulator 283 is provided between the insulator 282 and the insulator 285. As the insulator 283, an insulator having a function of inhibiting diffusion of hydrogen is preferably used. This can inhibit diffusion of hydrogen into the transistor 200 from above the insulator 283. As the insulator 283, an insulator that can be used as the insulator 275 described above is preferably used. For example, a film of silicon nitride formed by a sputtering method is used for the insulator 283. When the insulator 283 is formed by a sputtering method, a high-density silicon nitride film can be formed. As the insulator 283, silicon nitride deposited by a PEALD method or a CVD method may be stacked over silicon nitride deposited by a sputtering method.

The insulator 282, which has a function of capturing impurities such as hydrogen, is provided in contact with the insulator 280 in a region sandwiched between the insulator 212 and the insulator 283, whereby impurities such as hydrogen contained in the insulator 280 and the like can be captured and the amount of hydrogen in the region can be constant. It is preferable to use, in particular, aluminum oxide having an amorphous structure for the insulator 282, in which case hydrogen can be captured or fixed more effectively in some cases. Accordingly, the transistor 200 and the semiconductor device which have favorable characteristics and high reliability can be manufactured.

Although FIG. 32A to FIG. 32D illustrate the transistor 200 having a structure in which the insulator 283 is provided to have a single-layer structure, the present invention is not limited thereto. The insulator 283 may have a stacked-layer structure of two or more layers, for example.

For example, in the case where the insulator 283 has a stacked-layer structure of two layers, silicon nitride may be deposited by a sputtering method as a lower layer of the insulator 283 and silicon nitride may be deposited by an ALD method as an upper layer of the insulator 283. By using a sputtering method, which does not need to use a molecule containing hydrogen as a deposition gas, the hydrogen concentration in the lower layer of the insulator 282 can be reduced. Furthermore, in the case where a pinhole, disconnection, or the like is formed in the film formed by a sputtering method, a portion overlapping with the pinhole, the disconnection, or the like can be filled with the film formed by an ALD method with excellent coverage.

Note that in the case where the insulator 283 has a stacked-layer structure of two layers, part of the top surface of the upper layer of the insulator 283 is removed in some cases. The boundary between the upper layer and the lower layer of the insulator 283 is difficult to detect clearly in some cases.

The insulator 221 is provided between the insulator 222 and each of the insulator 216 and the conductor 205. The insulator 221 preferably has a function of inhibiting diffusion of hydrogen. This can inhibit diffusion of hydrogen into the transistor 200 from below the insulator 221. Note that the insulator 221 can also function as the insulator 212. In such a case, the structure without the insulator 212 enables simplification of the manufacturing process and the improvement in productivity of the semiconductor device.

As the insulator 221, an insulator that can be used as the insulator 275 described above is preferably used. For the insulator 221, silicon nitride deposited by an ALD method (especially a PEALD method) is preferably used, for example. When formed by an ALD method, the insulator 221 can have favorable coverage even when unevenness is formed by the insulator 216 and the conductor 205. This can inhibit formation of a pinhole, disconnection, or the like in the insulator 222 formed over the insulator 221.

An insulator having a function of inhibiting diffusion of hydrogen may be provided between the insulator 222 and the insulator 224. This can inhibit diffusion of hydrogen into the transistor 200 from below the insulator.

As illustrated in FIG. 32B and FIG. 32C, the conductor 205 may have a three-layer structure of the conductor 205a, the conductor 205b, and a conductor 205c. The conductor 205c is provided in contact with the top surface of the conductor 205b. A structure may be employed in which the side surface of the conductor 205c is in contact with the conductor 205a. Alternatively, a structure may be employed in which the top surface of the conductor 205c and the uppermost portion of the conductor 205a are aligned or substantially aligned with each other. Like the conductor 205a, the conductor 205c is preferably formed using a conductive material having a function of inhibiting diffusion of hydrogen. Thus, the conductor 205b can be surrounded by the conductor 205a and the conductor 205c, so that impurities such as hydrogen contained in the conductor 205b can be prevented from diffusing into the oxide 230 through the insulator 216, the insulator 224, and the like. When the conductor 205a and the conductor 205c are formed using a conductive material having a function of inhibiting diffusion of oxygen, the conductivity of the conductor 205b can be inhibited from being lowered because of oxidation.

A change in electrical characteristics of an OS transistor such as the transistor 200 due to exposure to radiation is small, i.e., an OS transistor is highly resistant to radiation; thus, an OS transistor can be suitably used even in an environment where radiation might enter. For example, OS transistors can be suitably used in outer space. Specifically, OS transistors can be used as transistors included in semiconductor devices provided in a space shuttle, an artificial satellite, a space probe, and the like. Examples of radiation include X-rays and a neutron beam. Outer space refers to, for example, space at an altitude greater than or equal to 100 km, and outer space in this specification may also include thermosphere, mesosphere, and stratosphere.

Alternatively, for example, OS transistors can be used as transistors included in semiconductor devices provided in working robots in a nuclear power plant and a treatment plant or a disposal plant for radioactive wastes. In particular, OS transistors can be suitably used as transistors included in semiconductor devices provided in remote control robots that are controlled remotely in demolishment of a reactor facility, taking out of a nuclear fuel or a fuel debris, a field investigation on a space with a large amount of radioactive substance, and the like.

According to one embodiment of the present invention, a novel transistor can be provided. Alternatively, a semiconductor device that can be miniaturized or highly integrated can be provided. Alternatively, a semiconductor device with favorable frequency characteristics can be provided. A semiconductor device with high operating speed can be provided. Alternatively, a semiconductor device with a small variation in transistor characteristics can be provided. Alternatively, a semiconductor device having favorable electrical characteristics can be provided. Alternatively, a semiconductor device with favorable reliability can be provided. Alternatively, a semiconductor device with a high on-state current can be provided. Alternatively, a semiconductor device with a high field-effect mobility can be provided. Alternatively, a semiconductor device with low power consumption can be provided.

The semiconductor device including the transistor 200 and the capacitor 100 described in this embodiment can be used as a memory cell of the storage device. The transistor 200 is a transistor in which a channel is formed in a semiconductor layer including an oxide semiconductor (hereinafter, referred to as an OS transistor in some cases). Since the transistor 200 has a low off-state current, a storage device that uses the transistor 200 can retain stored contents for a long time. In other words, such a storage device does not require refresh operation or has extremely low frequency of the refresh operation, which leads to a sufficient reduction in power consumption of the storage device. The transistor 200 has high frequency characteristics and thus enables the storage device to perform reading and writing at high speed.

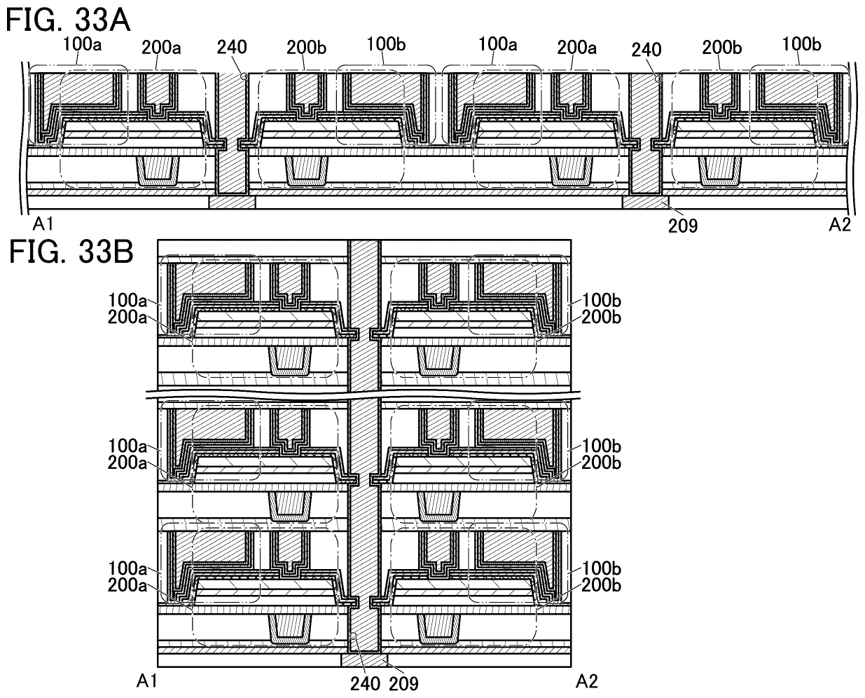

When semiconductor devices including the transistor 200 and the capacitor 100 that can be used as memory cells are arranged in a matrix, a memory cell array can be formed. As an example of the memory cell array, FIG. 33A illustrates an example in which a plurality of memory cells described above are arranged in A1-A2 direction.

Although FIG. 33A illustrates a structure in which a capacitor included in a memory cell and another capacitor included in another memory cell adjacent to the above memory cell not through the conductor 240 are provided independently of each other, the present invention is not limited thereto.

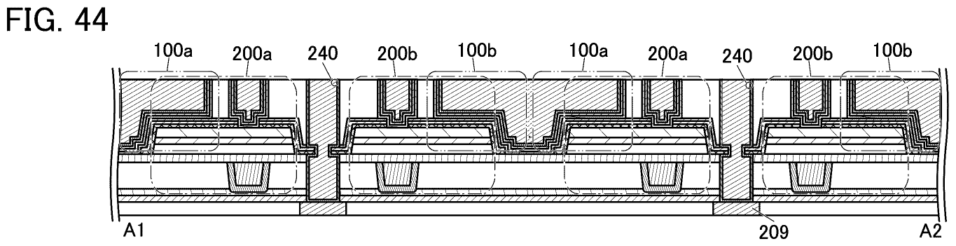

FIG. 44 illustrates a semiconductor device having a structure different from that of the semiconductor device illustrated in FIG. 33A. The semiconductor device illustrated in FIG. 44 has a structure in which an upper electrode (the other of the pair of electrodes) of a capacitor included in one memory cell also serves as an upper electrode (the other of the pair of electrodes) of another capacitor included in another memory cell adjacent to the above memory cell not through the conductor 240. With the structure, the semiconductor device can be more miniaturized and highly integrated.

Furthermore, the memory cells may be not only arranged in a plane but also have a stacked-layer structure. FIG. 33B is a cross-sectional view of a structure in which a plurality of layers including the above memory cells are stacked. In this case, it can be said that the storage device includes a plurality of layers including memory cells, the memory cells each include the transistor 200 and the capacitor 100, and the plurality of layers are stacked. Alternatively, it can be said that the storage device includes a plurality of layers each including at least two memory cells and has a structure in which the plurality of layers are stacked. Here, a memory cell including the transistor 200a and the capacitor 100a is referred to as a first memory cell, and a memory cell including the transistor 200b and the capacitor 100b is referred to as a second memory cell in some cases.

Although FIG. 33B illustrates a structure in which a plurality of layers including memory cells are stacked, one embodiment of the present invention is not limited thereto. For example, a plurality of layers including the memory cell array illustrated in FIG. 33A may be stacked. In this case, it can be said that the storage device includes a plurality of layers each including a memory cell array, the memory cell array is provided with a memory cell including the transistor 200 and the capacitor 100, and the plurality of layers are stacked.

As illustrated in FIG. 33B, each of the plurality of layers included in the storage device has an opening. Specifically, each of the plurality of layers included in the storage device has an opening between the first memory cell and the second memory cell. More specifically, each of the plurality of layers included in the storage device has an opening between the transistor 200a and the transistor 200b. The openings included in the plurality of layers each have a region where the openings overlap with each other. Since the openings in the plurality of layers each have a region where the openings overlap with each other, the openings in the plurality of layers can be formed at a time. Accordingly, the manufacturing process of the storage device can be simplified, and the productivity can be improved.

The conductor 240 is placed in the openings of the plurality of layers. In this case, the conductor 240 is electrically connected to the transistor 200a and the transistor 200b included in each of the plurality of layers. Note that in this embodiment, the conductor 242a is shared by the transistor 200a and the transistor 200b. Thus, it can be said that the conductor 240 is electrically connected to the conductor 242a included in each of the plurality of layers.

When a plurality of memory cells are stacked as illustrated in FIG. 33B, cells can be integrally arranged without increasing the area occupied by the memory cell array. In other words, a 3D memory cell array can be formed.

The storage device including the memory cell array will be described in detail in a later embodiment.

At least part of the structure, method, and the like described in this embodiment can be implemented in appropriate combination with any of the other embodiments described in this specification.

### Embodiment 3

In this embodiment, a structure example of a storage device using the semiconductor device described in the above embodiment as a memory cell will be described.

### [Structure Example of Storage Device]

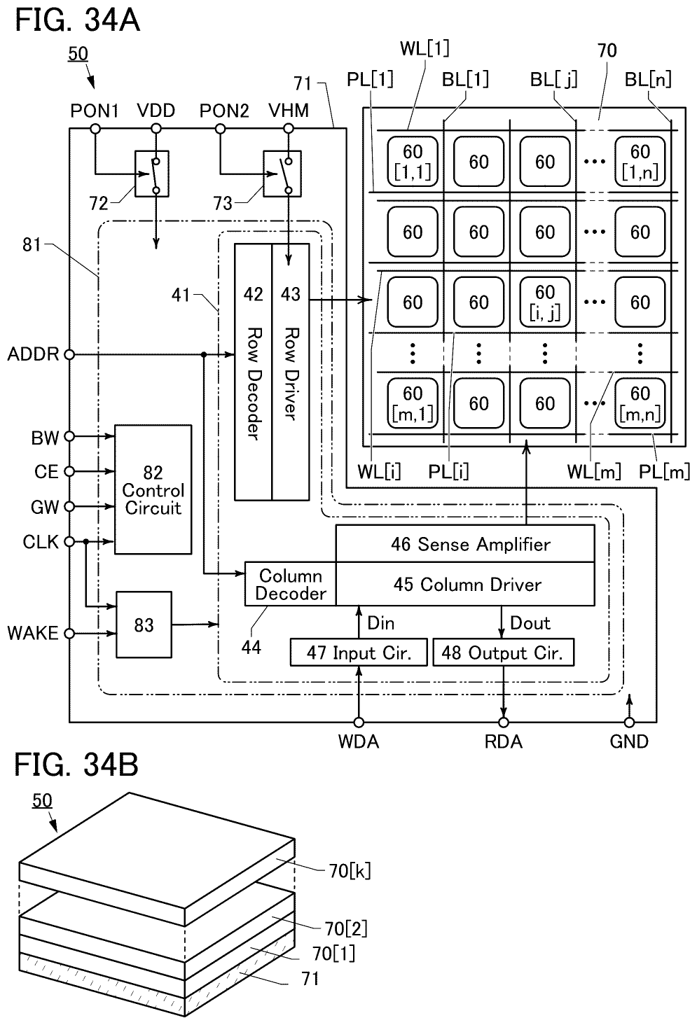

FIG. 34A is a block diagram illustrating a structure example of a storage device 50 of one embodiment of the present invention. The storage device 50 illustrated in FIG. 34A includes a driver circuit 71 and a memory array 70. The memory cell array 70 includes a plurality of memory cells 60. FIG. 34A illustrates an example in which the memory array 70 includes the plurality of memory cells 60 arranged in a matrix of m rows and n columns (each of m and n is an integer greater than or equal to 2).

Note that the rows and the columns extend in directions orthogonal to each other. In this embodiment, the X direction (direction along the X-axis) is referred to as a “row” and the Y direction (direction along the Y-axis) is referred to as a “column”, but the X direction may be referred to as a “column” and the Y direction may be referred to as a “row”.

In FIG. 34A, the memory cell 60 in the first row and the first column is referred to as a memory cell 60[1,1], and the memory cell 60 in the m-th row and the n-th column is referred to as a memory cell 60[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 60 in the i-th row and the j-th column is referred to as a memory cell 60[i,j]. Note that in this embodiment and the like, “i+a” (a is a positive or negative integer) is not below 1 and does not exceed m. Similarly, “j+a” is not below 1 and does not exceed n.

The memory array 70 includes m wirings WL extending in the row direction, m wirings PL extending in the row direction, and n wirings BL extending in the column direction. In this embodiment and the like, a first (first row) wiring WL is referred to as a wiring WL[1] and an m-th (m-th row) wiring WL is referred to as a wiring WL[m]. Similarly, a first (first row) wiring PL is referred to as a wiring PL[1] and an m-th (m-th row) wiring PL is referred to as a wiring PL[m]. Similarly, a first (first column) wiring BL is referred to as a wiring BL[1] and an n-th (n-th column) wiring BL is referred to as a wiring BL[n].

The plurality of memory cells 60 provided in the i-th row are electrically connected to the wiring WL in the i-th row (wiring WL[i]) and the wiring PL in the i-th row (wiring PL[i]). The plurality of memory cells 60 provided in the j-th column are electrically connected to the wiring BL in the j-th column (wiring BL[j]).

A DOSRAM (registered trademark) can be used for the memory cell array 70. The DOSRAM is a RAM including a 1T (transistor) 1C (capacitor) memory cell, which is a memory in which an access transistor is a transistor including an oxide semiconductor in a channel formation region (hereinafter also referred to as an “OS transistor”). A current flowing between a source and a drain in an off state, that is, a leakage current, is extremely low in an OS transistor. A DOSRAM can retain electric charges corresponding to data stored in a capacitor for a long time by turning off an access transistor (a non-conduction state). For this reason, the refresh operation frequency of a DOSRAM can be lower than that of a DRAM formed with a transistor including silicon in its channel formation region (a Si transistor). Thus, power consumption can be reduced.

The wiring BL functions as a bit line for writing and reading data. The wiring WL functions as a word line for controlling on/off (conduction and non-conduction states) of an access transistor serving as a switch. The wiring PL functions as a fixed potential line connected to the capacitor and has a function of transmitting a back gate potential to a back gate of the OS transistor that is an access transistor. Note that a wiring BGL (not illustrated) can be additionally provided as a wiring for transmitting the back gate potential.

The driver circuit 71 includes a PSW 72 (power switch), a PSW 73, and a peripheral circuit 81. The peripheral circuit 81 includes a peripheral circuit 41, a control circuit 82, and a voltage generation circuit 83.

In the storage device 50, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 82.

The control circuit 82 is a logic circuit having a function of controlling the entire operation of the storage device 50. For example, the control circuit performs a logical operation on the signal CE, the signal GW, and the signal BW to determine an operation mode (e.g., a writing operation or a reading operation) of the storage device 50. Alternatively, the control circuit 82 generates a control signal for the peripheral circuit 41 so that the operation mode is executed.

The voltage generation circuit 83 has a function of generating a negative voltage. The signal WAKE has a function of controlling the input of the signal CLK to the voltage generation circuit 83. For example, when an H-level signal is supplied as the signal WAKE, the signal CLK is input to the voltage generation circuit 83, and the voltage generation circuit 83 generates a negative voltage.

The peripheral circuit 41 is a circuit for writing and reading data to/from the memory cells 60. The peripheral circuit 41 includes a row decoder 42, a column decoder 44, a row driver 43, a column driver 45, an input circuit 47 (Input Cir.), an output circuit 48 (Output Cir.), and a sense amplifier 46.

The row decoder 42 and the column decoder 44 have a function of decoding the signal ADDR. The row decoder 42 is a circuit for specifying a row to be accessed, and the column decoder 44 is a circuit for specifying a column to be accessed. The row driver 43 has a function of selecting the wiring WL specified by the row decoder 42. The column driver 45 has a function of writing data to the memory cells 60, a function of reading data from the memory cells 60, a function of retaining the read data, and the like.

The input circuit 47 has a function of retaining the signal WDA. Data retained by the input circuit 47 is output to the column driver 45. Data output from the input circuit 47 is data (Din) to be written to the memory cells 60. Data (Dout) read from the memory cells 60 by the column driver 45 is output to the output circuit 48. The output circuit 48 has a function of retaining Dout. In addition, the output circuit 48 has a function of outputting Dout to the outside of the storage device 50. Data output from the output circuit 48 is the signal RDA.

The PSW 72 has a function of controlling supply of VDD to the peripheral circuit 81. The PSW 73 has a function of controlling supply of VHM to the row driver 43. Here, in the storage device 50, a high power supply voltage is VDD and a low power supply voltage is GND (a ground potential). In addition, VHM is a high power supply voltage used to set a word line at a high level and is higher than VDD. The on/off of the PSW 72 is controlled by the signal PON1, and the on/off of the PSW 73 is controlled by the signal PON2. The number of power domains to which VDD is supplied is one in the peripheral circuit 81 in FIG. 34A but can be more than one. In this case, a power switch is provided for each power domain.

The memory array 70 can be provided over the driver circuit 71 to overlap with the driver circuit 71. When the driver circuit 71 and the memory array 70 are provided to overlap with each other, the signal transmission distance between the driver circuit 71 and the memory array 70 can be shortened. Accordingly, resistance and parasitic capacitance between the driver circuit 71 and the memory array 70 are reduced, so that power consumption and signal delays can be reduced. In addition, the storage device 50 can be downsized.

As the memory array 70, a multilayer of memory arrays 70 overlapping with each other can be provided over the driver circuit 71. Stacking the memory arrays 70 in layers can increase the memory density of the memory cells 60. FIG. 34B illustrates an example in which k layers (k is an integer greater than or equal to 2) of the memory arrays 70 are provided over the driver circuit 71 to overlap with the driver circuit 71. In FIG. 34B and the like, the memory array 70 in the first layer is denoted as a memory array 70[1], the memory array 70 in the second layer is denoted as a memory array 70[2], and the memory array 70 in the k-th layer is denoted as a memory array 70[k].

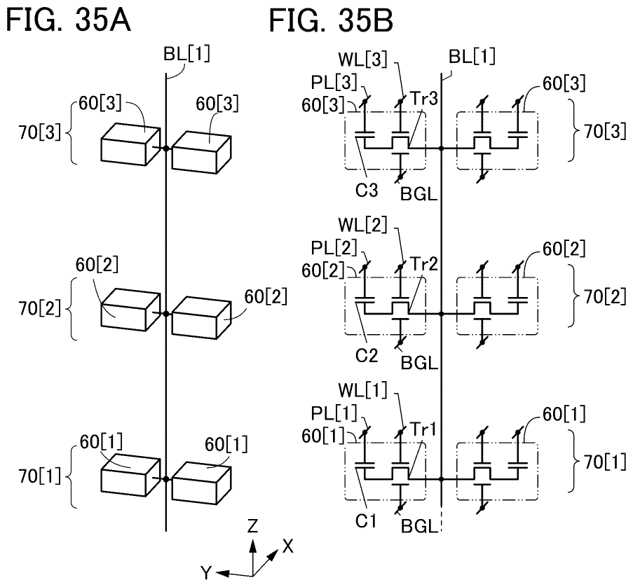

FIG. 35A and FIG. 35B are schematic views illustrating a structure example of the memory cells 60 connected to the wirings BL in the memory cell arrays 70[1] to 70[k] provided in a plurality of layers. A configuration in which a plurality of memory cells (memory cells 60) are electrically connected to one wiring BL is also referred to as “memory string”.

FIG. 35A illustrates a wiring BL[1] connected to the memory cells 60 included in each of the memory cell arrays 70 in the respective layers. The wiring BL[1] is configured to connect the plurality of memory cells 60 in each layer and connected to the sense amplifier 46 included in the driver circuit 71. FIG. 35A illustrates memory cells 60[1] provided in the memory array 70[1] in the first layer, memory cells 60[2] provided in the memory array 70[2] in the second layer, memory cells 60[3] provided in the memory array 70[3] in the third layer. The memory cell array 70 in each layer includes any one of the plurality of memory cells 60[1] arranged in a matrix, the plurality of memory cells 60[2] arranged in a matrix, and the plurality of memory cells 60[3] arranged in a matrix, and the wiring WL and the wiring PL that extend in the X direction. For easy viewing of the drawing, the wirings WL and the wirings PL included in the memory array 70 in each layer are not illustrated.

FIG. 35B illustrates a circuit diagram of the memory cell 60[1] to the memory cell 60[3] connected to the wiring BL[1]. The memory cell 60[1] to the memory cell 60[3] are configured to constitute the circuit diagram in FIG. 35B.

The memory cell 60[1] includes a transistor Tr and a capacitor C1. The memory cell 60[2] includes a transistor Tr2 and a capacitor C2. The memory cell 60[3] includes a transistor Tr3 and a capacitor C3. Note that in the case of matters common to the memory cell arrays in the layers, the memory cell in each layer is referred to as the memory cell 60 in some cases. As for the transistor Tr, the capacitor C, and the wirings (e.g., the wiring BL and the wiring WL), for example, the wiring BL[1] and the wiring WL[1] are referred to as the wiring BL and the wiring WL, respectively, in some cases.

In the memory cell 60[1], one of a source and a drain of the transistor Tr is electrically connected to a wiring BL[1]. The other of the source and the drain of the transistor Tr is electrically connected to one of a pair of electrodes of the capacitor C1. The other of the pair of electrodes of the capacitor C1 is connected to the wiring PL[1]. A gate of the transistor Tr is connected to the wiring WL[1]. A back gate of the transistor Tr is connected to the wiring BGL.

In the memory cell 60[2], one of a source and a drain of the transistor Tr2 is electrically connected to the wiring BL[1]. The other of the source and the drain of the transistor Tr2 is electrically connected to one of a pair of electrodes of the capacitor C2. The other of the pair of electrodes of the capacitor C2 is connected to the wiring PL[2]. A gate of the transistor Tr2 is connected to the wiring WL[2]. A back gate of the transistor Tr2 is connected to the wiring BGL.

In the memory cell 60[3], one of a source and a drain of the transistor Tr3 is electrically connected to the wiring BL[1]. The other of the source and the drain of the transistor Tr3 is electrically connected to one of a pair of electrodes of the capacitor C3. The other of the pair of electrodes of the capacitor C3 is connected to the wiring PL[3]. A gate of the transistor Tr3 is connected to the wiring WL[3]. A back gate of the transistor Tr3 is connected to the wiring BGL.

Although not illustrated, the structure similar to that of the second layer is repeated in the fourth layer and the subsequent layers. For example, in a memory cell 60[j] provided in a memory array 70[j] in the j-th layer (j is an integer satisfying 2≤j<k), one of a source and a drain of the transistor Trj is connected to the wiring BL[1]. The other of the source and the drain of the transistor Trj is electrically connected to one of a pair of electrodes of a capacitor Cj. The other of the pair of electrodes of the capacitor Cj is connected to a wiring PL[j]. A gate of the transistor Trj is connected to a wiring WL[j]. A back gate of the transistor Trj is connected to the wiring BGL.

The wiring PL is a wiring for supplying a fixed potential for retaining a potential of the capacitor C. The fixed potential supplied to the wiring PL is a ground potential (GND).

### [Arrangement Example of Memory Cell Array]

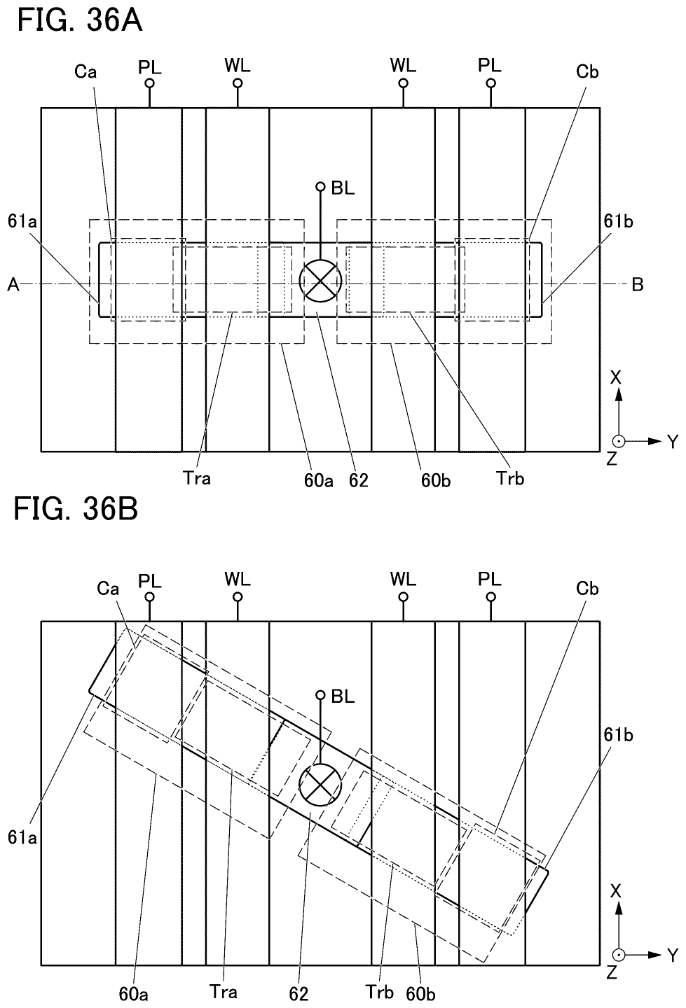

FIG. 36A is a layout diagram for showing an arrangement example of the wirings and semiconductor layers in the memory cells 60 described above. FIG. 36A illustrates the wiring WL and the wiring PL provided to extend in the X direction; a semiconductor layer 61a and a semiconductor layer 61b; a conductive layer 62; and the wiring BL provided to extend in the Z direction. The semiconductor layer 61a and the semiconductor layer 61b illustrated in FIG. 36A are each provided to intersect with one wiring WL and one wiring PL; the semiconductor layer 61a and the semiconductor layer 61b are connected to one wiring BL through the conductive layer 62, whereby two memory cells 60 are arranged.

For easy understanding of the invention, the memory cell 60 including the semiconductor layer 61a is referred to as a memory cell 60a, and the memory cell 60 including the semiconductor layer 61b is referred to as a memory cell 60b, whereby the two memory cells 60 are distinguished from each other in some cases.

In the memory cell 60a, the wiring WL, the wiring PL, and the conductive layer 62 are provided over the semiconductor layer 61a to overlap with each other. The transistor Tra is provided in a region where the wiring WL and the semiconductor layer 61a overlap with each other. The capacitor Ca is provided in a region where the wiring PL and the semiconductor layer 61a overlap with each other. The conductive layer 62 is a conductive layer for connecting the transistor Tra to the wiring BL. Similarly, in the memory cell 60b, the wiring WL, the wiring PL, and the conductive layer 62 are provided over the semiconductor layer 61b to overlap with each other. The transistor Trb is provided in a region where the wiring WL and the semiconductor layer 61b overlap with each other. The capacitor Cb is provided in a region where the wiring PL and the semiconductor layer 61b overlap with each other. The conductive layer 62 is a conductive layer for connecting the transistor Trb to the wiring BL.

Note that the transistor Tra, the transistor Trb, the capacitor Ca, and the capacitor Cb respectively correspond to the transistor 200a, the transistor 200b, the capacitor 100a, and the capacitor 100b described in Embodiment 2. The semiconductor layer 61a and the semiconductor layer 61b correspond to the oxide 230 described in Embodiment 2. The conductive layer 62 corresponds to the conductor 242a described in Embodiment 2. The wiring WL and the wiring PL respectively correspond to the conductor 260 and the conductor 160 described in Embodiment 2. Therefore, the above description is referred to for the memory cell 60 because the detailed description of the cross-sectional view is similar to the description in Embodiment 2.

In the case where the memory cell arrays 70 each including the memory cell 60 illustrated in FIG. 36A are stacked, it is preferable to employ a structure in which the wiring PL in an upper layer and the wiring PL in a lower layer overlap with each other and a structure in which the wiring WL in an upper layer and the wiring WL in a lower layer overlap with each other. That is, two layers of the memory cell arrays 70 that are provided to overlap with each other are preferably laid out to overlap with each other. With such a structure, the manufacturing process of the storage device can be simplified and the productivity can be improved.

Although FIG. 36A illustrates a structure in which the semiconductor layer 61a and the semiconductor layer 61b extending in the Y direction are provided to cross the wiring WL and the wiring PL at right angles, one embodiment of the present invention is not limited to the structure. For example, as illustrated in FIG. 36B, the semiconductor layer 61a and the semiconductor layer 61b extending in the Y direction may be positioned so that one end portion of each of the semiconductor layer 61a and the semiconductor layer 61b are inclined in the X direction to cross the wiring WL and the wiring PL. With this structure, the memory density of the memory cell 60 can be further increased.

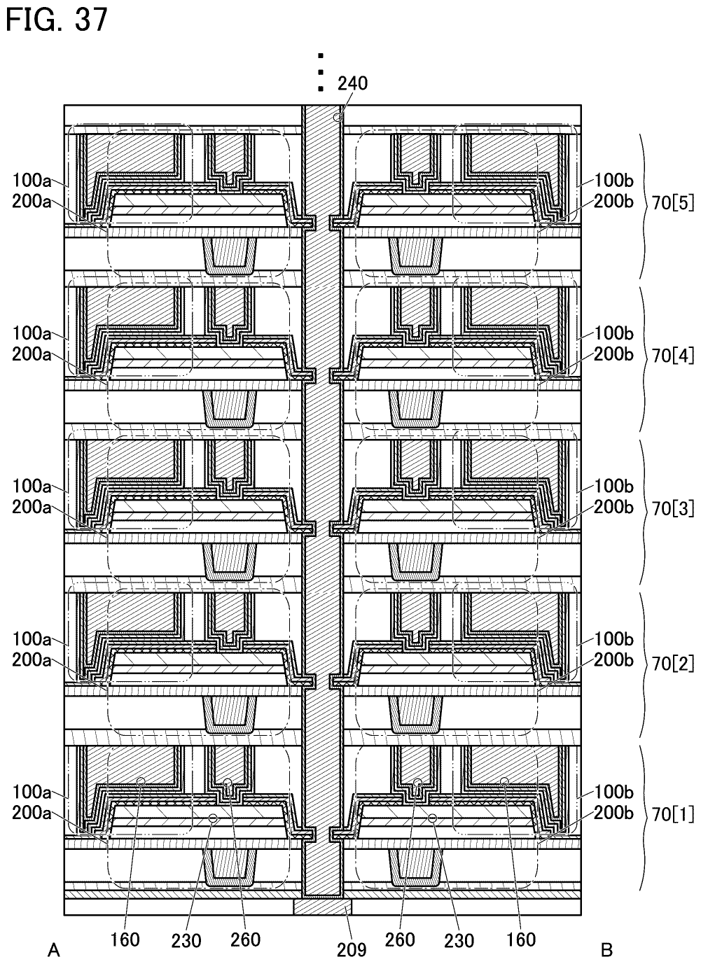

Here, FIG. 37 is a cross-sectional view in which a range of a section plane along the dashed-dotted line A-B in FIG. 36A is enlarged to the memory array 70[1] to the memory array 70[5], and the transistor 200 and the capacitor 100 described in the above embodiment are provided in each memory cell array.

In FIG. 37, the combination of the transistor 200a and the capacitor 100a corresponds to the memory cell 60a, and the combination of the transistor 200b and the capacitor 100b corresponds to the memory cell 60b. The conductor 260 corresponds to the wiring WL, and the conductor 160 corresponds to the wiring PL. The oxide 230 corresponds to the semiconductor layer 61a and the semiconductor layer 61b.

As illustrated in FIG. 37, the conductor 160 of the capacitor 100a in an upper layer is provided to overlap with the conductor 160 of the capacitor 100a in a lower layer, and the conductor 260 of the transistor 200a in an upper layer is provided to overlap with the conductor 260 of the transistor 200a in a lower layer.

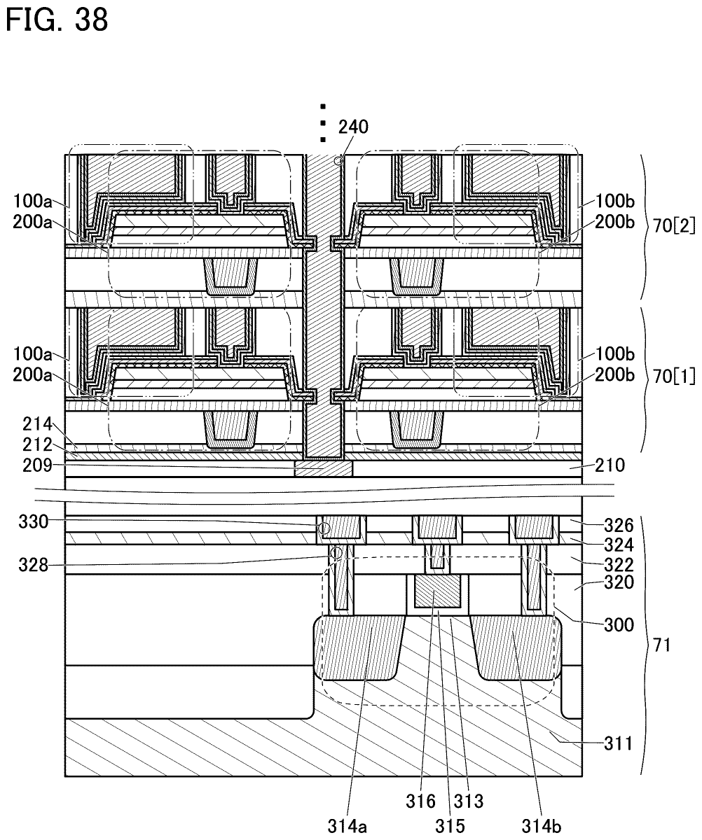

As illustrated in FIG. 38, a transistor 300 can be provided in the driver circuit 71 provided below the memory cell array 70[1].

The transistor 300 is provided on a substrate 311 and includes a conductor 316 functioning as a gate, an insulator 315 functioning as a gate insulator, a semiconductor region 313 formed of part of the substrate 311, and a low-resistance region 314a and a low-resistance region 314b functioning as a source region and a drain region. The transistor 300 may be a p-channel transistor or an n-channel transistor.

Here, in the transistor 300 illustrated in FIG. 38, the semiconductor region 313 (part of the substrate 311) in which a channel is formed has a convex shape. In addition, the conductor 316 is provided to cover the side surface and the top surface of the semiconductor region 313 with the insulator 315 therebetween. Note that a material adjusting the work function may be used for the conductor 316. Such a transistor 300 is also referred to as a FIN-type transistor because it utilizes a protruding portion of a semiconductor substrate. Note that an insulator functioning as a mask for forming the protruding portion may be included in contact with an upper portion of the protruding portion. Furthermore, although the case where the protruding portion is formed by processing part of the semiconductor substrate is described here, a semiconductor film having a protruding shape may be formed by processing an SOI substrate.

Note that the transistor 300 illustrated in FIG. 38 is an example and the structure is not limited thereto; an appropriate transistor is used in accordance with a circuit structure or a driving method.

Wiring layers provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, there are cases where part of a conductor functions as a wiring and part of a conductor functions as a plug.

For example, an insulator 320, an insulator 322, an insulator 324, and an insulator 326 are sequentially stacked over the transistor 300 as interlayer films. A conductor 328, a conductor 330, and the like that are electrically connected to the capacitor 100, the transistor 200, or the conductor 240 are embedded in the insulator 320, the insulator 322, the insulator 324, and the insulator 326. Note that the conductor 328 and the conductor 330 function as plugs or wirings.

The insulators functioning as interlayer films may also function as planarization films that cover uneven shapes therebelow. For example, the top surface of the insulator 322 may be planarized by planarization treatment using a chemical mechanical polishing (CMP) method or the like to improve planarity.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low relative dielectric constant is used as the insulator functioning as an interlayer film, parasitic capacitance generated between wirings can be reduced. Thus, a material is preferably selected depending on the function of the insulator.

For example, as the insulator 320, the insulator 322, the insulator 326, and the like, an insulator having a low dielectric constant is preferably used. For example, the insulator preferably includes silicon oxide to which fluorine is added, silicon oxide to which carbon is added, silicon oxide to which carbon and nitrogen are added, porous silicon oxide, a resin, or the like. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide or silicon oxynitride, which is thermally stable, is combined with a resin, the stacked-layer structure can have thermal stability and a low relative permittivity. Examples of the resin include polyester, polyolefin, polyamide (e.g., nylon and aramid), polyimide, polycarbonate, and acrylic.

When a transistor including an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used for the insulator 214, the insulator 212, the insulator 324, and the like.

As the insulator having a function of inhibiting passage of oxygen and impurities such as hydrogen, a single layer or stacked layers of an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum are used. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. Alternatively, a semiconductor having high electrical conductivity, typified by polycrystalline silicon containing an impurity element such as phosphorus, or silicide such as nickel silicide may be used.

For example, for the conductor 328, the conductor 330, the conductor 209, and the like, a single-layer structure or a stacked-layer structure using a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, it is preferable to use a low-resistance conductive material such as aluminum or copper. The use of a low-resistance conductive material can reduce wiring resistance.

When a plurality of memory cell arrays and the driver circuit are stacked as described above, high integration of the storage device and a high memory capacity can be achieved.

This embodiment can be combined as appropriate with any of the other embodiments and the like described in this specification.

### Embodiment 4

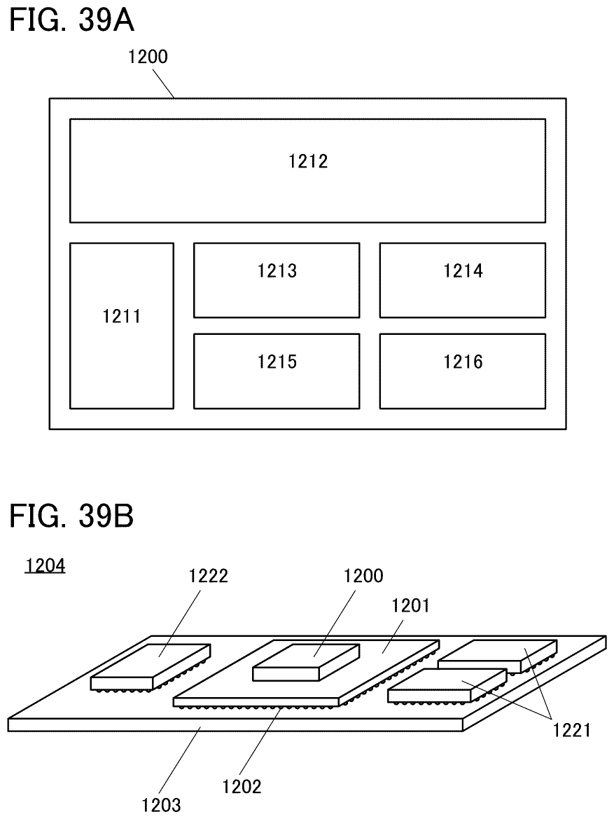

In this embodiment, an example of a chip 1200 on which the semiconductor device of the present invention is mounted will be described with reference to FIG. 39A and FIG. 39B. A plurality of circuits (systems) are mounted on the chip 1200. A technique for integrating a plurality of circuits (systems) into one chip is referred to as system on chip (SoC) in some cases.

As illustrated in FIG. 39A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

A bump (not illustrated) is provided on the chip 1200, and as illustrated in FIG. 39B, the chip 1200 is connected to a first surface of a package substrate 1201. In addition, a plurality of bumps 1202 are provided on a rear side of the first surface of the package substrate 1201, and the package substrate 1201 is connected to a motherboard 1203.

Storage devices such as DRAMs 1221 and a flash memory 1222 may be provided over the motherboard 1203. For example, the DOSRAM described in the above embodiment can be used as the DRAM 1221. This can make the DRAM 1221 operate at high speed and have a large capacity.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The DOSRAM described above can be used as the memory. Moreover, the GPU 1212 is suitable for parallel computation of a number of data and thus can be used for image processing or product-sum operation. When an image processing circuit or a product-sum operation circuit including an oxide semiconductor of the present invention is provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic appliance such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with any of those in the other embodiments and the like described in this specification.

### Embodiment 5

In this embodiment, examples of electronic components and electronic appliances in which the storage device or the like described in the above embodiment is incorporated will be described.

### <Electronic Component>

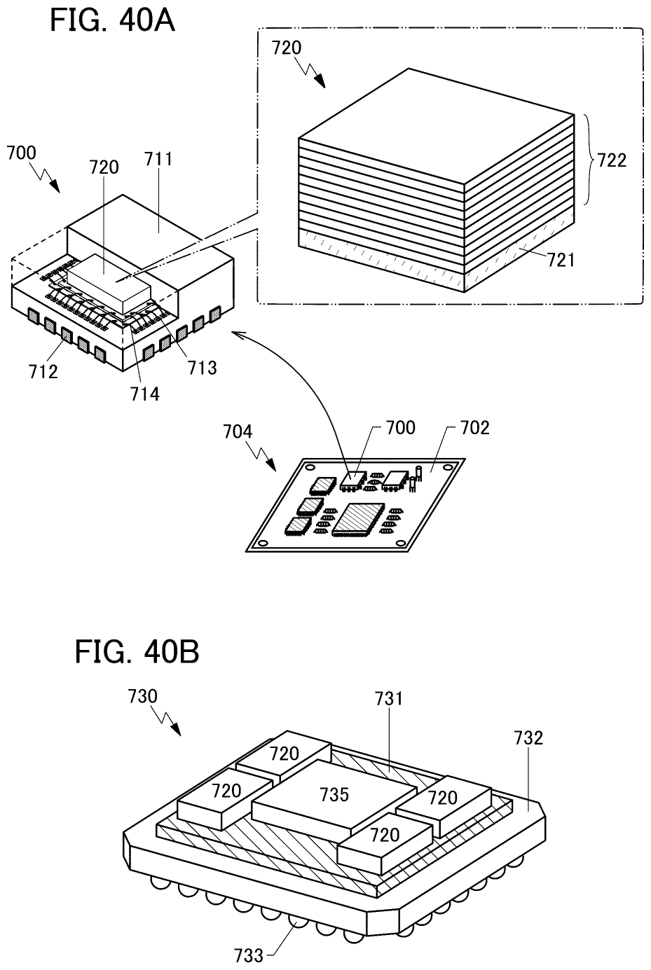

First, examples of an electronic component including a storage device 720 are described with reference to FIG. 40A and FIG. 40B.

FIG. 40A is a perspective view of an electronic component 700 and a substrate (circuit board 704) on which the electronic component 700 is mounted. The electronic component 700 illustrated in FIG. 40A includes the storage device 720 in a mold 711. FIG. 40A omits part of the electronic component to show the inside of the electronic component 700. The electronic component 700 includes a land 712 outside the mold 711. The land 712 is electrically connected to an electrode pad 713, and the electrode pad 713 is electrically connected to the storage device 720 via a wire 714. The electronic component 700 is mounted on a printed circuit board 702, for example. A plurality of such electronic components are combined and electrically connected to each other on the printed circuit board 702, which forms the circuit board 704.

The storage device 720 includes a driver circuit layer 721 and a storage circuit layer 722.

FIG. 40B is a perspective view of an electronic component 730. The electronic component 730 is an example of a SiP (System in package) or an MCM (Multi Chip Module). In the electronic component 730, an interposer 731 is provided over a package substrate 732 (printed circuit board) and a semiconductor device 735 and a plurality of storage devices 720 are provided over the interposer 731.

The electronic component 730 using the storage device 720 as a high bandwidth memory (HBM) is illustrated as an example. An integrated circuit (a semiconductor device) such as a CPU, a GPU, or an FPGA can be used as the semiconductor device 735.

As the package substrate 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings have a single-layer structure or a layered structure. The interposer 731 has a function of electrically connecting an integrated circuit provided on the interposer 731 to an electrode provided on the package substrate 732. Accordingly, the interposer is sometimes referred to as a “redistribution substrate” or an “intermediate substrate”. A through electrode may be provided in the interposer 731 to be used for electrically connecting the integrated circuit and the package substrate 732. In the case of using a silicon interposer, a TSV (Through Silicon Via) can also be used as the through electrode.

A silicon interposer is preferably used as the interposer 731. The silicon interposer can be manufactured at lower cost than an integrated circuit because it is not necessary to provide an active element. Meanwhile, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in expansion coefficient between an integrated circuit and the interposer is less likely to occur. Furthermore, a surface of a silicon interposer has high planarity, and a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the storage device 720 and the semiconductor device 735 are preferably the same, for example.

An electrode 733 may be provided on the bottom portion of the package substrate 732 to mount the electronic component 730 on another substrate. FIG. 40B illustrates an example where the electrode 733 is formed of a solder ball. Solder balls are provided in a matrix on the bottom portion of the package substrate 732, whereby a BGA (Ball Grid Array) mounting can be achieved. Alternatively, the electrode 733 may be formed of a conductive pin. When conductive pins are provided in a matrix on the bottom portion of the package substrate 732, a PGA (Pin Grid Array) mounting can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

The structure, method, and the like described in this embodiment can be used in an appropriate combination with any of other structures, methods, and the like described in this embodiment or any of structures, methods, and the like described in the other embodiments.

### Embodiment 6

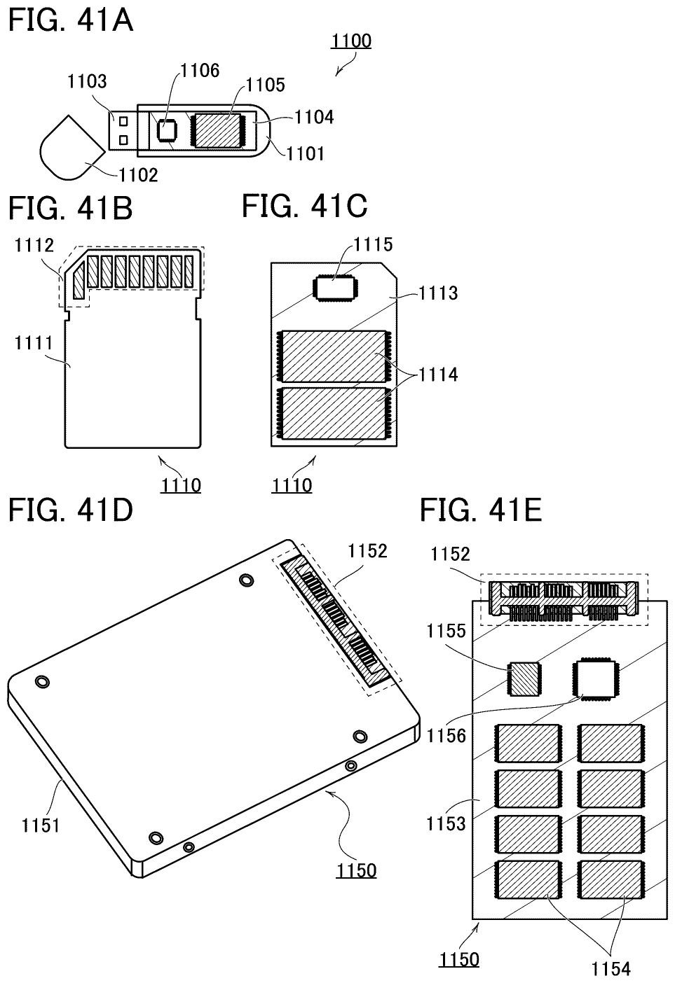

In this embodiment, application examples of the storage device using the semiconductor device described in the above embodiment will be described. The semiconductor device described in the above embodiment can be applied to, for example, storage devices of a variety of electronic appliances (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable storage devices such as memory cards (e.g., SD cards), USB memories, and SSDs (solid state drives). FIG. 41A to FIG. 41E schematically illustrate some structure examples of removable storage devices. The semiconductor device described in the above embodiment is processed into a packaged memory chip and used in a variety of storage devices and removable memories, for example.

FIG. 41A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105 or the like.

FIG. 41B is a schematic external view of an SD card, and FIG. 41C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. This enables data reading and writing of the memory chip 1114 by wireless communication between a host device and the SD card 1110. The semiconductor device described in the above embodiment can be incorporated in the memory chip 1114 or the like.

FIG. 41D is a schematic external view of an SSD, and FIG. 41E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154 or the like.

At least part of the structure, method, and the like described in this embodiment can be implemented in appropriate combination with any of those in the other embodiments and the like described in this specification.

### Embodiment 7

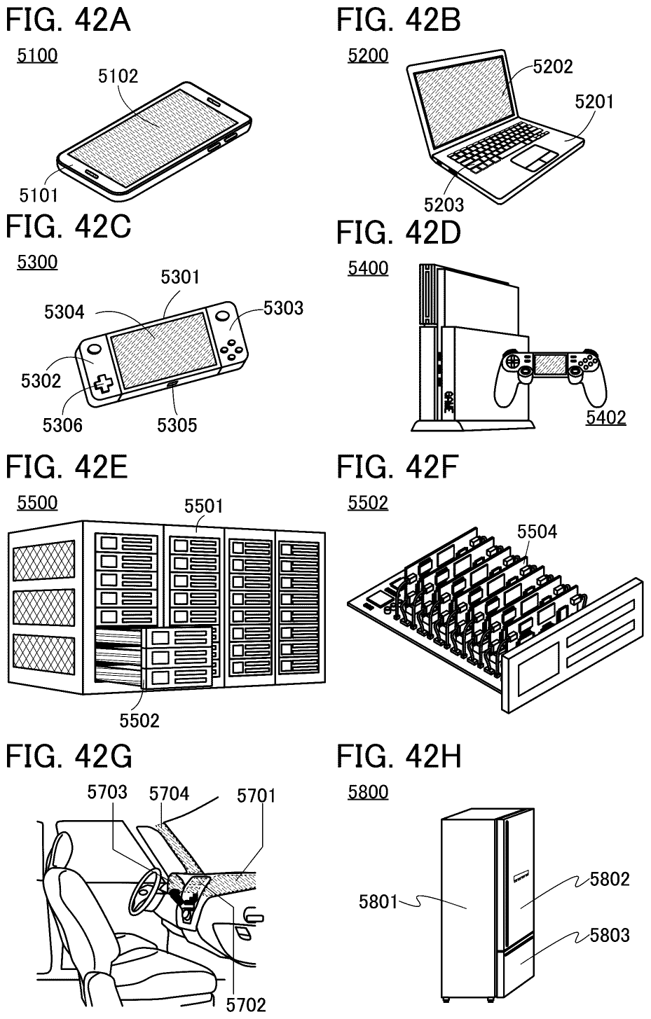

The semiconductor device of one embodiment of the present invention can be used as a processor such as a CPU and a GPU, a storage device, or a chip. FIG. 42A to FIG. 42H illustrate specific examples of electronic appliances including a chip, a storage device, or a processor such as a CPU or a GPU of one embodiment of the present invention.

### <Electronic Device and System>

The GPU, the storage device, or the chip of one embodiment of the present invention can be mounted on a variety of electronic appliances. Examples of electronic appliances include a digital camera, a digital video camera, a digital photo frame, an e-book reader, a mobile phone, a portable game machine, a portable information terminal, and an audio reproducing device in addition to electronic appliances provided with a relatively large screen, such as a television device, a monitor for a desktop or notebook information terminal or the like, digital signage, and a large game machine like a pachinko machine. When the GPU or the chip of one embodiment of the present invention is provided in the electronic appliance, the electronic appliance can include artificial intelligence.

The electronic appliance of one embodiment of the present invention may include an antenna. When a signal is received by the antenna, the electronic appliance can display a video, data, or the like on a display portion. When the electronic appliance includes the antenna and a secondary battery, the antenna may be used for contactless power transmission.

The electronic appliance of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, an electric field, current, voltage, power, radioactive rays, flow rate, humidity, a gradient, oscillation, odor, or infrared rays).

The electronic appliance of one embodiment of the present invention can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 42A to FIG. 42H illustrate examples of electronic devices.

### [Information Terminal]

FIG. 42A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the contents of the conversation on the display portion 5102; an application for recognizing letters, figures, and the like input to the touch panel of the display portion 5102 by a user and displaying them on the display portion 5102; and an application for performing biometric authentication using fingerprints, voice prints, or the like.

FIG. 42B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with use of the notebook information terminal 5200, novel artificial intelligence can be developed.

Note that although FIG. 42A and FIG. 42B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 42C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In this case, the housing 5302 and the housing 5303 can each function as an operating unit. Thus, a plurality of players can play a game at the same time. The chip described in the above embodiment can be incorporated into the chip provided on a substrate in the housing 5301, the housing 5302, and the housing 5303.

FIG. 42D illustrates a stationary game machine 5400 as an example of a game machine. A controller 5402 is wired or connected wirelessly to the stationary game machine 5400.

Using the GPU, the storage device, or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are illustrated as examples of game machines in FIG. 42C and FIG. 42D, the game machine using the GPU, the storage device, or the chip of one embodiment of the present invention is not limited thereto. Examples of the game machine to which the GPU, the storage device, or the chip of one embodiment of the present invention is applied include an arcade game machine installed in entertainment facilities (a game center, an amusement park, and the like), and a throwing machine for batting practice installed in sports facilities.

### [Large Computer]

The GPU, the storage device, or the chip of one embodiment of the present invention can be used in a large computer.

FIG. 42E illustrates a supercomputer 5500 as an example of a large computer. FIG. 42F illustrates a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504, on which the GPU, the storage device, or the chip described in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU, the storage device, or the chip of one embodiment of the present invention in the supercomputer 5500 achieves a low-power-consumption supercomputer. Moreover, heat generation from a circuit can be reduced owing to low power consumption; thus, the influence of heat generation on the circuit, a peripheral circuit, and a module can be reduced.

Although a supercomputer is illustrated as an example of a large computer in FIG. 42E and FIG. 42F, a large computer using the GPU, the storage device, or the chip of one embodiment of the present invention is not limited thereto. Other examples of large computers in which the GPU, the storage device, or the chip of one embodiment of the present invention is usable include a computer that provides service (a server) and a large general-purpose computer (a mainframe).

### [Moving Vehicle]

The GPU, the storage device, or the chip of one embodiment of the present invention can be applied to an automobile, which is a moving vehicle, and the periphery of a driver's seat in the automobile.

FIG. 42G illustrates an area around a windshield inside an automobile, which is an example of a moving vehicle. FIG. 42G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, and the like. In addition, the content, layout, or the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an image capturing device (not illustrated) provided for the automobile. That is, displaying an image taken by the image capturing device provided outside the automobile leads to compensation for the blind spot and an increase in safety. In addition, displaying an image to compensate for a portion that cannot be seen makes it possible for the driver to confirm the safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 42H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on foods stored in the electric refrigerator-freezer 5800, expiration dates of the foods, or the like, a function of automatically adjusting temperature to be appropriate for the foods stored in the electric refrigerator-freezer 5800, and the like.

Although the electric refrigerator-freezer is described as an example of a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic appliances, the functions of the electronic appliances, the application examples of artificial intelligence, their effects, and the like described in this embodiment can be combined as appropriate with the description of another electronic appliance.

At least part of the structure, method, and the like described in this embodiment can be implemented in appropriate combination with any of those in the other embodiments and the like described in this specification.

### Embodiment 8

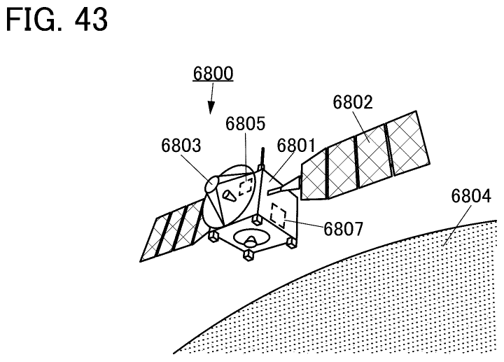

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, OS transistors can be suitably used in outer space. In this embodiment, a specific example of using the semiconductor device of one embodiment of the present invention in a device for space will be described with reference to FIG. 43.

FIG. 43 illustrates an artificial satellite 6800 as an example of a device for space. The artificial satellite 6800 includes a body 6801, a solar panel 6802, an antenna 6803, a secondary battery 6805, and a control device 6807. In FIG. 43, a planet 6804 in outer space is illustrated as an example. Note that outer space refers to, for example, space at an altitude greater than or equal to 100 km, and outer space described in this specification may include thermosphere, mesosphere, and stratosphere.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for the operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for the operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a storage device, for example. Note that the semiconductor device including the OS transistor of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can be configured to include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can have a function of an earth observing satellite, for example.

Although the artificial satellite is described as an example of a device for space in this embodiment, one embodiment of the present invention is not limited thereto. The semiconductor device of one embodiment of the present invention can be suitably used for a device for space such as a spacecraft, a space capsule, or a space probe, for example.

### REFERENCE NUMERALS

ADDR: signal, BGL: wiring, BL[1]: wiring, BL[j]: wiring, BL[n]: wiring, BL: wiring, BW: signal, Ca: capacitor, Cb: capacitor, CE: signal, Cj: capacitor, CLK: signal, GV: gate valve, GW: signal, PL[1]: wiring, PL[2]: wiring, PL[3]: wiring, PL[i]: wiring, PL[j]: wiring, PL[m]: wiring, PL: wiring, RDA: signal, Tr: transistor, Tra: transistor, Trb: transistor, Trj: transistor, WAKE: signal, WDA: signal, Wᵢ: width, WL[1]: wiring, WL[2]: wiring, WL[3]: wiring, WL[i]: wiring, WL[j]: wiring, WL[m]: wiring, WL: wiring, Wₘ: width, 10: device, 11: wiring, 12_1: wiring, 12_2: wiring, 12_3: wiring, 12f: conductive film, 20: connection portion, 21f: conductive film, 21: conductor, 22: conductor, 25: opening, 31_1: insulator, 31_2: insulator, 31_3: insulator, 31_4: insulator, 31: insulator, 32: insulator, 33_1: insulator, 33_2: insulator, 33_3: insulator, 35: resist mask, 41: peripheral circuit, 42: row decoder, 43: row driver, 44: column decoder, 45: column driver, 46: sense amplifier, 47: input circuit, 48: output circuit, 50: storage device, 60[1,1]: memory cell, 60[1]: memory cell, 60[2]: memory cell, 60[3]: memory cell, 60[i,j]: memory cell, 60[j]: memory cell, 60[m,n]: memory cell, 60a: memory cell, 60b: memory cell, 60: memory cell, 61a: semiconductor layer, 61b: semiconductor layer, 62: conductive layer, 70[1]: memory cell array, 70[2]: memory cell array, 70[3]: memory cell array, 70[5]: memory cell array, 70[j]: memory cell array, 70[k]: memory cell array, 70: memory cell array, 71: driver circuit, 72: PSW, 73: PSW, 81: peripheral circuit, 82: control circuit, 83: voltage generation circuit, 100a: capacitor, 100b: capacitor, 100: capacitor, 153: insulator, 154: insulator, 158: opening, 160a: conductor, 160b: conductor, 160: conductor, 200a: transistor, 200b: transistor, 200: transistor, 205a: conductor, 205b: conductor, 205c: conductor, 205: conductor, 209: conductor, 210: insulator, 212: insulator, 214: insulator, 216: insulator, 221: insulator, 222: insulator, 224A: insulating layer, 224Af: insulating film, 224: insulator, 230a: oxide, 230A: oxide layer, 230Af: oxide film, 230b: oxide, 230B: oxide layer, 230ba: region, 230bb: region, 230bc: region, 230Bf: oxide film, 230: oxide, 240a: conductor, 240b: conductor, 240: conductor, 242a: conductor, 242A: conductive layer, 242Af: conductive film, 242b: conductor, 242B: conductive layer, 242Bf: conductive film, 242: conductor, 253A: insulating film, 253: insulator, 254: insulator, 258: opening, 259: mask layer, 260a: conductor, 260b: conductor, 260: conductor, 263: opening, 275: insulator, 280: insulator, 282: insulator, 283: insulator, 285: insulator, 300: transistor, 311: substrate, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 700: electronic component, 702: printed circuit board, 704: circuit board, 711: mold, 712: land, 713: electrode pad, 714: wire, 720: storage device, 721: driver circuit layer, 722: storage circuit layer, 730: electronic component, 731: interposer, 732: package substrate, 733: electrode, 735: semiconductor device, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 2700: manufacturing apparatus, 2701: atmosphere-side substrate supply chamber, 2702: atmosphere-side substrate transfer chamber, 2703a: load lock chamber, 2703b: unload lock chamber, 2704: transfer chamber, 2706a: chamber, 2706b: chamber, 2706c: chamber, 2706d: chamber, 2761: cassette port, 2762: alignment port, 2763a: transfer robot, 2763b: transfer robot, 2801: gas supply source, 2802: valve, 2803: high-frequency generator, 2804: waveguide, 2805: mode converter, 2806: gas pipe, 2807: waveguide, 2808: slot antenna plate, 2809: dielectric plate, 2810: high-density plasma, 2811_1: substrate, 2811_2: substrate, 2811_3: substrate, 2811_n: substrate, 2811: substrate, 2812: substrate holder, 2813: heating mechanism, 2815: matching box, 2816: high-frequency power source, 2817: vacuum pump, 2818: valve, 2819: exhaust port, 2820: lamp, 2821: gas supply source, 2822: valve, 2823: gas inlet, 2824: substrate, 2825: substrate holder, 2826: heating mechanism, 2828: vacuum pump, 2829: valve, 2830: exhaust port, 2900: microwave treatment apparatus, 2901: quartz tube, 2902: substrate holder, 2903: heating means, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door, 6800: artificial satellite, 6801: body, 6802: solar panel, 6803: antenna, 6804: planet, 6805: secondary battery, 6807: control device

1. An electronic device comprising:
a first conductor;
a second conductor;
a first insulator;
a second insulator; and
a connection electrode,
wherein the first insulator comprises a first opening over the first conductor and overlapping with the first conductor,
wherein the second conductor comprises a second opening over the first conductor and overlapping with the first conductor,
wherein the second insulator comprises a third opening over the second conductor and overlapping with the first conductor,
wherein a width of a first region of the second opening is smaller than a width of the third opening,
wherein the connection electrode is positioned inside the first opening, the second opening, and the third opening,
wherein the connection electrode is in contact with a top surface of the first conductor, and
wherein the connection electrode comprises a first region in contact with a top surface and a side surface of the second conductor.

2. The electronic device according to claim 1,
wherein a width of a second region of the second opening is smaller than a width of the first opening, and
wherein the connection electrode comprises a second region in contact with of a bottom surface of the second conductor.

3. The electronic device according to claim 1,
wherein the connection electrode comprises a third conductor and a fourth conductor,
wherein the third conductor is on an inner side of the first opening, an inner side of the second opening, and an inner side of the third opening,
wherein the fourth conductor is between the third conductor and the first insulator, between the third conductor and the second conductor, and between the third conductor and the second insulator, and
wherein the fourth conductor comprises the first region of the connection electrode.

4. The electronic device according to claim 3,
wherein the third conductor comprises one of tantalum, tungsten, titanium, molybdenum, aluminum, and copper, and
wherein the fourth conductor comprises one of tantalum nitride, tungsten nitride, and titanium nitride.

5. The electronic device according to claim 3,
wherein an inner wall of the first opening has a concave shape, and
wherein a side surface of the third conductor comprises a first region having a convex shape.

6. The electronic device according to claim 3,
wherein a width of the first opening is smaller than a width of a second region of the second opening,
wherein a width of a first region of the third conductor is smaller than a width of a second region of the third conductor,
wherein the first region of the third conductor is provided inside the third opening, and
wherein the second region of the third conductor is provided inside the first opening.

7. A method for manufacturing an electronic device comprising:
forming a first conductor;
forming a first insulator over the first conductor;
forming a second conductor over the first insulator;
forming a first opening in the second conductor;
forming a second insulator over the second conductor;
performing a first etching treatment on the first insulator to form a second opening in the first insulator overlapping with the first conductor and the first opening and on the second insulator to form a third opening in the second insulator overlapping with the first conductor and the first opening;
performing a second etching treatment on a first part of the first insulator and on a first part of the second insulator to widen a width of the second opening and a width of the third opening; and
forming a connection electrode inside the first opening, the second opening, and the third opening,
wherein the connection electrode is in contact with a top surface of the first conductor and a top surface and a side surface of the second conductor, and
wherein the first etching treatment is anisotropic etching and the second etching treatment is isotropic etching.

8. The method for manufacturing an electronic device according to claim 7,
wherein a dry etching treatment is performed between the first etching treatment and the second etching treatment, and
wherein the first etching treatment and the second etching treatment are performed successively in a same apparatus without exposing the first conductor, the first insulator, the second conductor, and the second insulator to air.

9. The method for manufacturing an electronic device according to claim 7,
wherein dry etching is used in the first etching treatment, and
wherein wet etching is used in the second etching treatment.

10. A semiconductor device comprising:
a transistor; and
a capacitor,
wherein the transistor comprises:
an oxide;
a first conductor and a second conductor over the oxide;
a first insulator over the first conductor and the second conductor;
a second insulator over the first insulator;
a third insulator over the oxide; and
a third conductor over the third insulator,
wherein the second insulator comprises a first opening and a second opening,
wherein the first insulator comprises a third opening overlapping with the first opening,
wherein the first opening and the third opening each comprises a region overlapping with the oxide,
wherein the third insulator and the third opening are in the first opening,
wherein the third conductor comprises a region overlapping with the oxide with the third insulator therebetween,
wherein the third insulator comprises a region in contact with a top surface of the oxide and a sidewall of the first opening,
wherein the capacitor comprises:
the second conductor;
the first insulator over the second conductor;
a fourth insulator over the first insulator; and
a fourth conductor over the fourth insulator,
wherein the fourth insulator and the fourth conductor are in the second opening, and
wherein, in a cross-sectional view of the transistor in a channel length direction, a distance between the first conductor and the second conductor is smaller than a width of the first opening.

11. The semiconductor device according to claim 10,
wherein the second opening comprises a region overlapping with the second conductor,
wherein the fourth conductor comprises a region overlapping with the second conductor with the first insulator and the fourth insulator therebetween, and
wherein the fourth insulator comprises a region in contact with a top surface of the first insulator and a sidewall of the second opening.

12. The semiconductor device according to claim 10,
wherein the third insulator comprises a fifth insulator and a sixth insulator over the fifth insulator,
wherein the fourth insulator comprises a seventh insulator and an eighth insulator over the seventh insulator,
wherein the fifth insulator comprises a same insulating material as the seventh insulator,
wherein the sixth insulator comprises a same insulating material as the eighth insulator, and
wherein the third conductor comprises a same conductive material as the fourth conductor.

13. The semiconductor device according to claim 10, wherein a side surface of the first conductor and a side surface of the second conductor that face each other are substantially perpendicular to the top surface of the oxide.

14. The semiconductor device according to claim 10,
wherein the first conductor comprises a fifth conductor and a sixth conductor over the fifth conductor,
wherein the second conductor comprises a seventh conductor and an eighth conductor over the seventh conductor,
wherein the fifth conductor comprises a same conductive material as the seventh conductor, and
wherein the sixth conductor comprises a same conductive material as the eighth conductor.

15. The semiconductor device according to claim 10, wherein the oxide comprises at least one of indium, zinc, gallium, aluminum, and tin.

16.-19. (canceled)
